(19) United States
(12) Patent Application Publication
(10) Pub. No.: US 2023/0013624 A1
(43) Pub. Date: Jan. 19, 2023

(54) RESIST COMPOSITION AND PATTERN FORMING PROCESS

(71) Applicant: Shin-Etsu Chemical Co., Ltd., Tokyo (JP)

(72) Inventor: Jun Hatakeyama, Joetsu-shi (JP)

(73) Assignee: Shin-Etsu Chemical Co., Ltd., Tokyo (JP)

(21) Appl. No.: 17/830,821

(22) Filed: Jun. 2, 2022

(30) Foreign Application Priority Data
Jun. 15, 2021 (JP) 2021-099189

(51) Int. Cl. G03F 7/039; G03F 7/004; G03F 7/038; G03F 7/20

(52) U.S. Cl. CPC G03F 7/0397; G03F 7/0045; G03F 7/0048; G03F 7/0382; G03F 7/202

(57) ABSTRACT

A resist composition comprising a polymer is provided, the polymer comprising repeat units derived from a sulfonium or iodonium salt having a nitro-substituted benzene ring in a linker between a polymerizable unsaturated bond and a fluorosulfonic acid site. The resist composition has a high sensitivity and forms a pattern with improved LWR or CDU, independent of whether it is of positive or negative tone.

### CROSS-REFERENCE TO RELATED APPLICATION

This non-provisional application claims priority under 35 U.S.C. § 119(a) on Patent Application No. 2021-099189 filed in Japan on Jun. 15, 2021, the entire contents of which are hereby incorporated by reference.

### TECHNICAL FIELD

This invention relates to a resist composition and a pattern forming process.

### BACKGROUND ART

To meet the demand for higher integration density and operating speed of LSIs, the effort to reduce the pattern rule is in rapid progress. As the use of 5G high-speed communications and artificial intelligence (AI) is widely spreading, high-performance devices are needed for their processing. As the advanced miniaturization technology, manufacturing of microelectronic devices at the 5-nm node by the lithography using EUV of wavelength 13.5 nm has been implemented in a mass scale. Studies are made on the application of EUV lithography to 3-nm node devices of the next generation and 2-nm node devices of the next-but-one generation.

As the pattern feature size is reduced, the edge roughness (LWR) of line patterns and the critical dimension uniformity (CDU) of hole patterns are regarded significant. It is pointed out that these factors are affected by the segregation or agglomeration of a base polymer and acid generator and the diffusion of generated acid. There is a tendency that as the resist film becomes thinner, values of LWR and CDU become noticeable. A film thickness reduction to comply with the progress of size reduction causes a degradation of LWR or CDU, which poses a serious problem.

The EUV resist material must meet high sensitivity, high resolution and low LWR at the same time. As the acid diffusion distance is reduced, LWR or CDU is improved, but sensitivity becomes lower. For example, as the PEB temperature is lowered, the outcome is an improved LWR or CDU, but a lower sensitivity. As the amount of quencher added is increased, the outcome is an improved LWR or CDU, but a lower sensitivity. It is necessary to overcome the tradeoff relation between sensitivity and LWR.

For the purpose of suppressing acid diffusion, Patent Documents 1 and 2 propose resist compositions comprising an acid generator capable of generating a sulfonic acid bound to a polymer backbone upon light exposure. The polymer-bound acid generator is characterized by extremely short acid diffusion, which leads to an improvement in LWR.

Patent Documents 3 and 4 disclose resist compositions comprising an acid generator capable of generating a sulfonic acid having iodine or bromine between a polymer backbone and a sulfonic acid group. These compositions aim to improve sensitivity by enhancing absorption of EUV or inducing ionization to increase the generation efficiency of secondary electrons during exposure and to improve physical contrast by increasing the amount of photons absorbed, but not to control acid diffusion. Further acid diffusion control is thus necessary.

### CITATION LIST

Patent Document 1: JP 4425776
Patent Document 2: JP 4893580
Patent Document 3: JP-A 2018-197853 (U.S. Pat. No. 11,022,883)
Patent Document 4: JP-A 2019-008280 (U.S. Pat. No. 10,802,400)

### SUMMARY OF INVENTION

It is desired to develop a resist composition exhibiting a higher sensitivity than prior art resist compositions and capable of reducing the LWR of line patterns or improving the CDU of hole patterns.

An object of the invention is to provide a resist composition which achieves a high sensitivity, minimal LWR and improved CDU independent of whether it is of positive or negative tone, and a pattern forming process using the resist composition.

The inventor has found that a resist composition having a high sensitivity, improved LWR or CDU, high contrast, high resolution and wide process margin is obtained from a polymer serving as the polymer-bound acid generator, the polymer comprising repeat units derived from a sulfonium or iodonium salt containing a polymerizable unsaturated bond and a fluorosulfonic acid site and having a nitro-substituted benzene ring in a linker between the polymerizable unsaturated bond and the fluorosulfonic acid site.

In one aspect, the invention provides a resist composition comprising a polymer comprising repeat units having the formula (a1) or (a2).

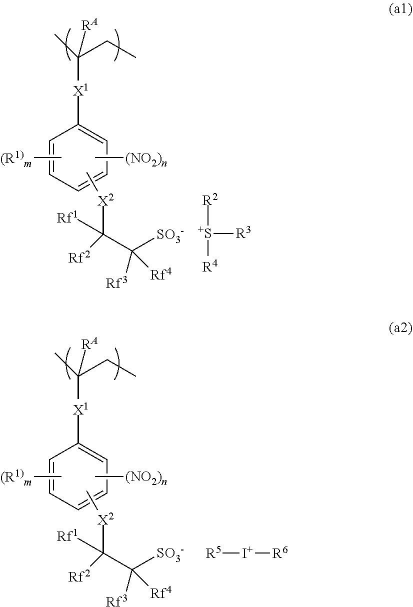

Herein R^{A} is hydrogen or methyl. X¹ is a single bond, ester bond, amide bond or —X^{1A}—X^{1C}—X^{1B}—, X^{1A} and X^{1B} are each independently a single bond, ether bond or ester bond, X^{1C} is a C₁-C₁₂ saturated hydrocarbylene group, C₆-C₁₀ arylene group or a combination thereof, wherein some constituent —CH₂— may be replaced by an ether bond, ester bond, amide bond, lactone ring-containing moiety or sultone ring-containing moiety, and some or all of the hydrogen atoms on the aromatic ring may be substituted by a C₁-C₄ alkyl moiety, C₁-C₄ alkyloxy moiety, C₂-C₅ alkylcarbonyloxy moiety, halogen or nitro moiety. X² is a single bond, ether bond, ester bond or —X^{2A}—X^{2C}—X^{2B}—, wherein X^{2A} and X^{2B} are each independently a single bond, ether bond or ester bond, X^{2C} is a C₁-C₁₂ saturated hydrocarbylene group, C₆-C₁₀ arylene group or a combination thereof, wherein some constituent —CH₂— may be replaced by an ether bond, ester bond, amide bond, lactone ring-containing moiety or sultone ring-containing moiety, and some or all of the hydrogen atoms on the aromatic ring may be substituted by a C₁-C₄ alkyl moiety, C₁-C₄ alkyloxy moiety, C₂-C₅ alkylcarbonyloxy moiety, halogen or nitro moiety. Rf¹ to Rf⁴ are each independently hydrogen, fluorine or trifluoromethyl, at least one of Rf¹ to Rf⁴ being fluorine or trifluoromethyl, and Rf¹ and Rf², taken together, may form a carbonyl group. R¹ is a C₁-C₄ alkyl group, C₁-C₄ alkyloxy group, C₂-C₅ alkylcarbonyloxy group or halogen. R² to R⁶ are each independently halogen or a C₁-C₂₀ hydrocarbyl group which may contain a heteroatom, R² and R³ may bond together to form a ring with the sulfur atom to which they are attached, m is an integer of 0 to 3, and n is 1 or 2.

In a preferred embodiment, the repeat units having formula (a1) have the formula (a1-1) and the repeat units having formula (a2) have the formula (a2-1).

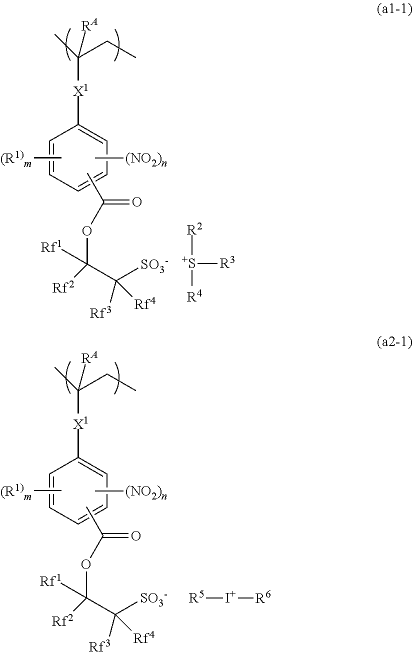

Herein R^{A}, X¹, Rf¹ to Rf⁴, R¹ to R⁶, m, and n are as defined above.

In a preferred embodiment, the polymer further comprises repeat units having the formula (b1) or (b2).

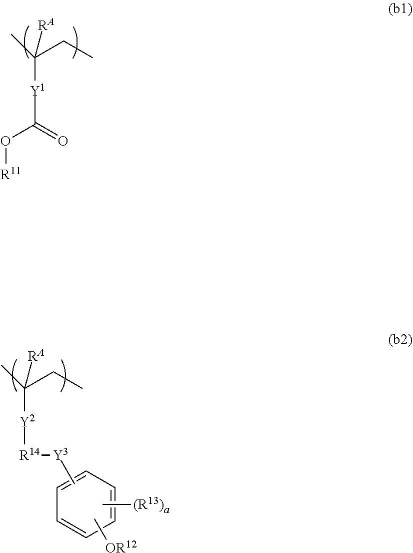

Herein R^{A} is each independently hydrogen or methyl. Y¹ is a single bond, phenylene, naphthylene, or a C₁-C₁₂ linking group containing at least one moiety selected from ester bond, ether bond and lactone ring. Y² is a single bond or ester bond. R¹¹ and R¹² are each independently an acid labile group. R¹³ is a C₁-C₄ saturated hydrocarbyl group, halogen, C₂-C₅ saturated hydrocarbylcarbonyl group, cyano group or C₂-C₅ saturated hydrocarbyloxycarbonyl group. R¹⁴ is a single bond or a C₁-C₆ alkanediyl group which may contain an ether bond or ester bond, and “a” is an integer of 0 to 4.

Typically, the resist composition is a chemically amplified positive resist composition.

In another preferred embodiment, the polymer is free of an acid labile group. Typically, the resist composition is a chemically amplified negative resist composition.

The resist composition may further comprise an organic solvent, a quencher, and/or a surfactant.

In another aspect, the invention provides a pattern forming process comprising the steps of applying the resist composition defined above onto a substrate to form a resist film thereon, exposing the resist film to high-energy radiation, and developing the exposed resist film in a developer.

Typically, the high-energy radiation is ArF excimer laser of wavelength 193 nm, KrF excimer laser of wavelength 248 nm, EB, or EUV of wavelength 3 to 15 nm.

### Advantageous Effects of Invention

A resist film containing a polymer comprising repeat units derived from a sulfonium or iodonium salt containing a polymerizable unsaturated bond and a fluorosulfonic acid site and having a nitro-substituted benzene ring in a linker between the polymerizable unsaturated bond and the fluorosulfonic acid site is characterized in that the nitro group serves to control acid diffusion. This prevents a lowering of resolution due to blur by acid diffusion for thereby improving LWR or CDU. The inventive resist composition is a self-sensitizing resist composition in which secondary electrons generate from the delocalized electron cloud of the nitro group during EUV exposure, and the energy of secondary electrons is transferred to the acid generator to bring about a higher sensitivity. Since the nitro group and the acid generator are incorporated in close proximity within a common repeat unit, image blurs due to diffusion of secondary electrons are prohibited. A resist composition having a high sensitivity and improved LWR or CDU is thus designed.

### DESCRIPTION OF EMBODIMENTS

As used herein, the singular forms “a,” “an” and “the” include plural referents unless the context clearly dictates otherwise. The notation (Cn-Cm) means a group containing from n to m carbon atoms per group. As used herein, the terms “group” and “moiety” are interchangeable. In chemical formulae, the broken line designates a valence bond.

The abbreviations and acronyms have the following meaning.

EB: electron beam

EUV: extreme ultraviolet

Mw: weight average molecular weight

Mn: number average molecular weight

Mw/Mn: molecular weight distribution or dispersity

GPC: gel permeation chromatography

PEB: post-exposure bake

PAG: photoacid generator

LWR: line width roughness

CDU: critical dimension uniformity

### Resist Composition

One embodiment of the invention is a resist composition comprising a polymer-bound acid generator. Specifically, the resist composition contains as the polymer-bound acid generator, a polymer comprising repeat units derived from a sulfonium or iodonium salt containing a polymerizable unsaturated bond and a fluorosulfonic acid site and having a nitro-substituted benzene ring in a linker between the polymerizable unsaturated bond and the fluorosulfonic acid site. In the resist composition, another acid generator capable of generating a sulfonic acid, imide acid or methide acid may be added.

When a resist composition containing the polymer-bound acid generator in admixture with a sulfonium salt capable of generating a weaker sulfonic or carboxylic acid is exposed to radiation, a polymeric fluorosulfonic acid containing a nitro-substituted benzene ring in the linker and the weaker sulfonic or carboxylic acid generate. Since the acid generator is not entirely decomposed, the undecomposed sulfonium salt is present nearby. When the polymeric fluorosulfonic acid containing a nitro-substituted benzene ring in the linker co-exists with the sulfonium salt of weaker sulfonic or carboxylic acid, an ion exchange takes place between the polymeric fluorosulfonic acid containing a nitro-substituted benzene ring in the linker and the sulfonium salt of weaker sulfonic or carboxylic acid, whereby a sulfonium or iodonium salt of the polymeric fluorosulfonic acid containing a nitro-substituted benzene ring in the linker is created and the weaker sulfonic or carboxylic acid is released. This is because the salt of the polymeric fluorosulfonic acid containing a nitro-substituted benzene ring in the linker has a higher acid strength and is more stable. In contrast, when a sulfonium salt of the polymeric fluorosulfonic acid containing a nitro-substituted benzene ring in the linker co-exists with weaker sulfonic or carboxylic acid, no ion exchange takes place. The ion exchange conforming to the order of acid strength takes place not only with sulfonium salts, but also similarly with iodonium salts. When combined with an acid generator in the form of fluorosulfonic acid, a sulfonium or iodonium salt of weak acid functions as a quencher. Also, secondary electrons generate from the delocalized electron cloud of the nitro group during exposure, and the energy of secondary electrons is transferred to the acid generator to promote decomposition of the acid generator, contributing to a higher sensitivity. The polymer-bound acid generator is successful in providing the resist composition with low acid diffusion and high sensitivity.

The polymer-bound acid generator used herein has the advantages of reduced acid diffusion and efficient acid generation because not only the anion moiety is attached to the polymer backbone, but also the nitro group is incorporated. Since the acid generator is admixed at the monomer stage prior to polymerization, the acid generator is uniformly distributed in the polymer. This leads to improvements in LWR and CDU.

The polymer-bound acid generator exerts a LWR or CDU-improving effect, which may stand good either in positive and negative tone pattern formation by aqueous alkaline development or in negative tone pattern formation by organic solvent development.

### Polymer-Bound Acid Generator

The polymer-bound acid generator used herein is a polymer comprising repeat units derived from a sulfonium or iodonium salt containing a polymerizable unsaturated bond and a fluorosulfonic acid site and having a nitro-substituted benzene ring in a linker between the polymerizable unsaturated bond and the fluorosulfonic acid site. Specifically, it is a polymer comprising repeat units having the formula (a1) or repeat units having the formula (a2). The repeat units having formulae (a1) and (a2) are also referred to as repeat units (a1) and (a2), respectively.

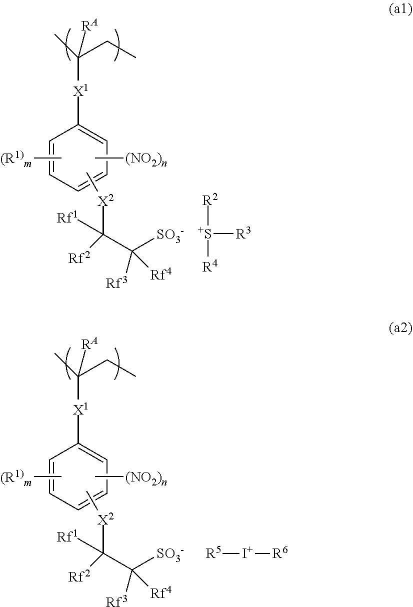

In formulae (a1) and (a2), R^{A} is hydrogen or methyl.

In formulae (a1) and (a2), X¹ is a single bond, ester bond, amide bond or —X^{1A}—X^{1C}—X^{1B}—. X^{1A} and X^{1B} are each independently a single bond, ether bond or ester bond. X^{1C} is a C₁-C₁₂ saturated hydrocarbylene group, C₆-C₁₀ arylene group or a combination thereof, wherein some constituent —CH₂— may be replaced by an ether bond, ester bond, amide bond, lactone ring-containing moiety or sultone ring-containing moiety, and some or all of the hydrogen atoms on the aromatic ring may be substituted by a C₁-C₄ alkyl moiety, C₁-C₄ alkyloxy moiety, C₂-C₅ alkylcarbonyloxy moiety, halogen or nitro moiety.

In formulae (a1) and (a2), X² is a single bond, ether bond, ester bond or —X^{2A}—X^{2C}—X^{2B}—. X^{2A} and X^{2B} are each independently a single bond, ether bond or ester bond. X^{2C} is a C₁-C₁₂ saturated hydrocarbylene group, C₆-C₁₀ arylene group or a combination thereof, wherein some constituent —CH₂— may be replaced by an ether bond, ester bond, amide bond, lactone ring-containing moiety or sultone ring-containing moiety, and some or all of the hydrogen atoms on the aromatic ring may be substituted by a C₁-C₄ alkyl moiety, C₁-C₄ alkyloxy moiety, C₂-C₅ alkylcarbonyloxy moiety, halogen or nitro moiety.

The C₁-C₁₂ saturated hydrocarbylene group represented by X^{1C} and X^{2C} may be straight, branched or cyclic. Examples thereof include C₁-C₁₂ alkanediyl groups such as methanediyl, ethane-1,1-diyl, ethane-1,2-diyl, propane-1,1-diyl, propane-1,2-diyl, propane-1,3-diyl, propane-2,2-diyl, butane-1,1-diyl, butane-1,2-diyl, butane-1,3-diyl, butane-2,3-diyl, butane-1,4-diyl, 1,1-dimethylethane-1,2-diyl, pentane-1,5-diyl, 2-methylbutane-1,2-diyl, hexane-1,6-diyl, heptane-1,7-diyl, octane-1,8-diyl, nonane-1,9-diyl, decane-1,10-diyl, undecane-1,11-diyl, and dodecane-1,12-diyl; C₃-C₁₂ cyclic saturated hydrocarbylene groups such as cyclopropane-1,2-diyl, cyclobutane-1,2-diyl, cyclobutane-1,3-diyl, cyclopentane-1,1-diyl, cyclopentane-1,2-diyl, cyclopentane-1,3-diyl, cyclohexane-1,2-diyl, cyclohexane-1,3-diyl, cyclohexane-1,4-diyl, adamantane-1,3-diyl, norbornane-2,3-diyl and norbornane-2,6-diyl; and combinations thereof. Examples of the C₆-C₁₀ arylene group represented by X^{1C} and X^{2C} include 1,2-phenylene, 1,3-phenylene, 1,4-phenylene, 1,3-naphthylene, 1,4-naphthylene, 1,5-naphthylene, 1,6-naphthylene, 1,7-naphthylene, 1,8-naphthylene, 2,6-naphthylene, and 2,7-naphthylene.

In formulae (a1) and (a2), Rf¹ to Rf⁴ are each independently hydrogen, fluorine or trifluoromethyl, at least one of Rf¹ to Rf⁴ being fluorine or trifluoromethyl. Rf¹ and Rf², taken together, may form a carbonyl group.

In formulae (a1) and (a2), R¹ is a C₁-C₄ alkyl group, C₁-C₄ alkyloxy group, C₂-C₅ alkylcarbonyloxy group or halogen. Examples of the alkyl group and alkyl moiety in the alkyloxy group and alkylcarbonyloxy group include methyl, ethyl, n-propyl, isopropyl, n-butyl, isobutyl, sec-butyl, and tert-butyl. Suitable halogen atoms include fluorine, chlorine, bromine and iodine.

Examples of the anion in the monomer from which repeat units (a1) or (a2) are derived are shown below, but not limited thereto.

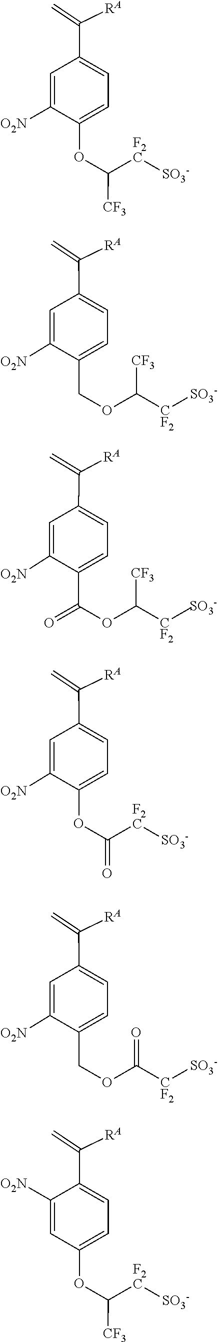

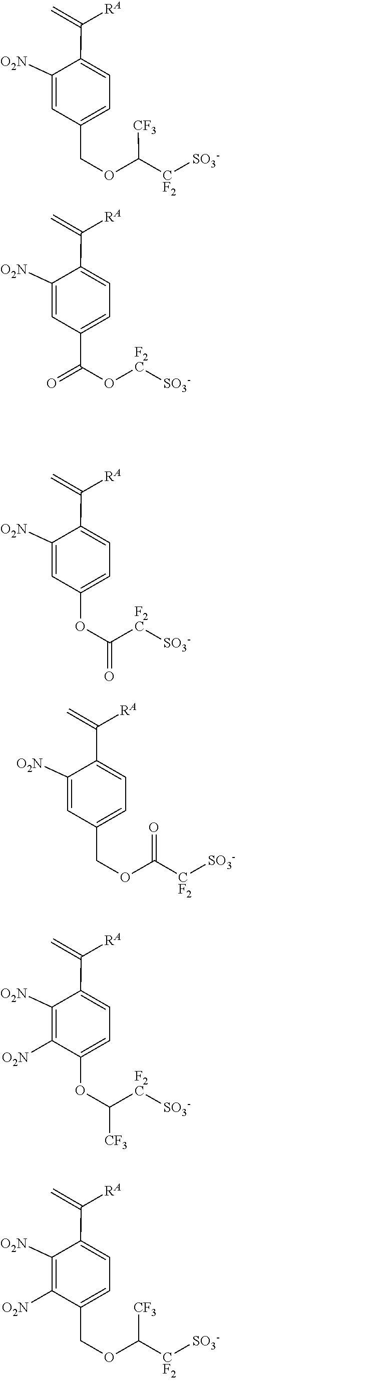

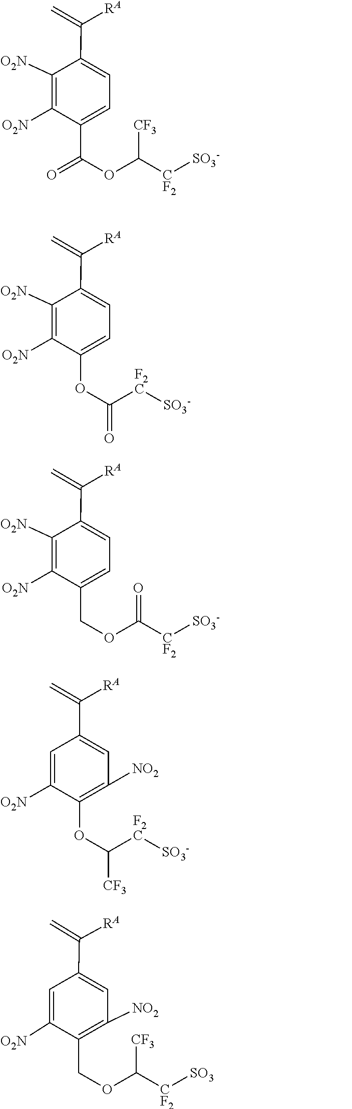

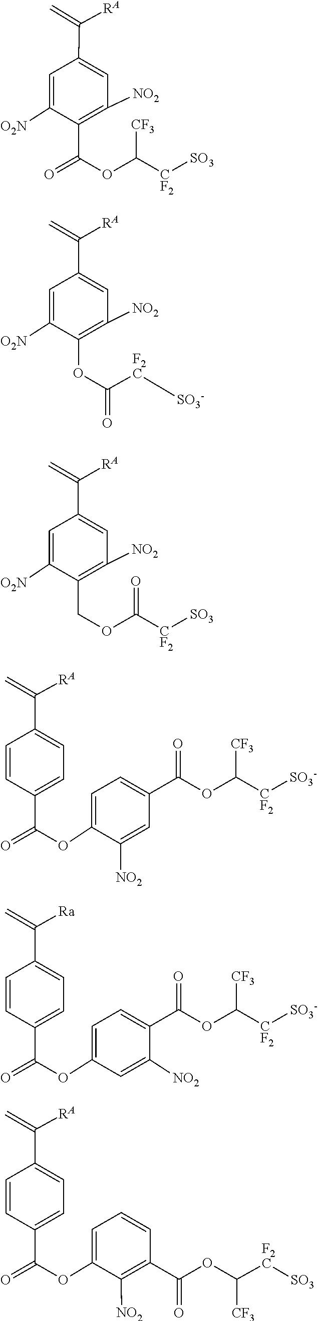

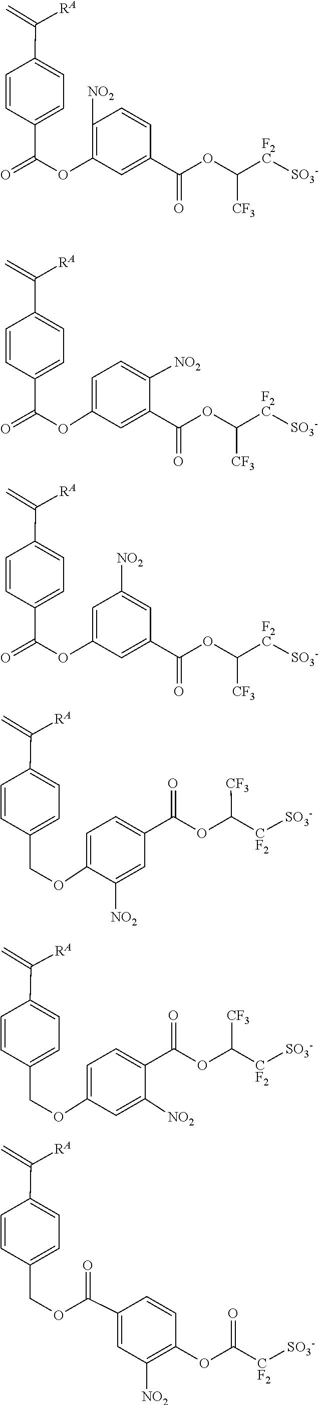

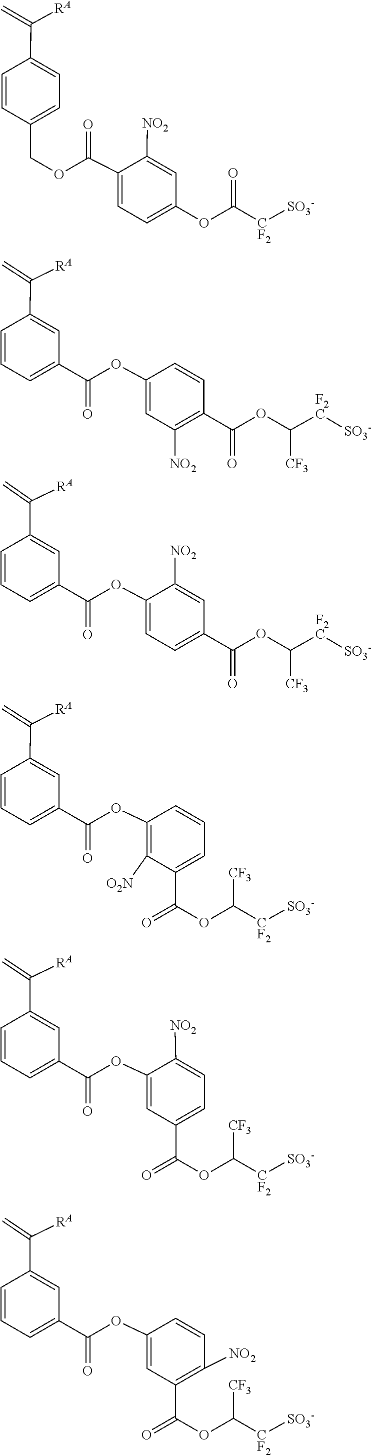

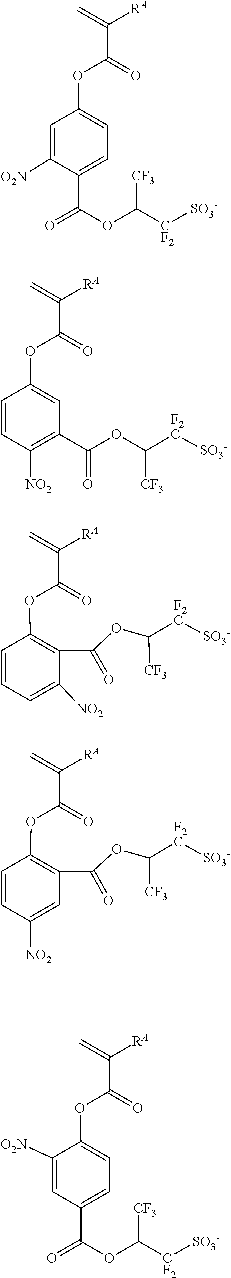

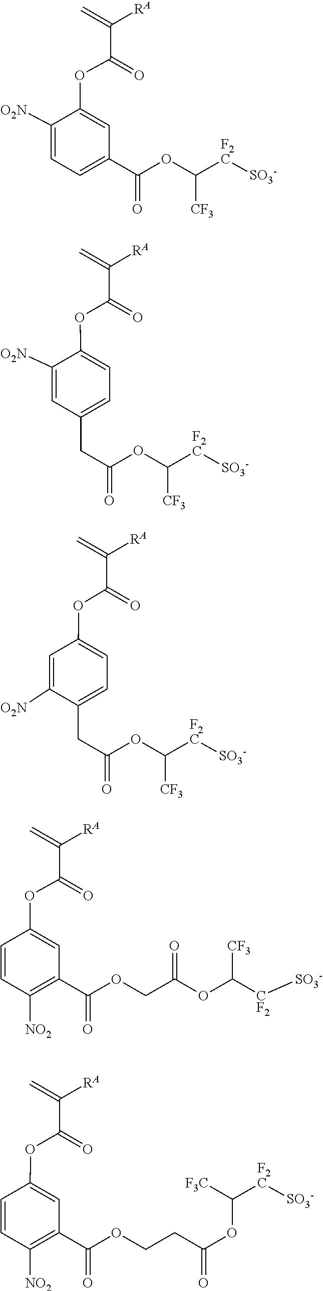

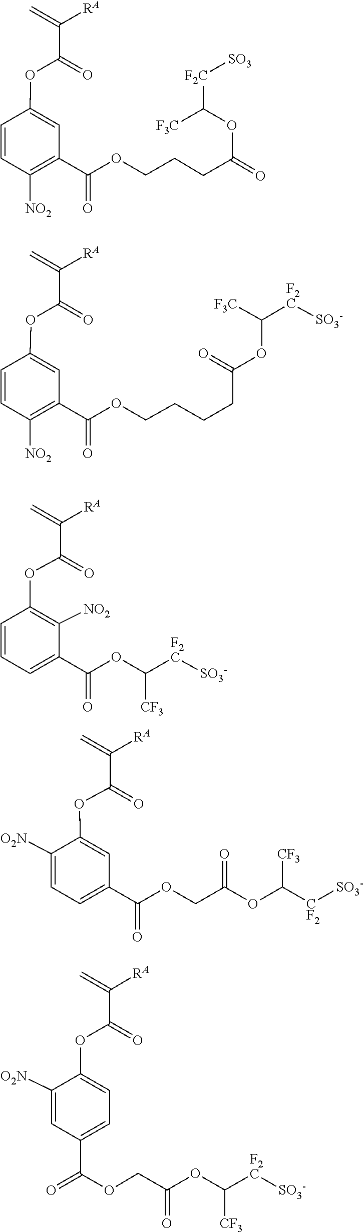

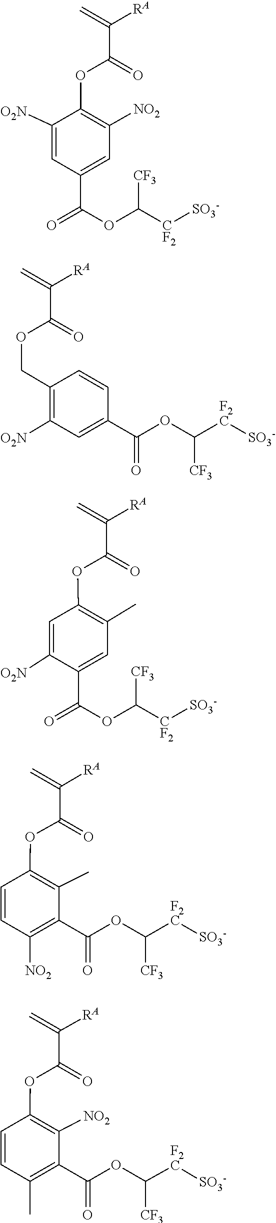

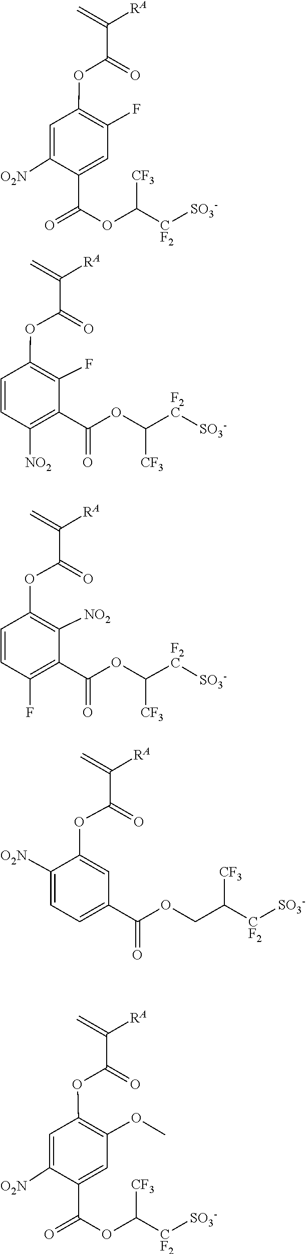

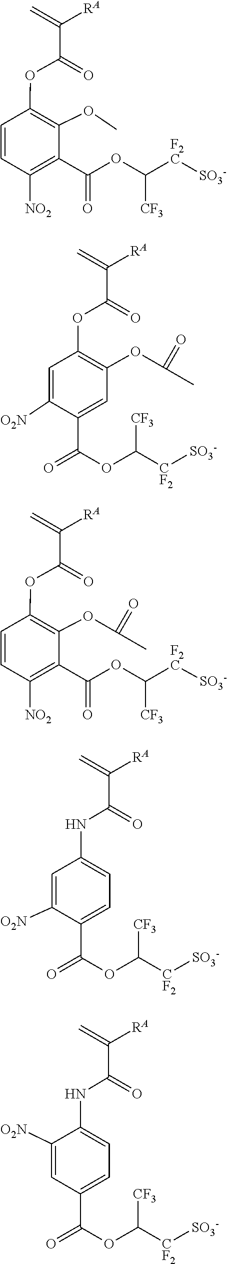

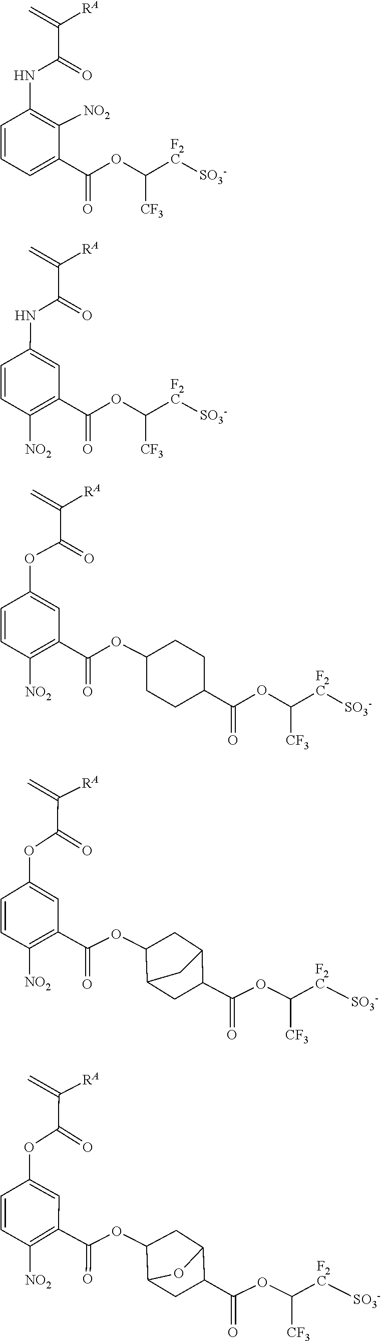

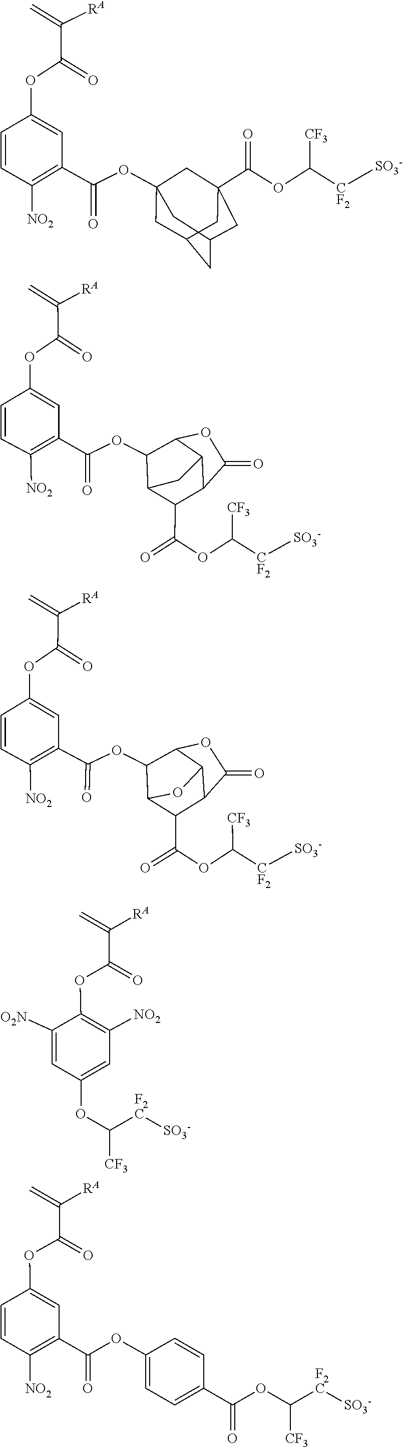

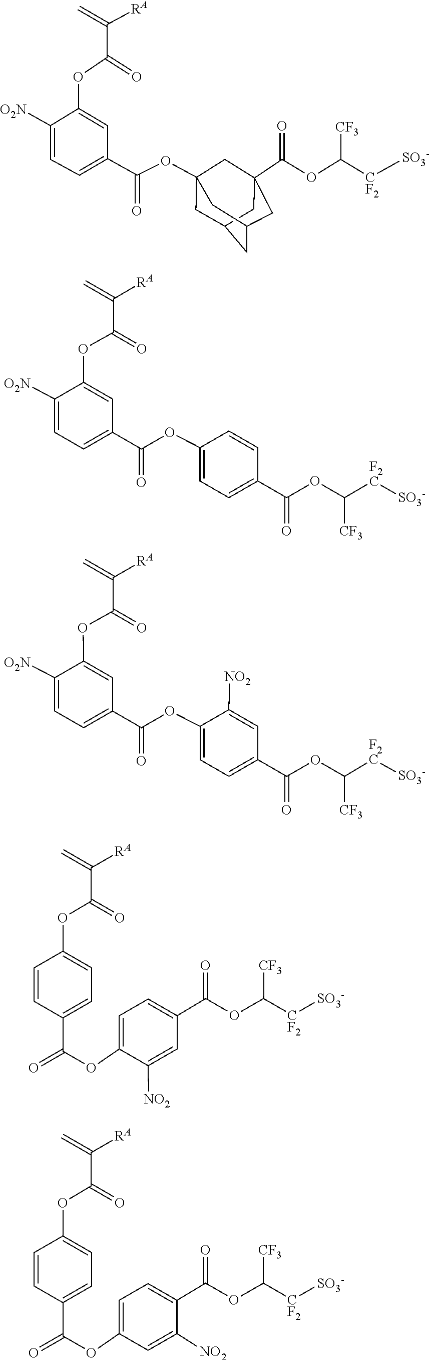

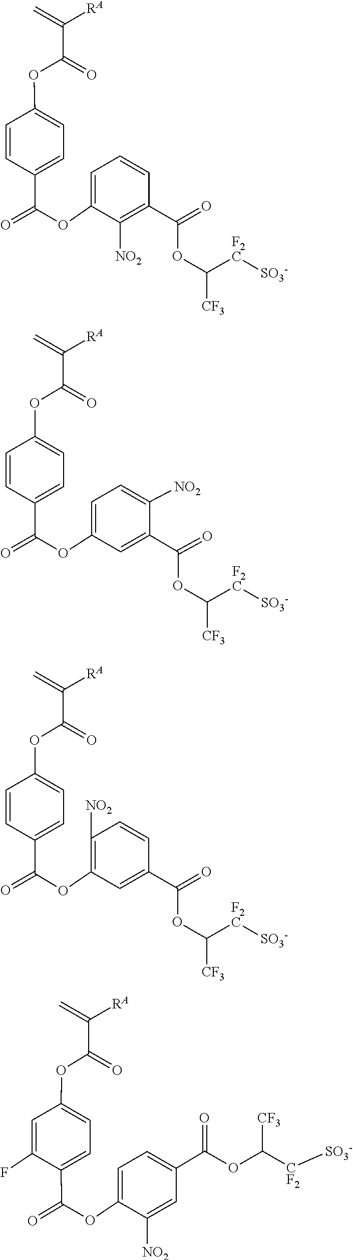

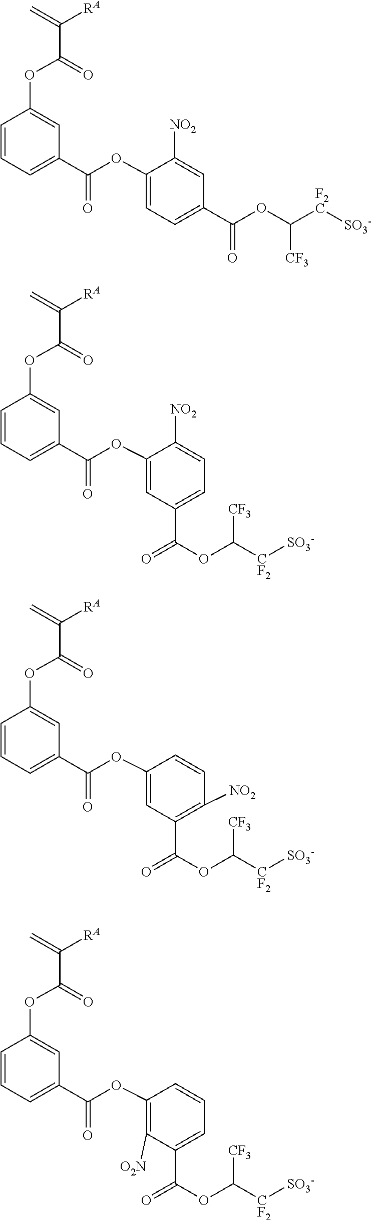

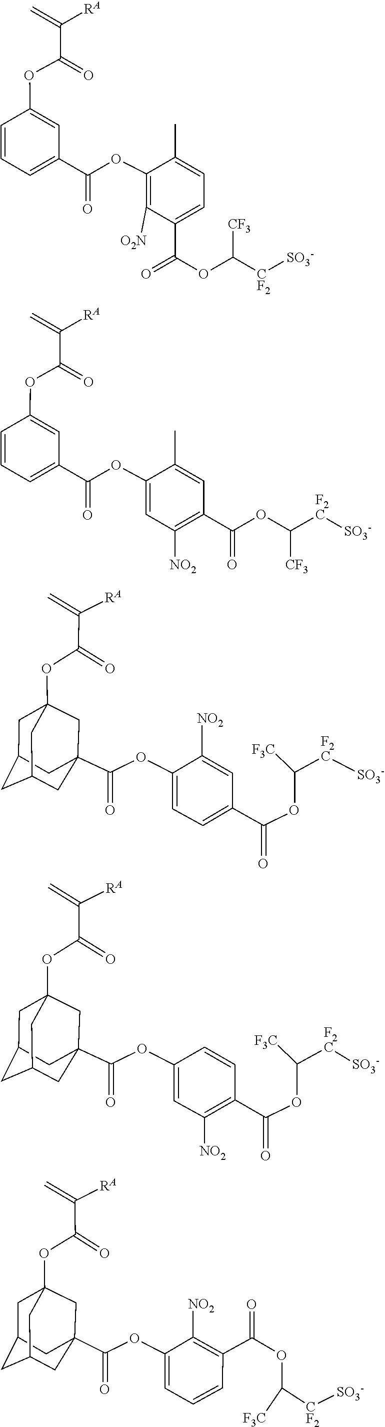

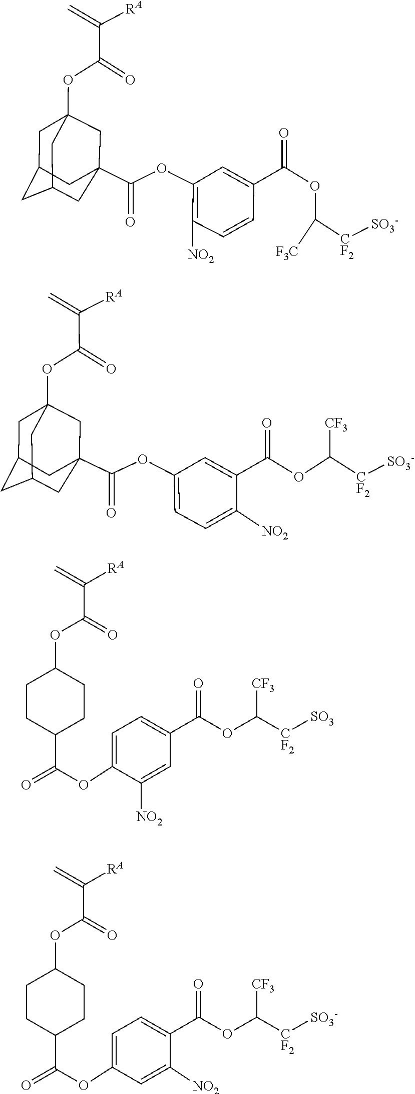

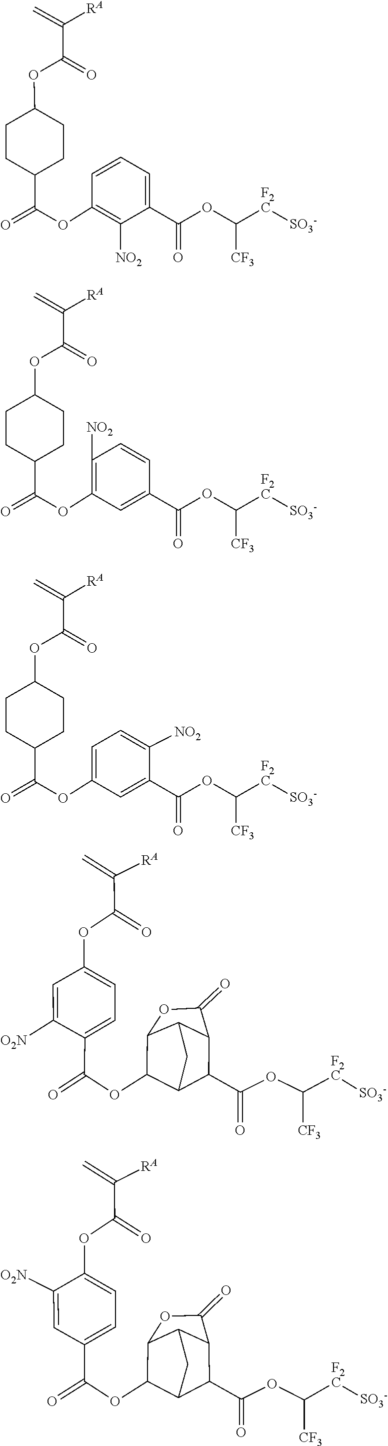

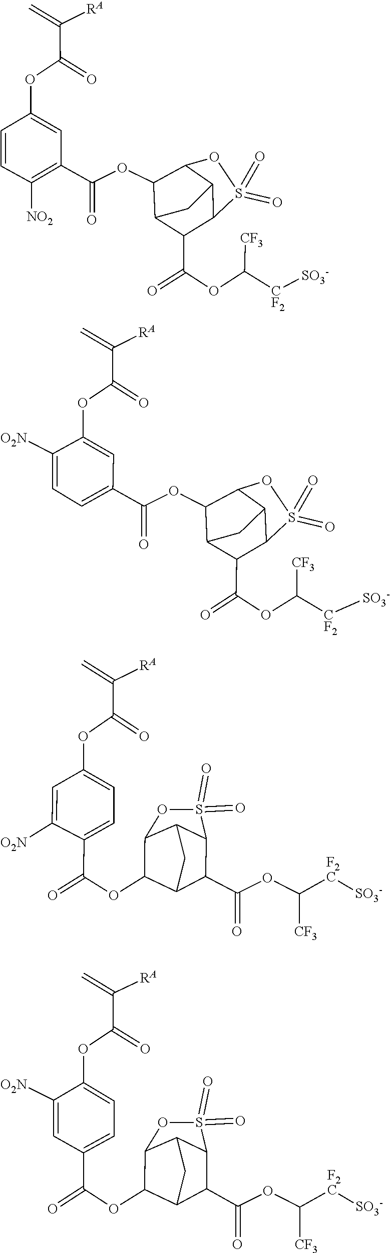

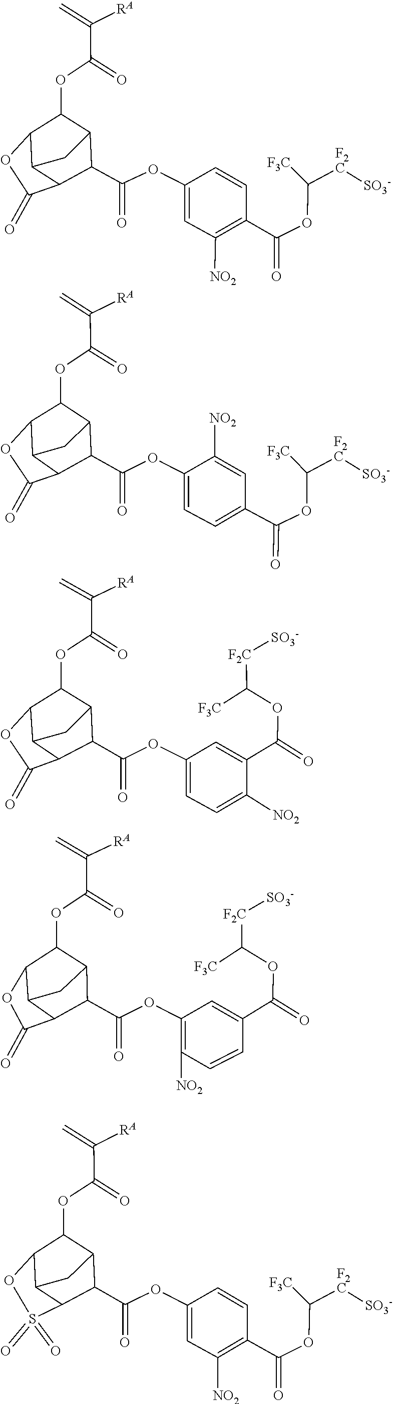

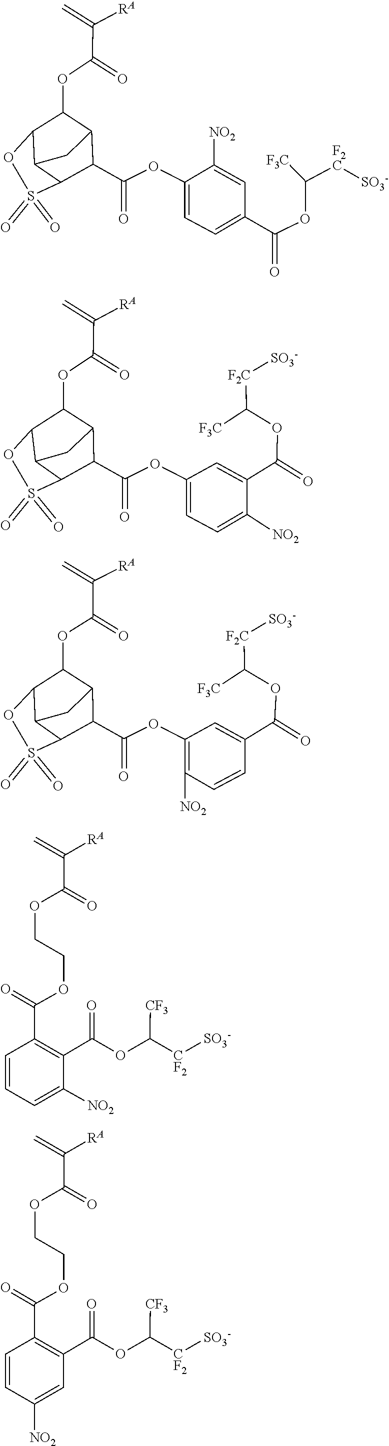

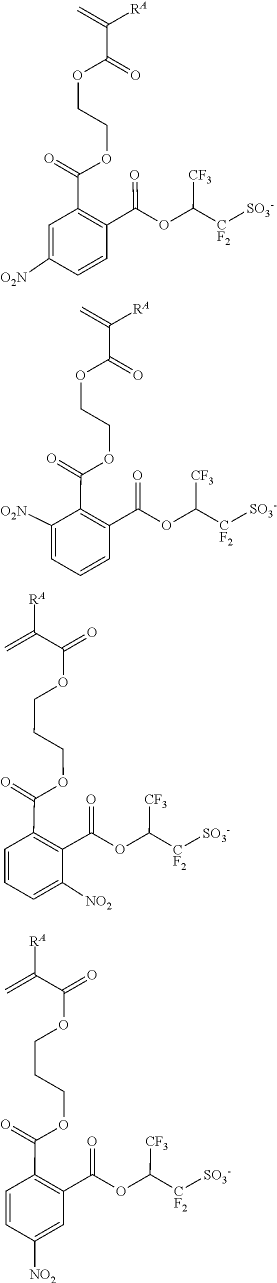

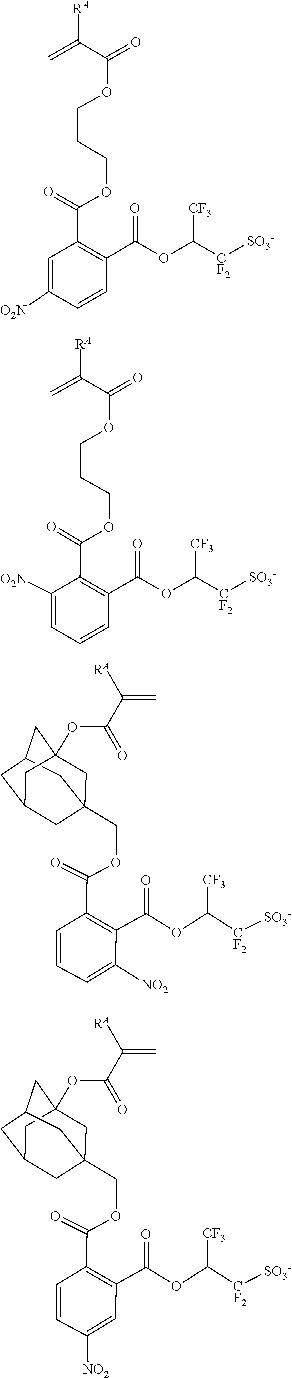

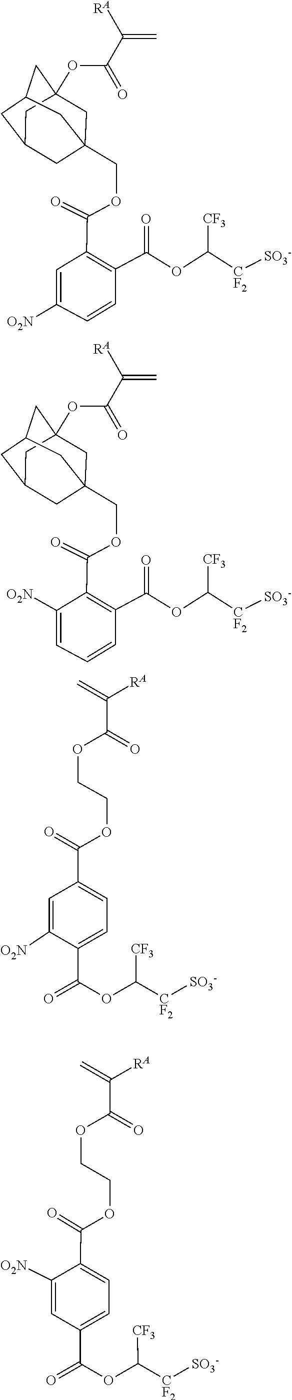

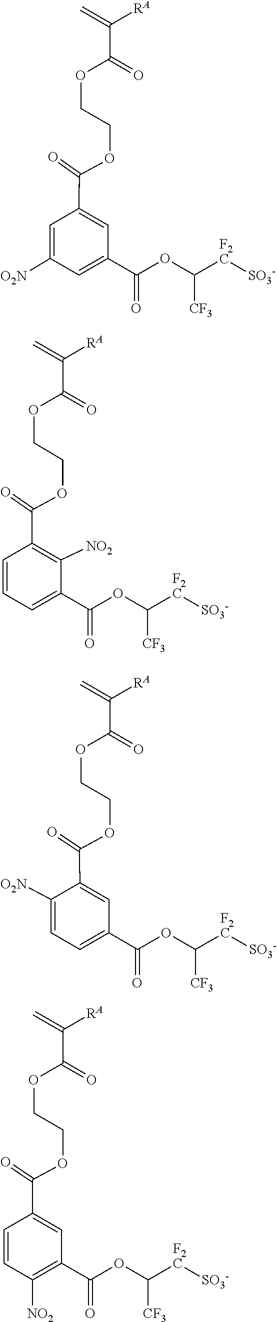

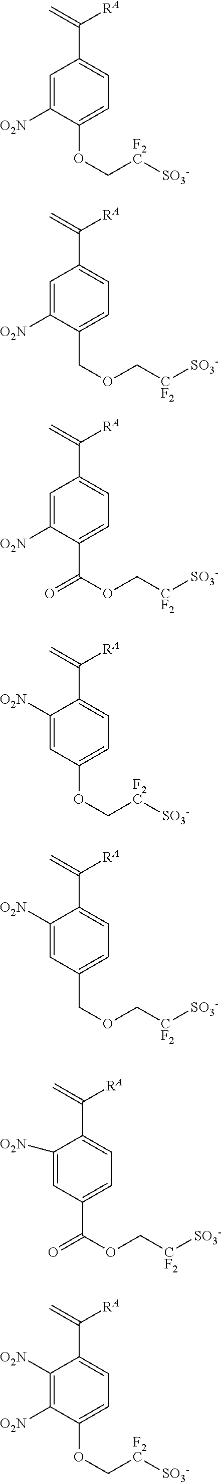

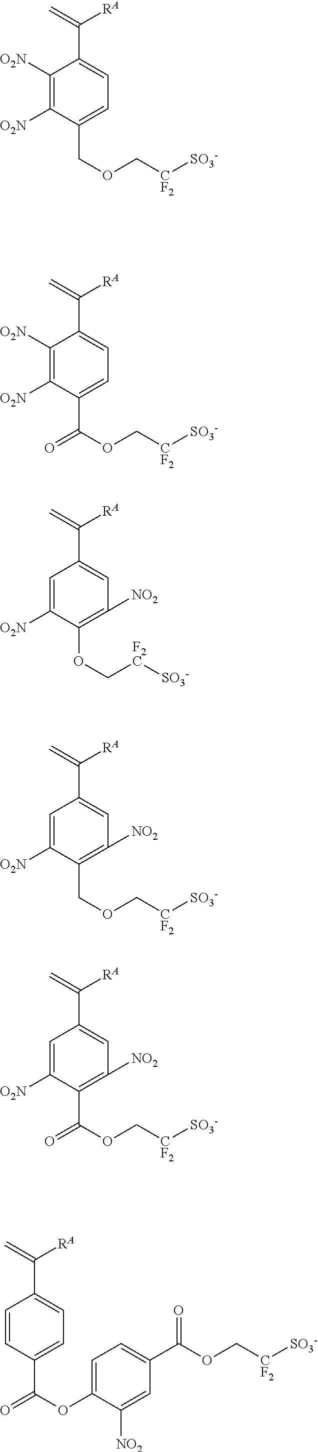

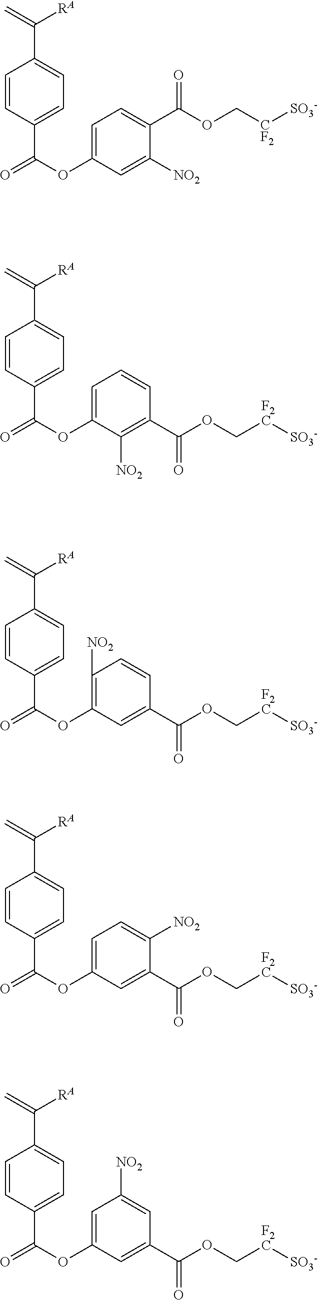

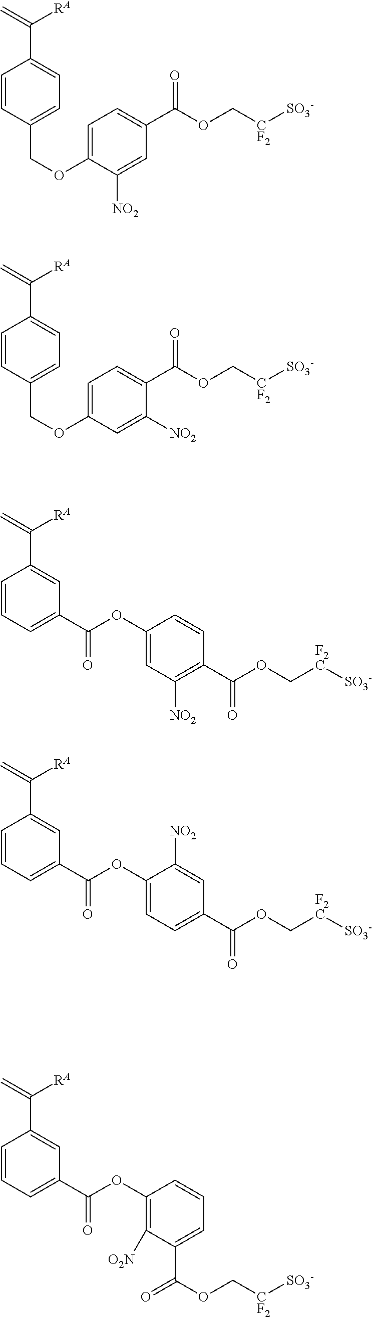

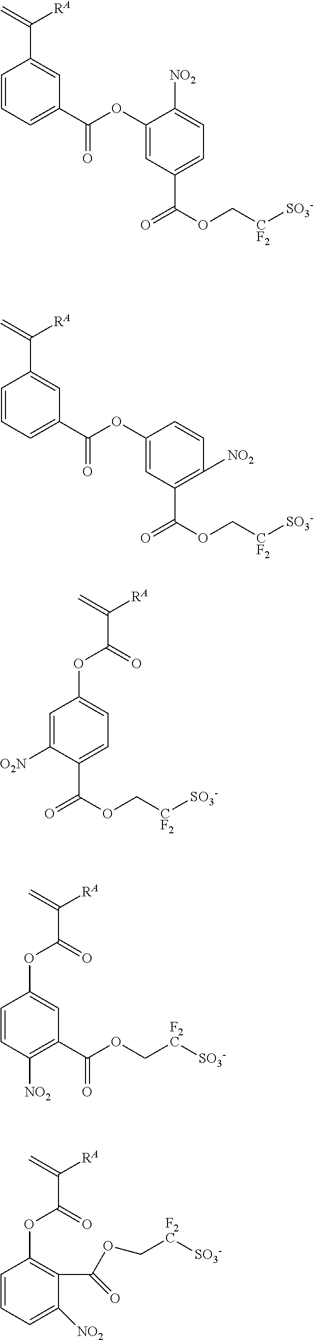

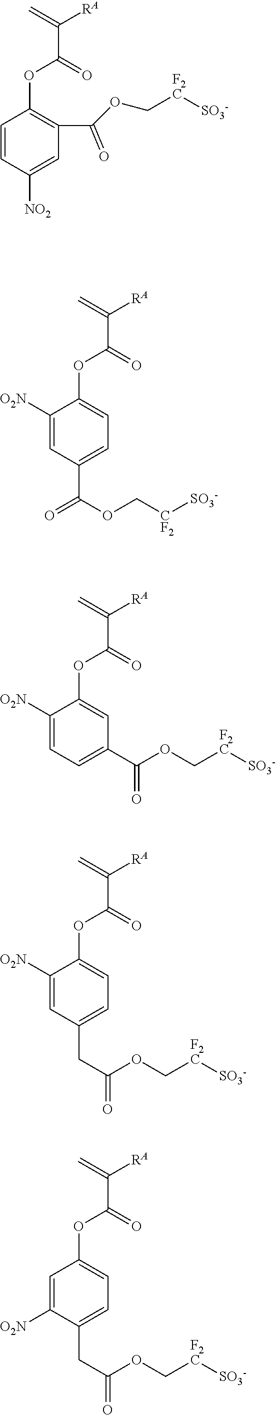

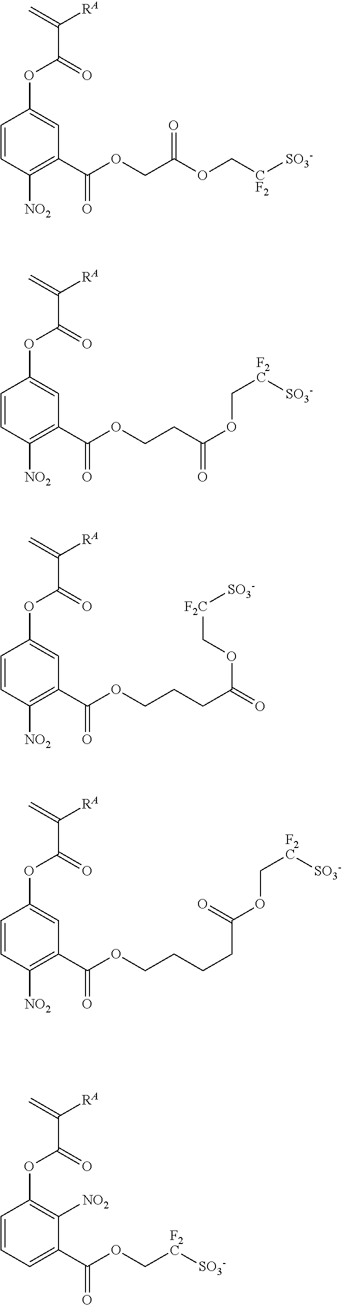

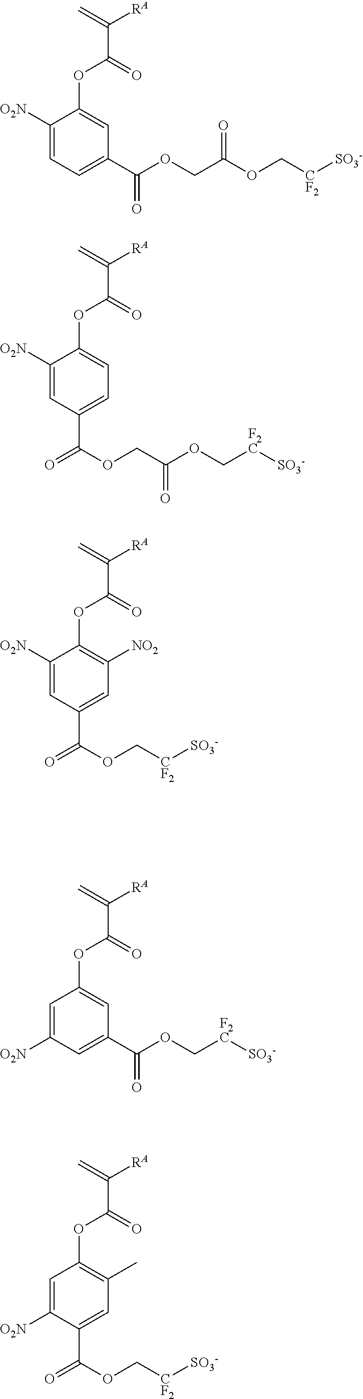

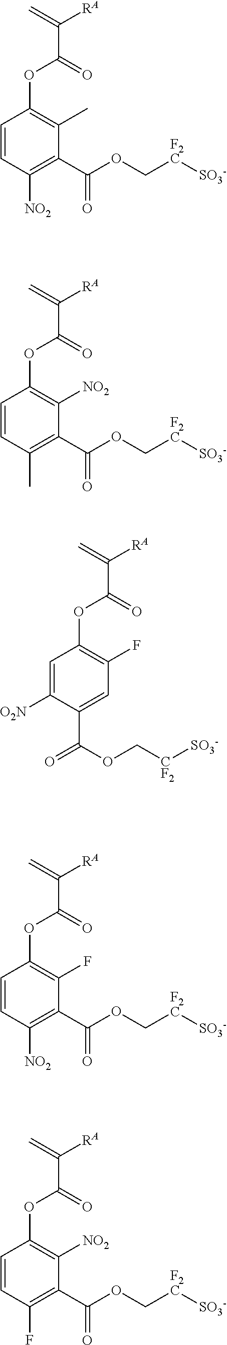

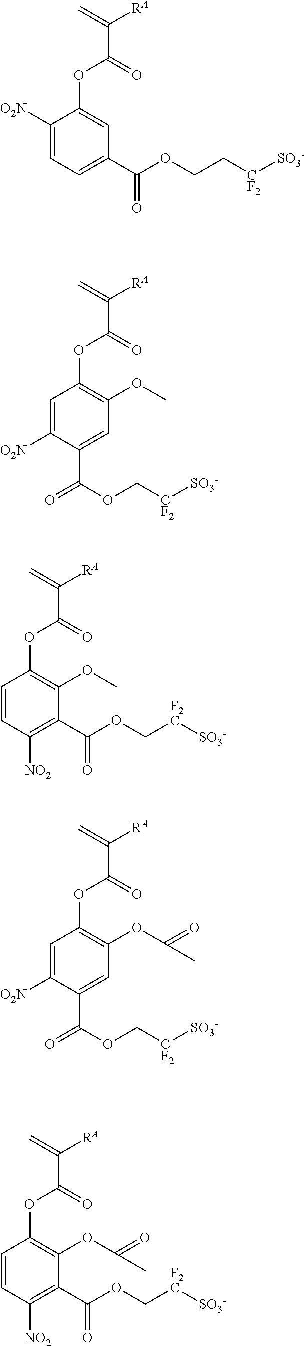

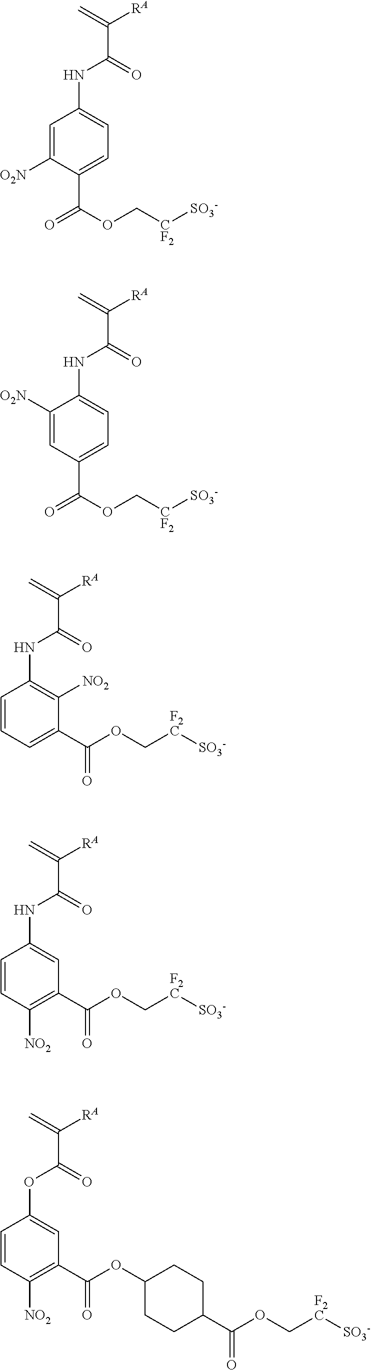

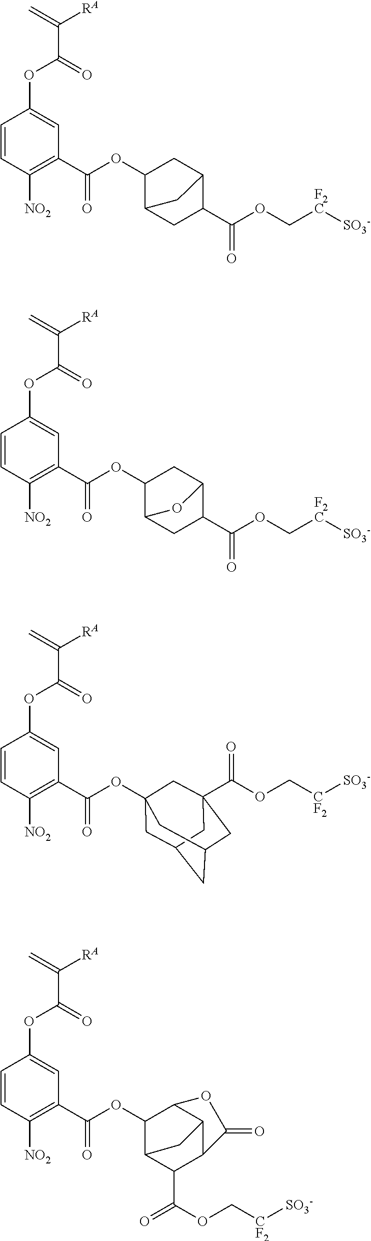

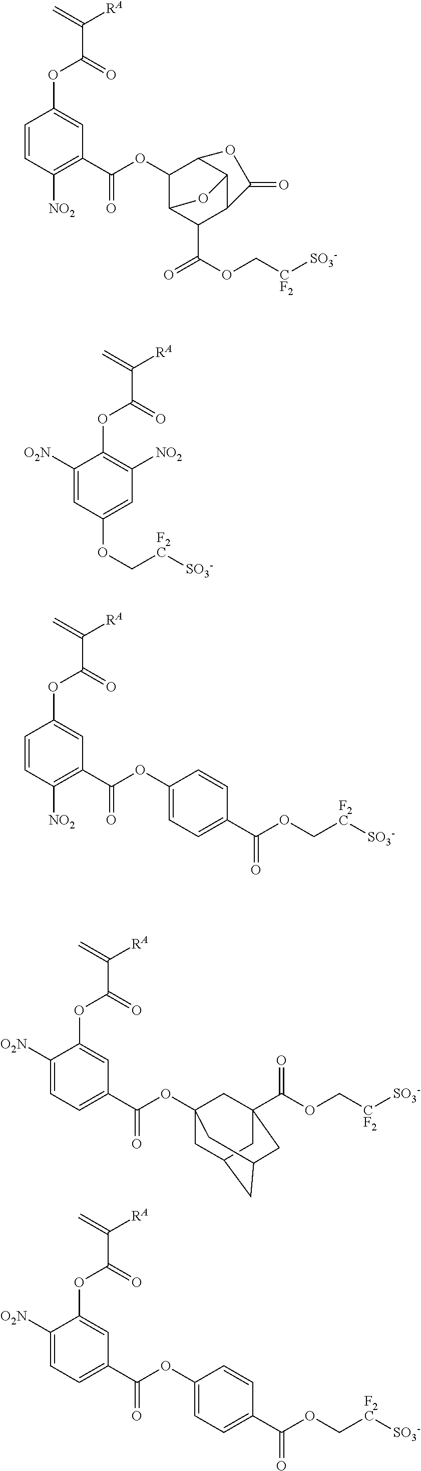

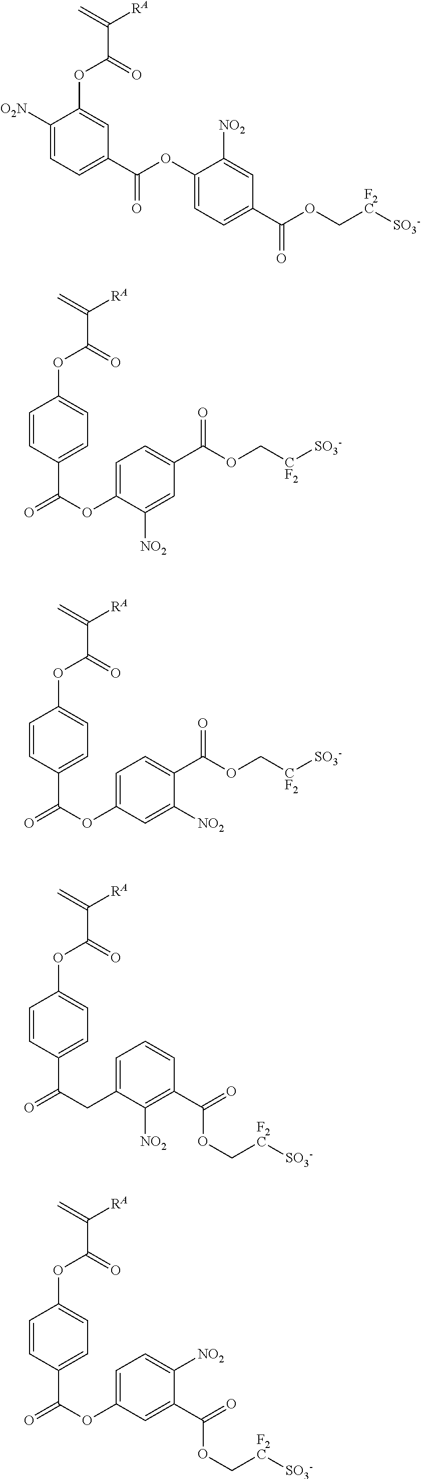

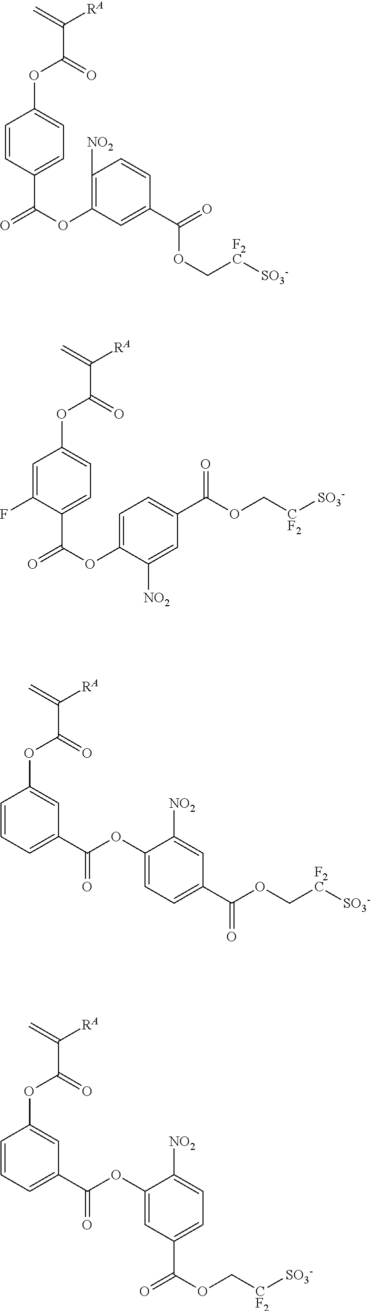

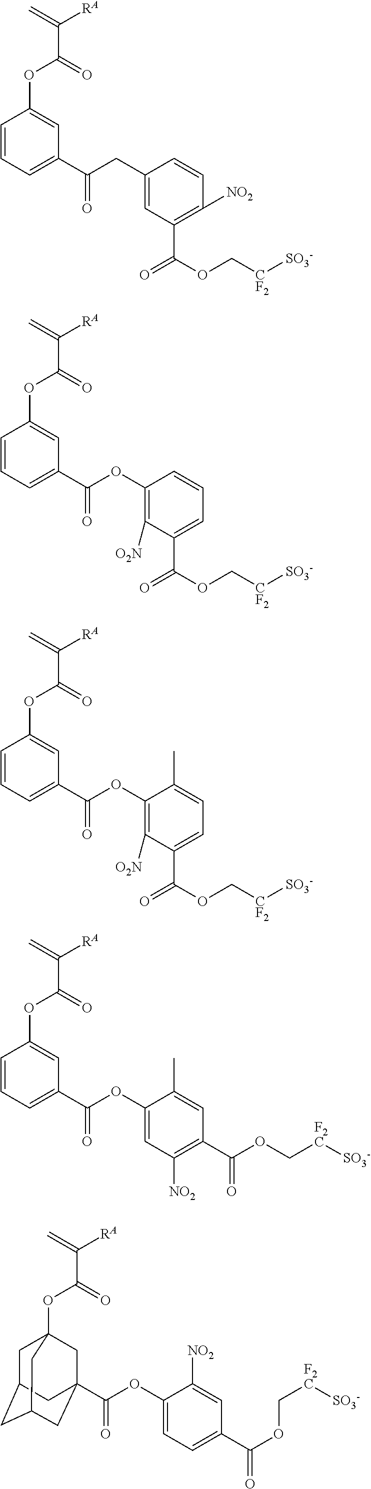

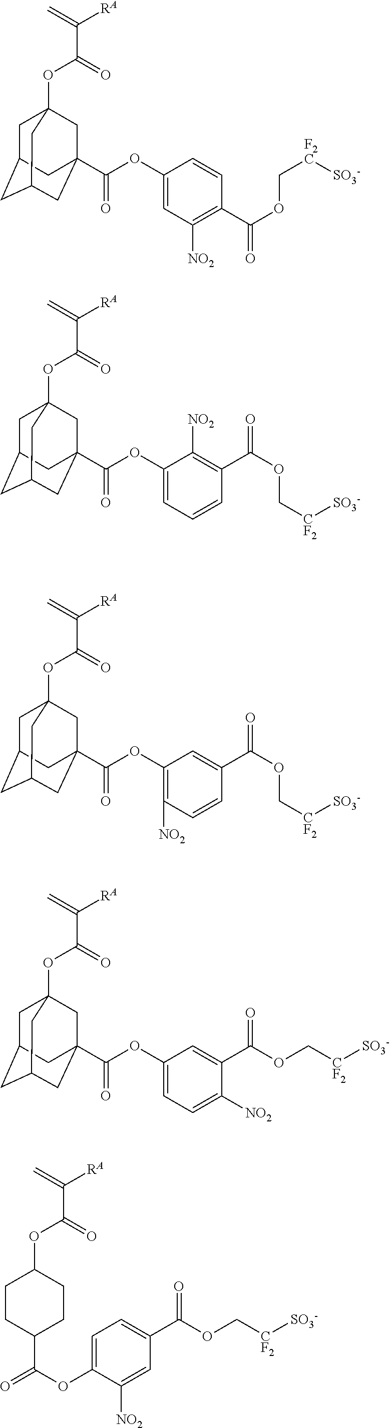

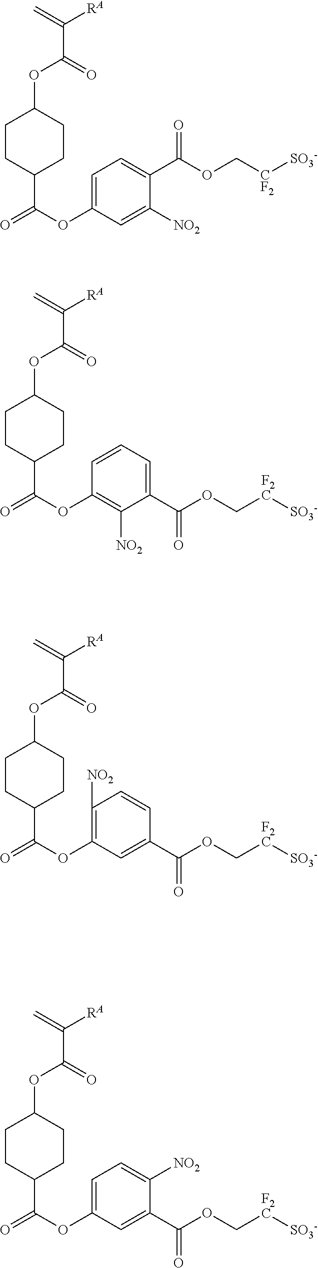

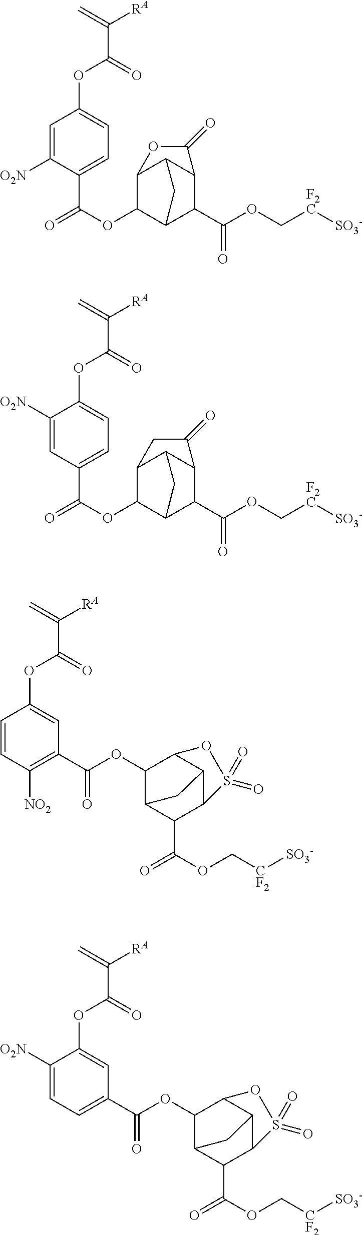

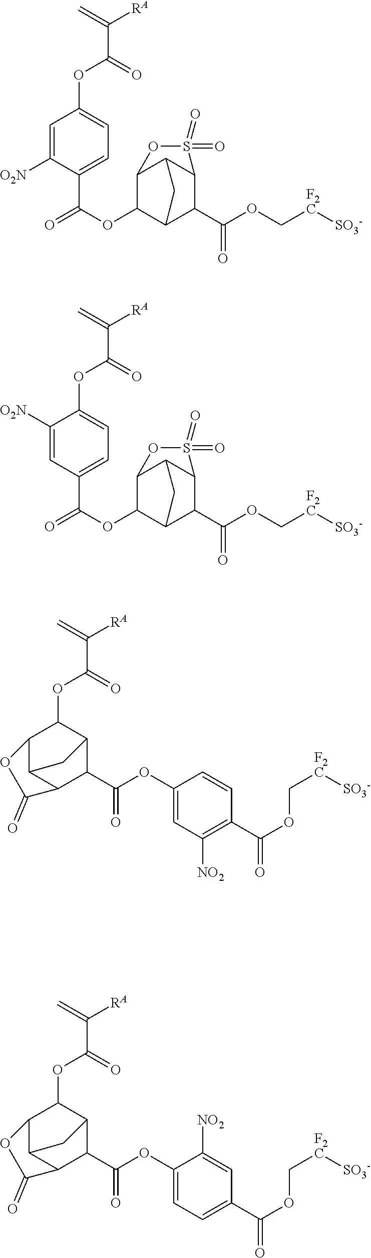

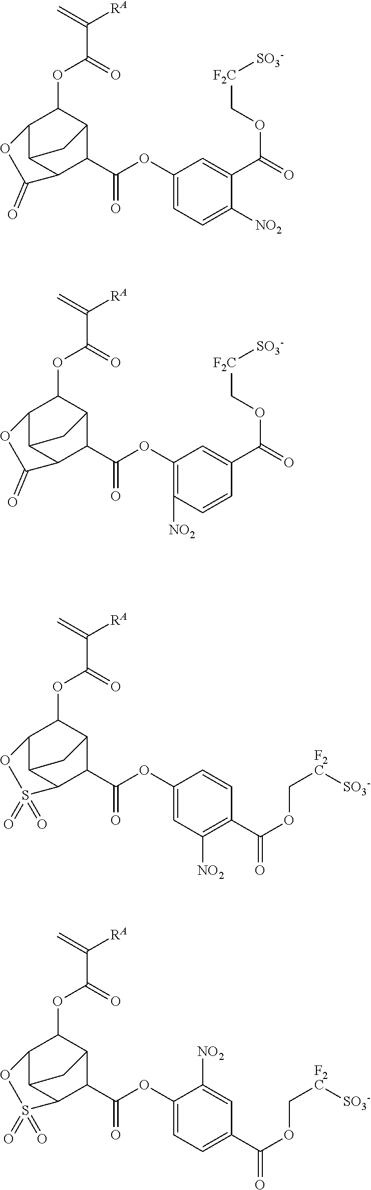

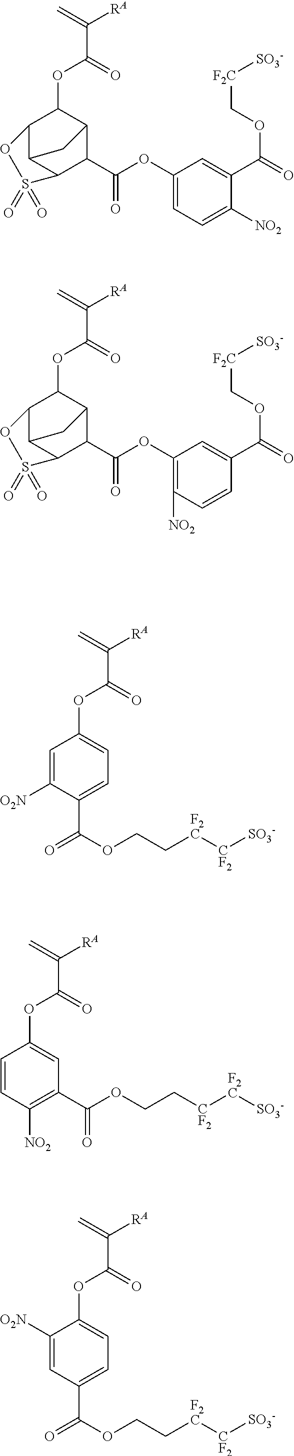

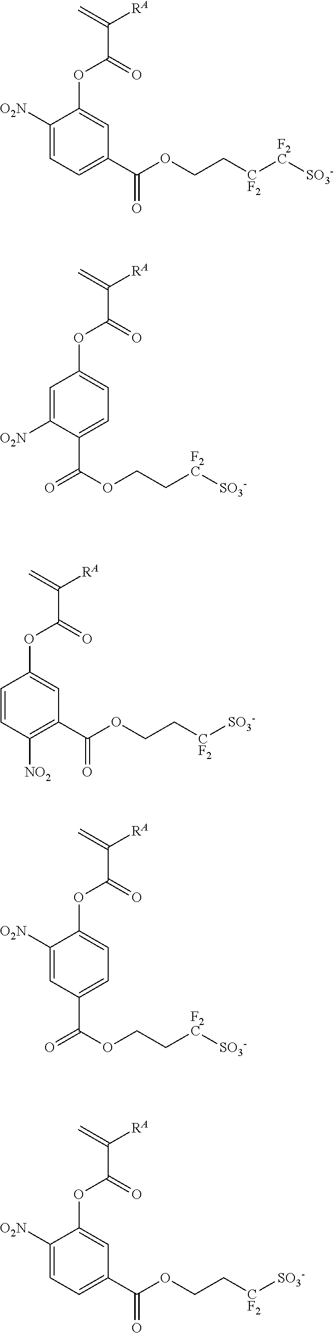

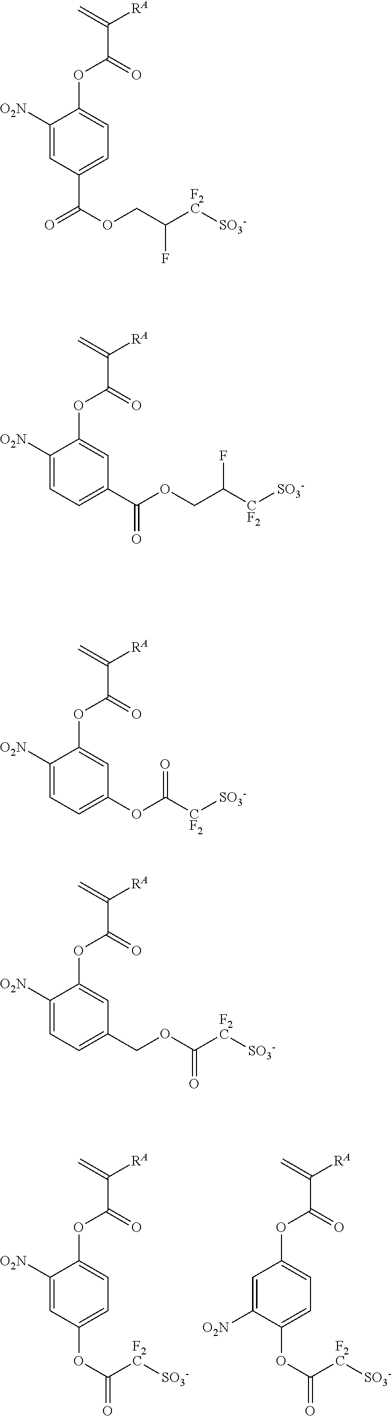

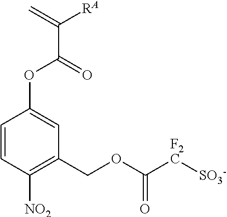

In formulae (a1) and (a2), R² to R⁶ are each independently halogen or a C₁-C₂₀ hydrocarbyl group which may contain a heteroatom.

Suitable halogen atoms represented by R² to R⁶ include fluorine, chlorine, bromine and iodine.

The hydrocarbyl group represented by R² to R⁶ may be saturated or unsaturated and straight, branched or cyclic. Examples thereof include C₁-C₂₀ alkyl groups such as methyl, ethyl, n-propyl, isopropyl, n-butyl, isobutyl, sec-butyl, tert-butyl, n-pentyl, n-hexyl, n-octyl, n-nonyl, n-decyl, undecyl, dodecyl, tridecyl, tetradecyl, pentadecyl, heptadecyl, octadecyl, nonadecyl and icosyl; C₃-C₂₀ cyclic saturated hydrocarbyl groups such as cyclopropyl, cyclopentyl, cyclohexyl, cyclopropylmethyl, 4-methylcyclohexyl, cyclohexylmethyl, norbornyl, and adamantyl; C₂-C₂₀ alkenyl groups such as vinyl, propenyl, butenyl, and hexenyl; C₃-C₂₀ cyclic unsaturated aliphatic hydrocarbyl groups such as cyclohexenyl and norbornenyl; C₂-C₂₀ alkynyl groups such as ethynyl, propynyl and butynyl; C₆-C₂₀ aryl groups such as phenyl, methylphenyl, ethylphenyl, n-propylphenyl, isopropylphenyl, n-butylphenyl, isobutylphenyl, sec-butylphenyl, tert-butylphenyl, naphthyl, methylnaphthyl, ethylnaphthyl, n-propylnaphthyl, isopropylnaphthyl, n-butylnaphthyl, isobutylnaphthyl, sec-butylnaphthyl, and tert-butylnaphthyl; C₇-C₂₀ aralkyl groups such as benzyl and phenethyl; and combinations thereof. In the hydrocarbyl groups, some or all of the hydrogen atoms may be substituted by a moiety containing a heteroatom such as oxygen, sulfur, nitrogen or halogen, or some constituent —CH₂— may be replaced by a moiety containing a heteroatom such as oxygen, sulfur or nitrogen, so that the group may contain a hydroxy moiety, fluorine, chlorine, bromine, iodine, cyano moiety, nitro moiety, carbonyl moiety, ether bond, ester bond, sulfonic ester bond, carbonate bond, lactone ring, sultone ring, carboxylic anhydride (—C(═O)—O—C(═O)—) or haloalkyl moiety.

Also, R² and R³ may bond together to form a ring with the sulfur atom to which they are attached. Preferred examples of the ring are shown by the following structures.

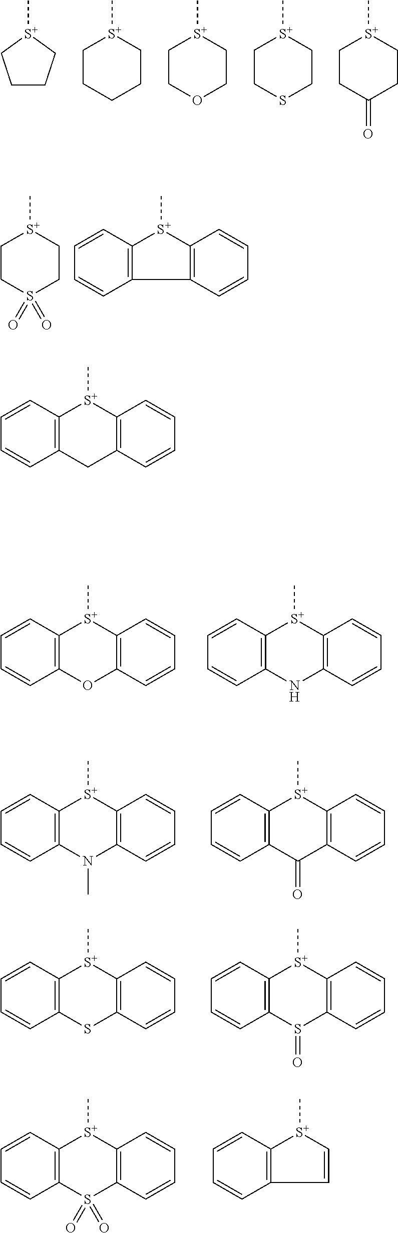

Herein the broken line designates a point of attachment to R⁴.

Preferred examples of the sulfonium cation in repeat unit (a1) include those having the formula (M-1) or (M-2). Preferred examples of the iodonium cation in repeat unit (a2) include those having the formula (M-3).

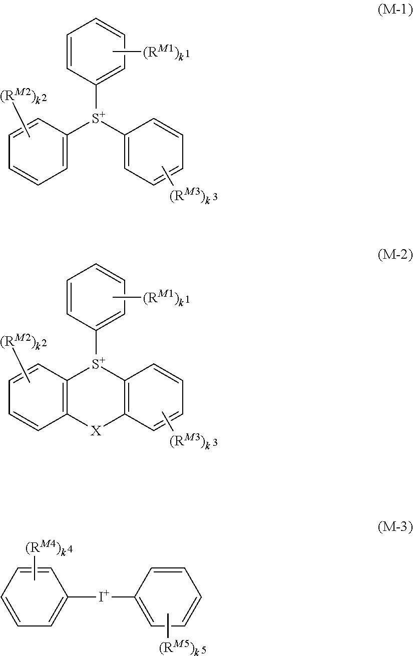

In formulae (M-1) to (M-3), R^{M1}, R^{M2}, R^{M3}, R^{M4} and R^{M5} are each independently halogen, hydroxy, nitro, cyano, carboxy, C₁-C₁₄ hydrocarbyl group, C₁-C₁₄ hydrocarbyloxy group, C₂-C₁₄ hydrocarbylcarbonyl group, C₂-C₁₄ hydrocarbylcarbonyloxy group, C₂-C₁₄ hydrocarbyloxycarbonyl group, or C₁-C₁₄ hydrocarbylthio group.

Suitable halogen atoms include fluorine, chlorine, bromine and iodine.

The C₁-C₁₄ hydrocarbyl group and hydrocarbyl moiety in the C₁-C₁₄ hydrocarbyloxy group, C₂-C₁₄ hydrocarbylcarbonyl group, C₂-C₁₄ hydrocarbylcarbonyloxy group, C₂-C₁₄ hydrocarbyloxycarbonyl group, and C₁-C₁₄ hydrocarbylthio group may be saturated or unsaturated and straight, branched or cyclic. Examples thereof include alkyl groups such as methyl, ethyl, propyl, isopropyl, n-butyl, sec-butyl, tert-butyl, n-pentyl, n-hexyl, n-octyl, 2-ethylhexyl, n-nonyl, and n-decyl; cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decanyl, adamantyl, and adamantylmethyl; alkenyl groups such as vinyl, allyl, propenyl, butenyl, and hexenyl; cyclic unsaturated aliphatic hydrocarbyl groups such as cyclohexenyl; aryl groups such as phenyl, naphthyl, thienyl, 4-hydroxyphenyl, 4-methoxyphenyl, 3-methoxyphenyl, 2-methoxyphenyl, 4-ethoxyphenyl, 4-tert-butoxyphenyl, 3-tert-butoxyphenyl, 2-methylphenyl, 3-methylphenyl, 4-methylphenyl, 4-ethylphenyl, 4-tert-butylphenyl, 4-n-butylphenyl, 2,4-dimethylphenyl, 2,4,6-triisopropylphenyl, methylnaphthyl, ethylnaphthyl, methoxynaphthyl, ethoxynaphthyl, n-propoxynaphthyl, n-butoxynaphthyl, dimethylnaphthyl, diethylnaphthyl, dimethoxynaphthyl, and diethoxynaphthyl; and aralkyl groups such as benzyl, 1-phenylethyl and 2-phenylethyl.

Some or all of the hydrogen atoms in the hydrocarbyl group may be substituted by a moiety containing a heteroatom such as oxygen, sulfur, nitrogen or halogen so that the group may contain a hydroxy moiety, cyano moiety, fluorine, chlorine, bromine, iodine, or haloalkyl moiety. Some constituent —CH₂— in the hydrocarbyl group may be replaced by —O—, —C(═O)—, —S—, —S(═O)—, —S(═O)₂— or —N(R^{N})—. R^{N} is hydrogen or a C₁-C₁₀ hydrocarbyl group in which some hydrogen may be substituted by a moiety containing a heteroatom such as oxygen, sulfur, nitrogen or halogen so that the group may contain a hydroxy moiety, cyano moiety, fluorine, chlorine, bromine, iodine, or haloalkyl moiety, and some constituent —CH₂— may be replaced by —O—, —C(═O)—, or —S(═O)₂—.

In formula (M-2), X is a single bond, —CH₂—, —O—, —C(═O)—, —S—, —S(═O)—, —S(═O)₂—, or —N(R^{N})— wherein R^{N} is as defined above.

In formulae (M-1) to (M-3), k¹, k², k³, k⁴ and k⁵ are each independently an integer of 0 to 5. When k¹ is 2 or more, groups R^{M1} may be identical or different, and two R¹ may bond together to form a ring with the carbon atoms on the benzene ring to which they are attached. When k² is 2 or more, groups R^{M2} may be identical or different, and two R^{M2} may bond together to form a ring with the carbon atoms on the benzene ring to which they are attached. When k³ is 2 or more, groups R^{M3} may be identical or different, and two R^{M3} may bond together to form a ring with the carbon atoms on the benzene ring to which they are attached. When k⁴ is 2 or more, groups R^{M4} may be identical or different, and two R^{M4} may bond together to form a ring with the carbon atoms on the benzene ring to which they are attached. When k⁵ is 2 or more, groups R^{M5} may be identical or different, and two R^{M5} may bond together to form a ring with the carbon atoms on the benzene ring to which they are attached.

Examples of the sulfonium cation in repeat unit (a1) are shown below, but not limited thereto.

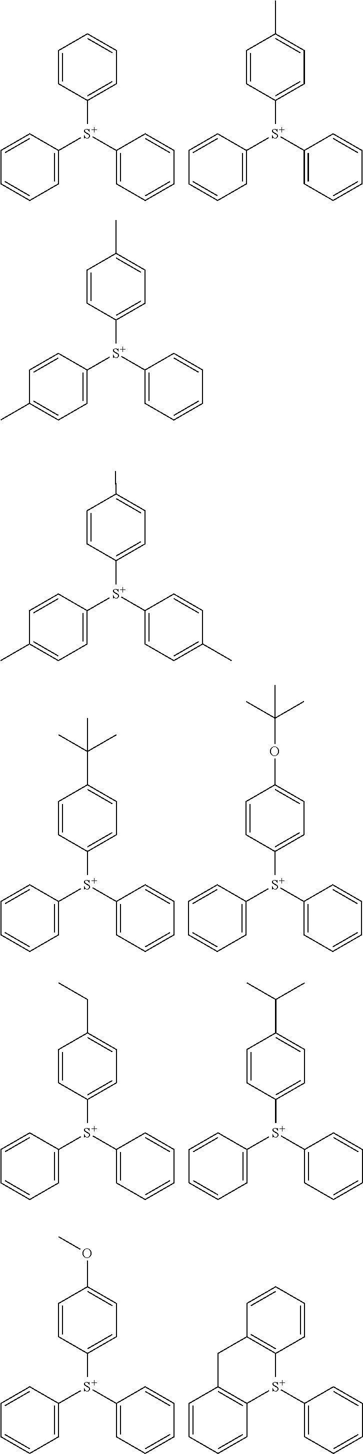

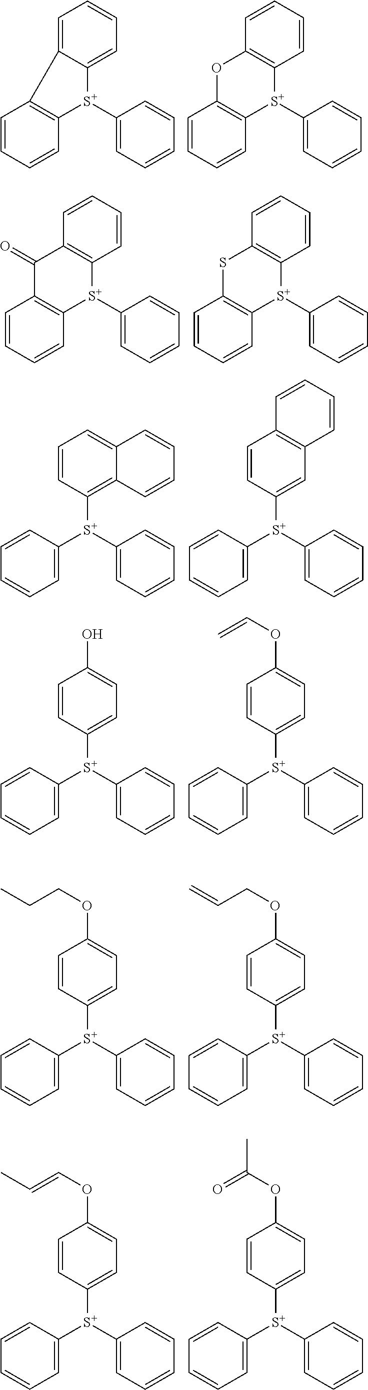

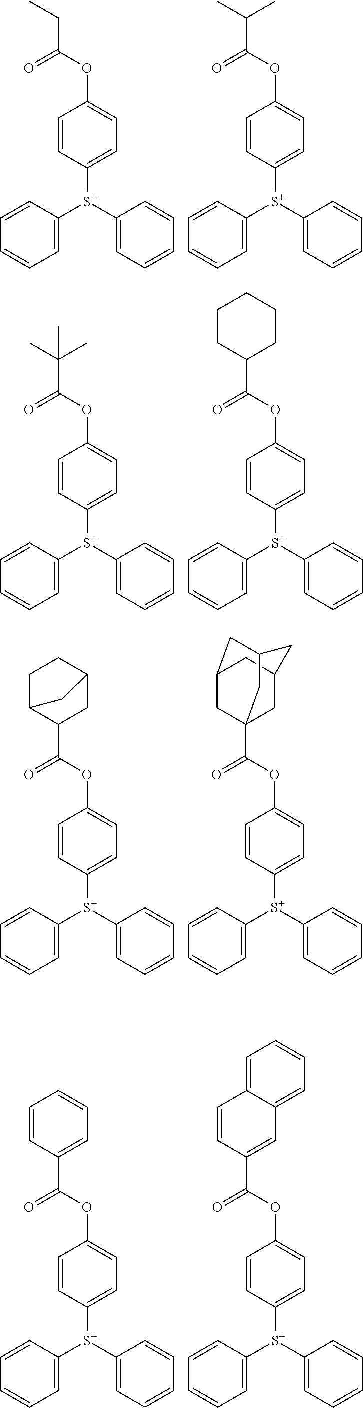

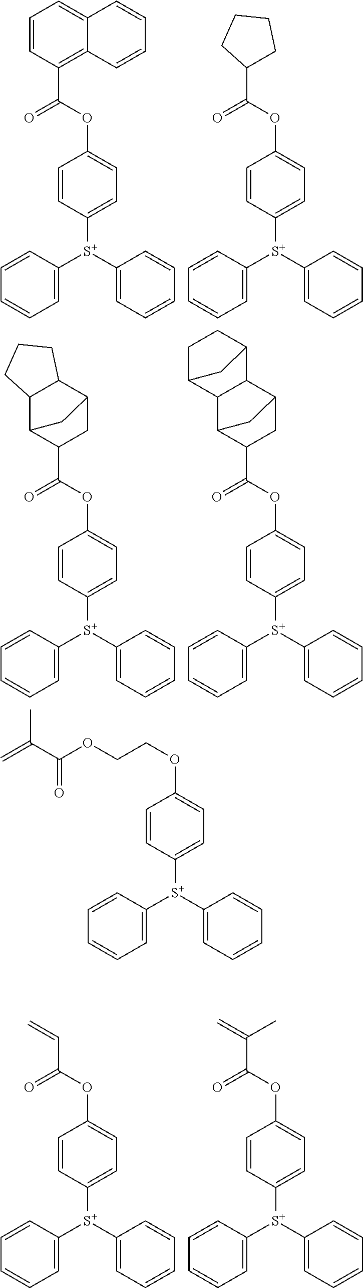

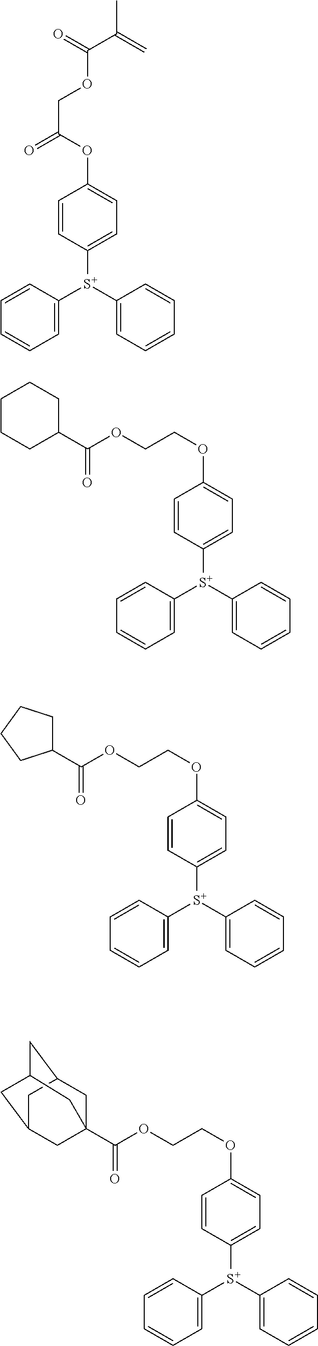

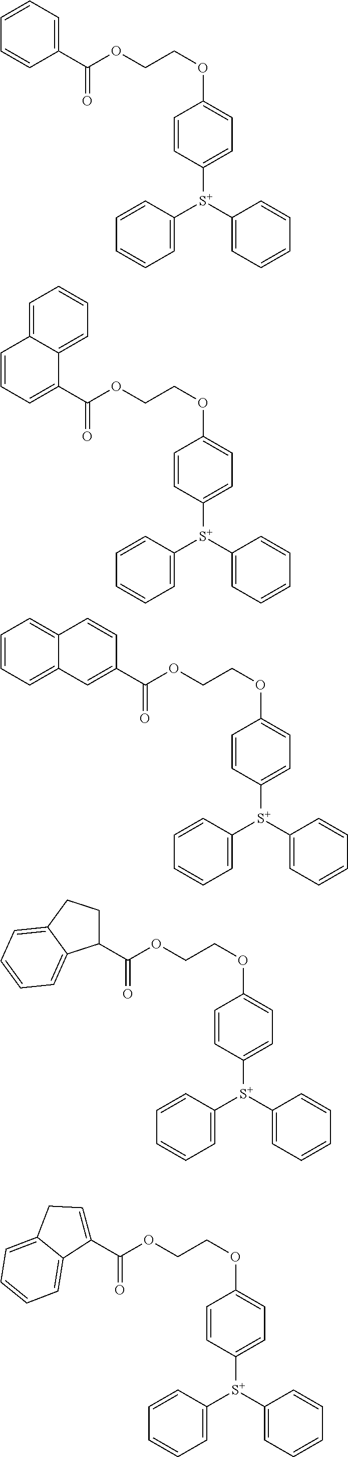

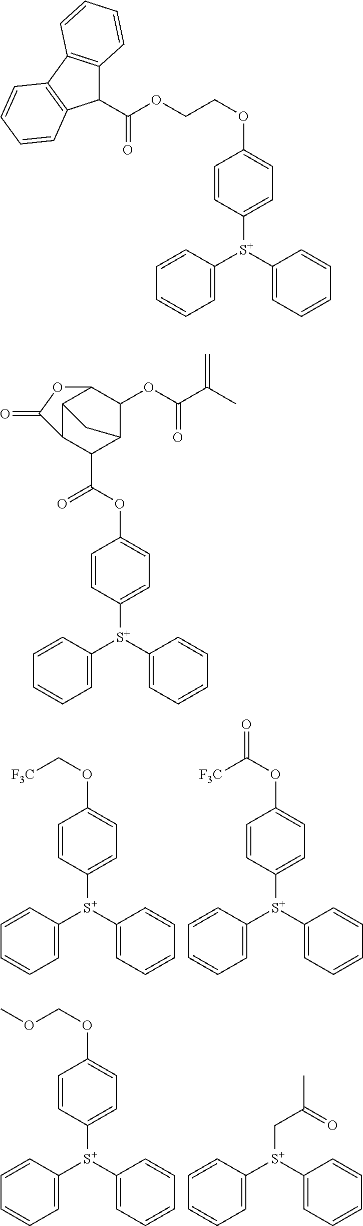

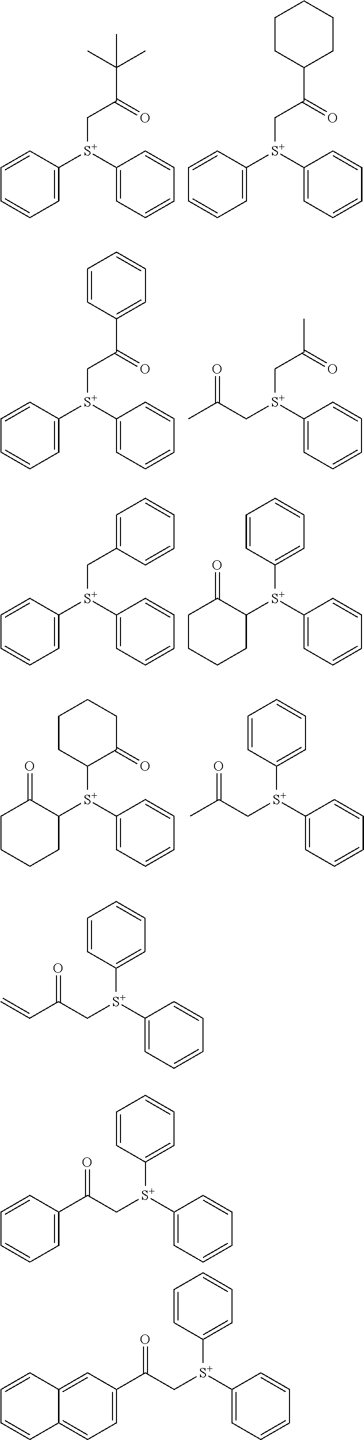

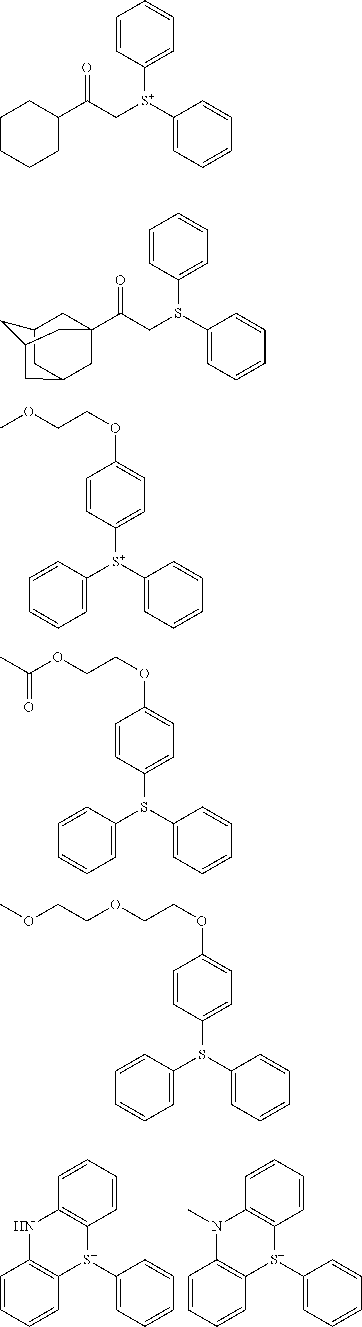

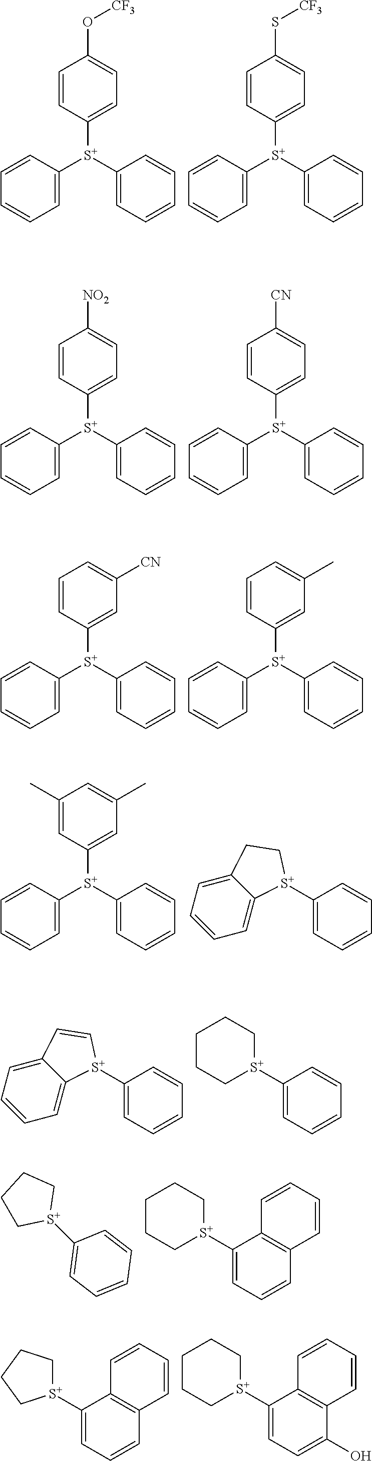

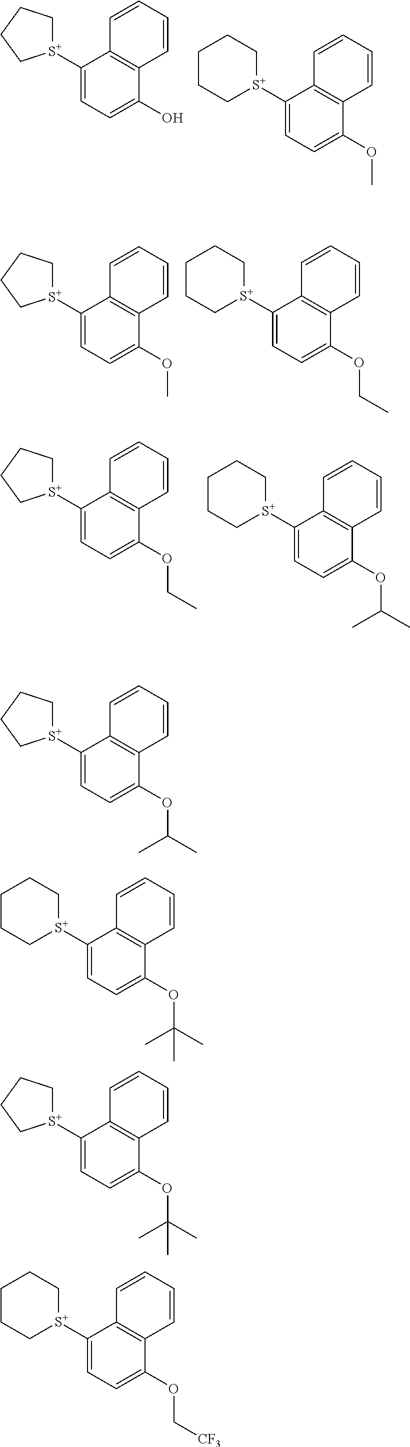

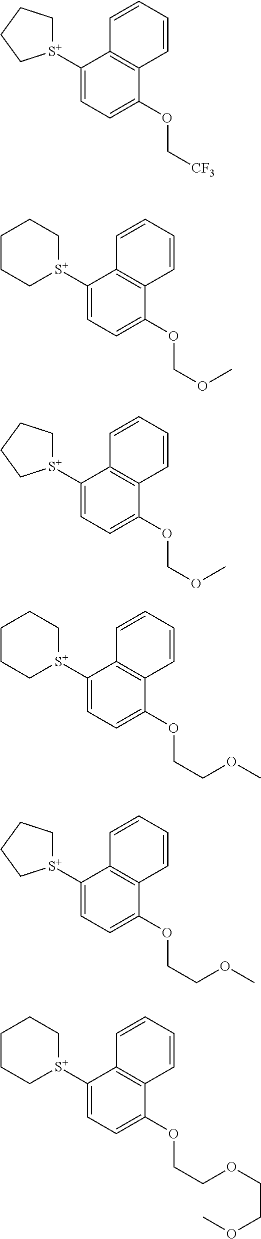

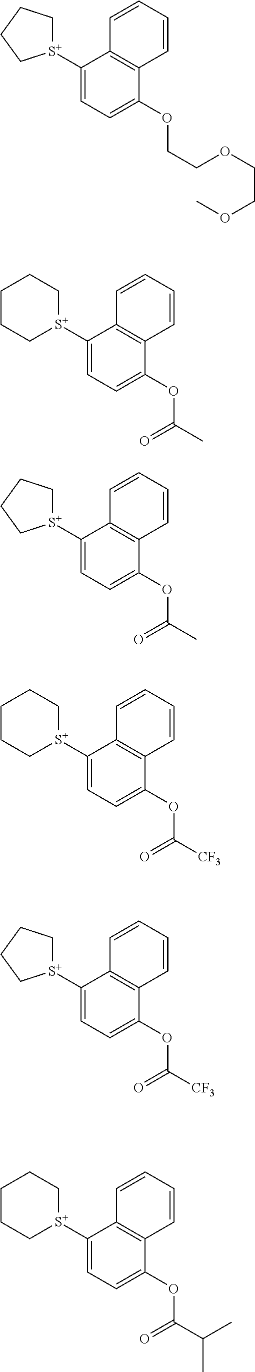

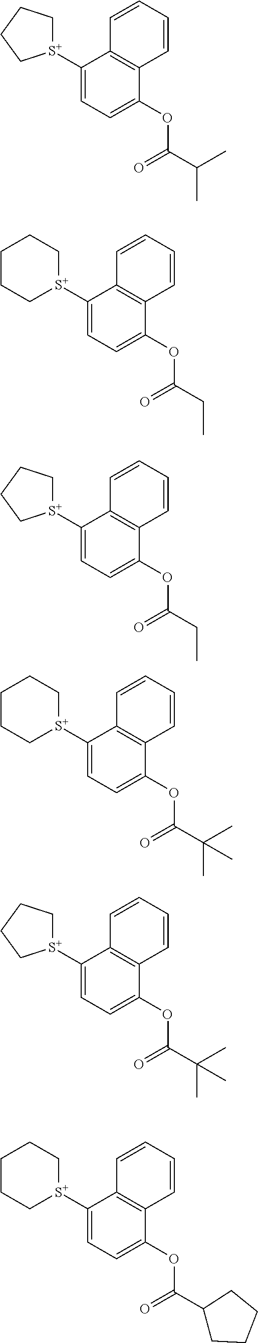

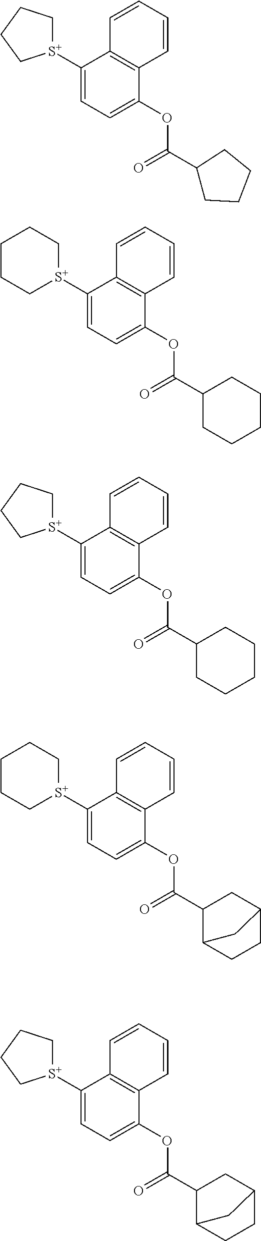

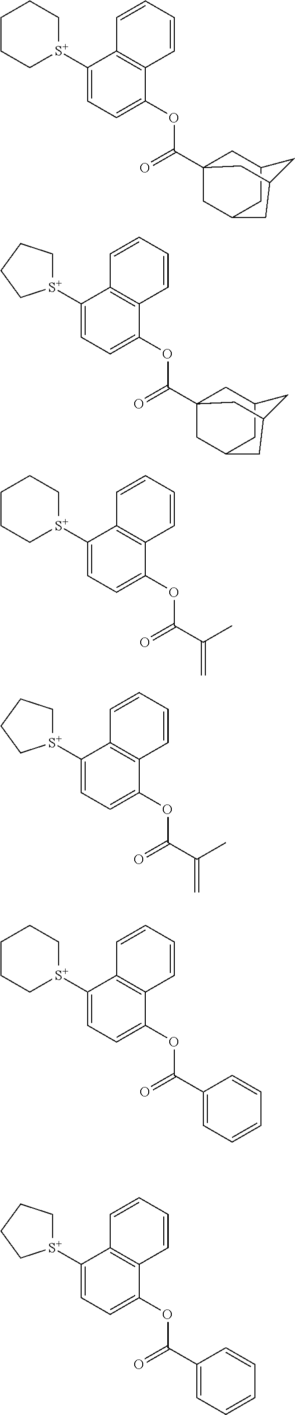

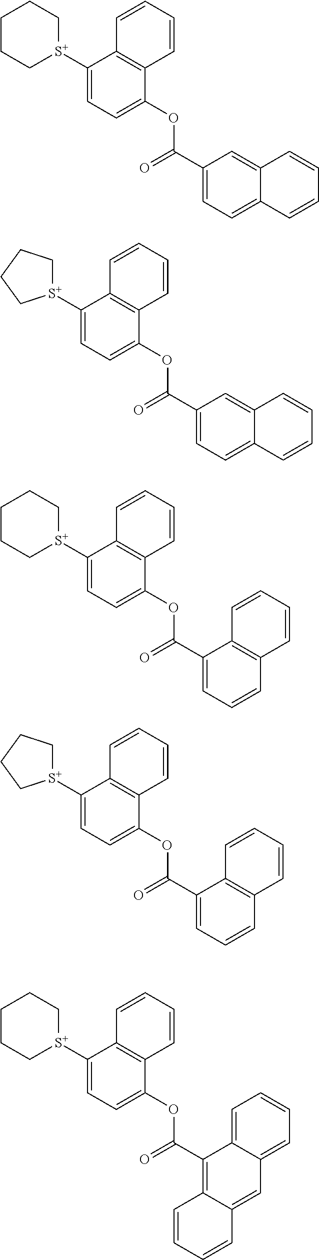

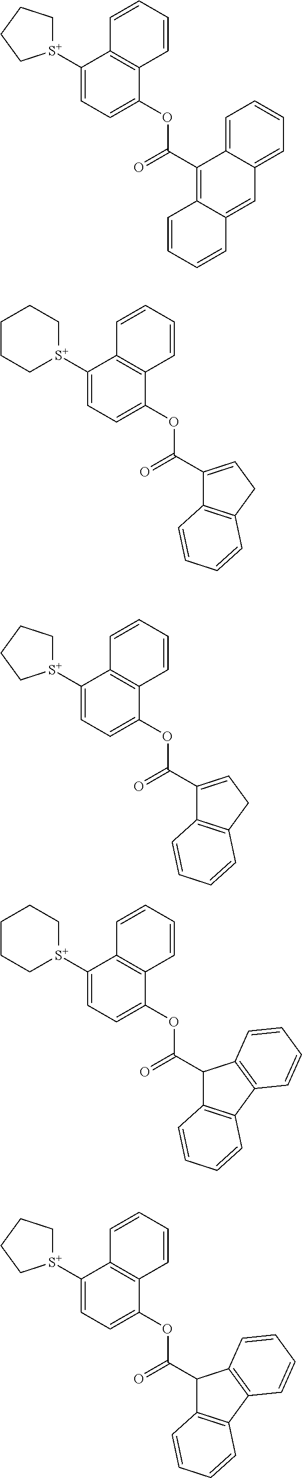

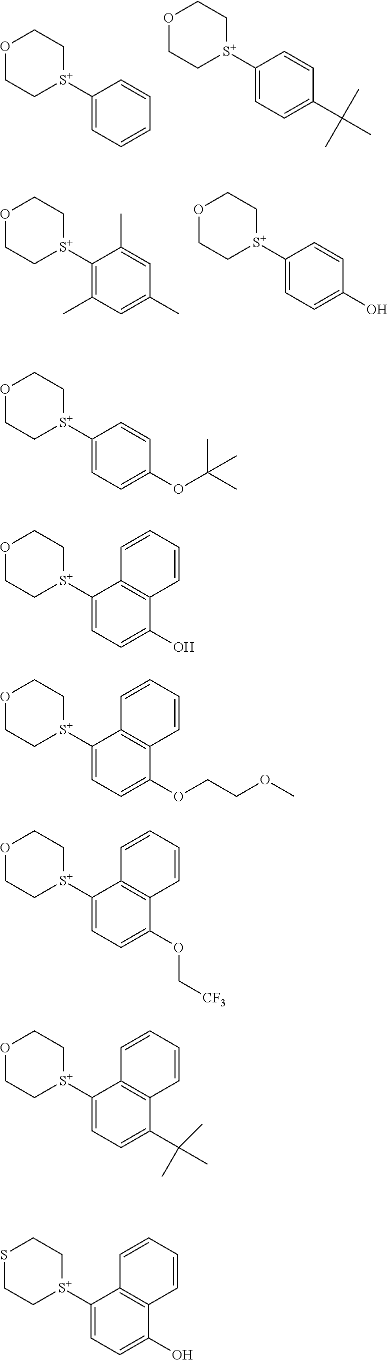

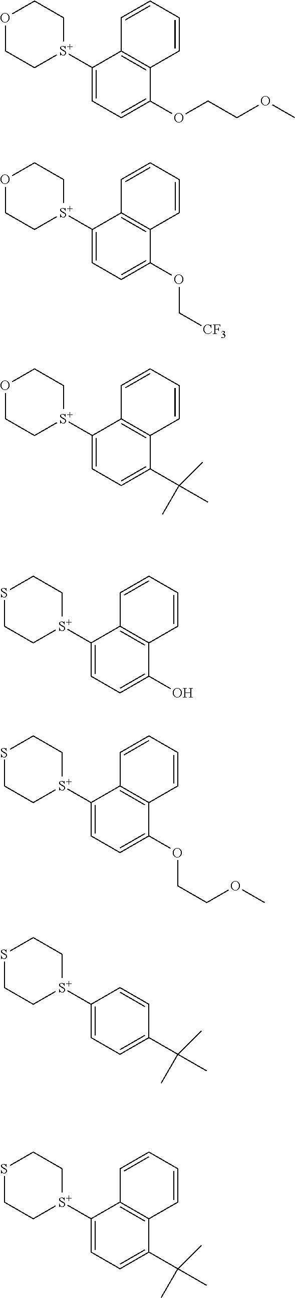

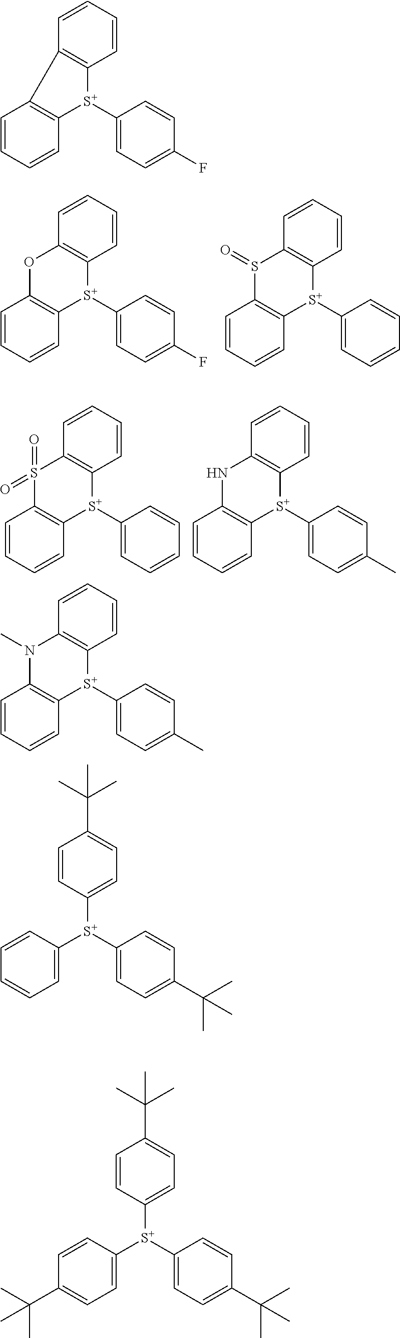

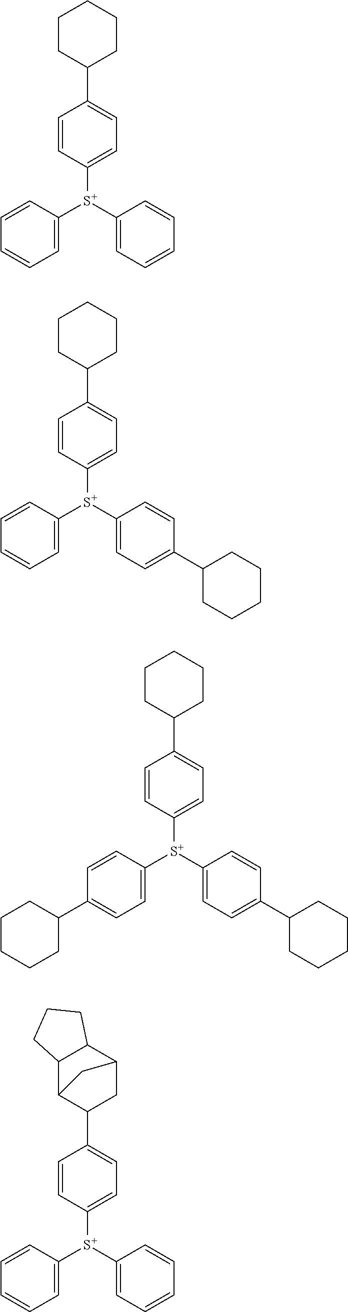

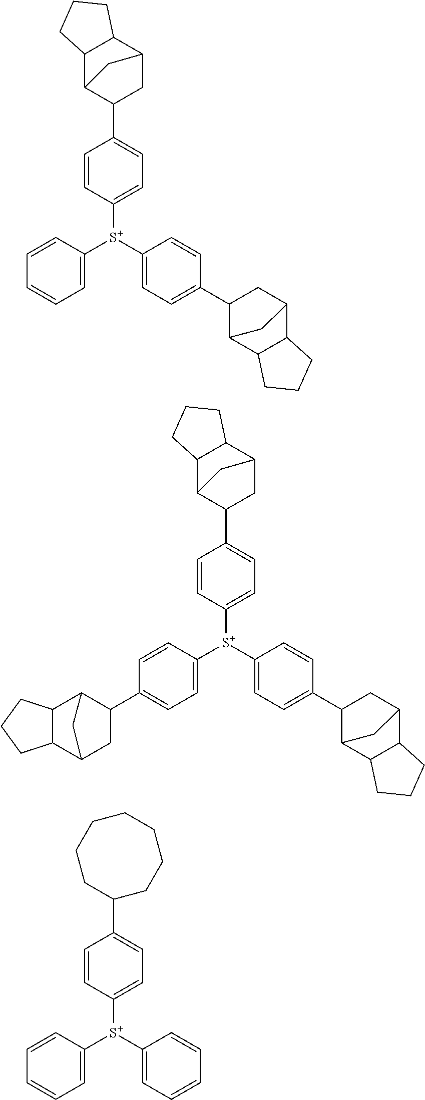

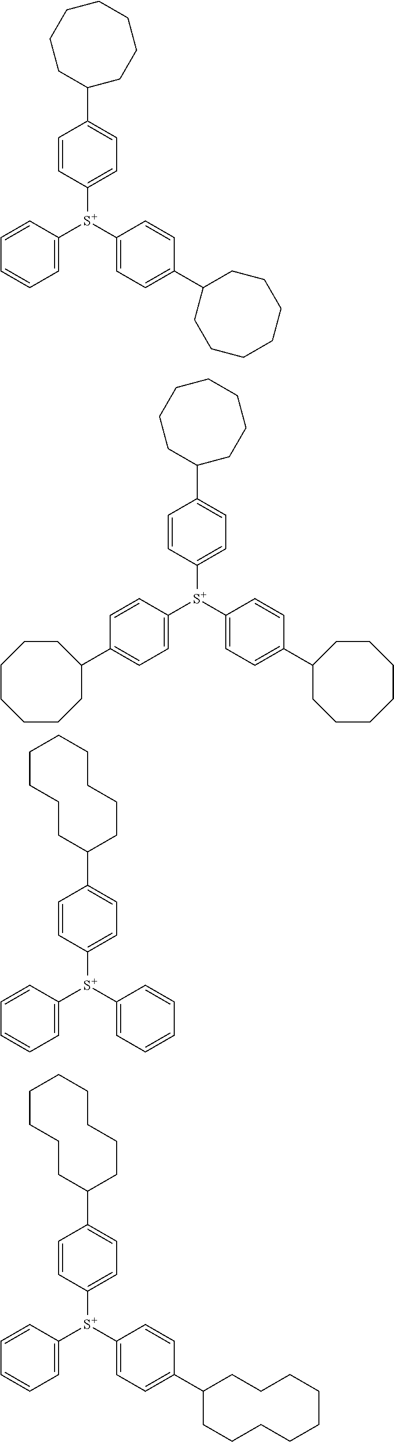

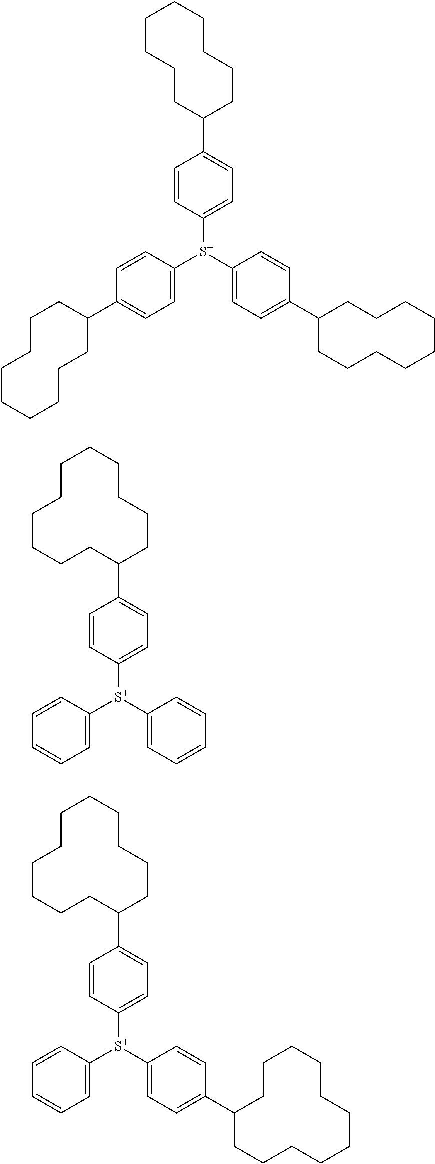

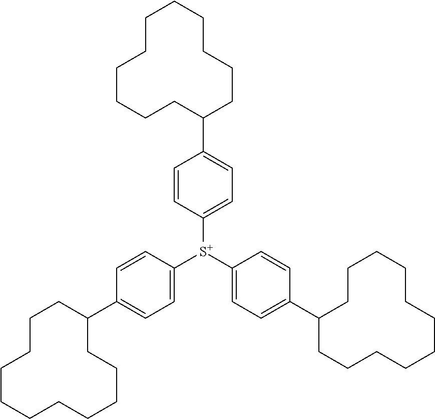

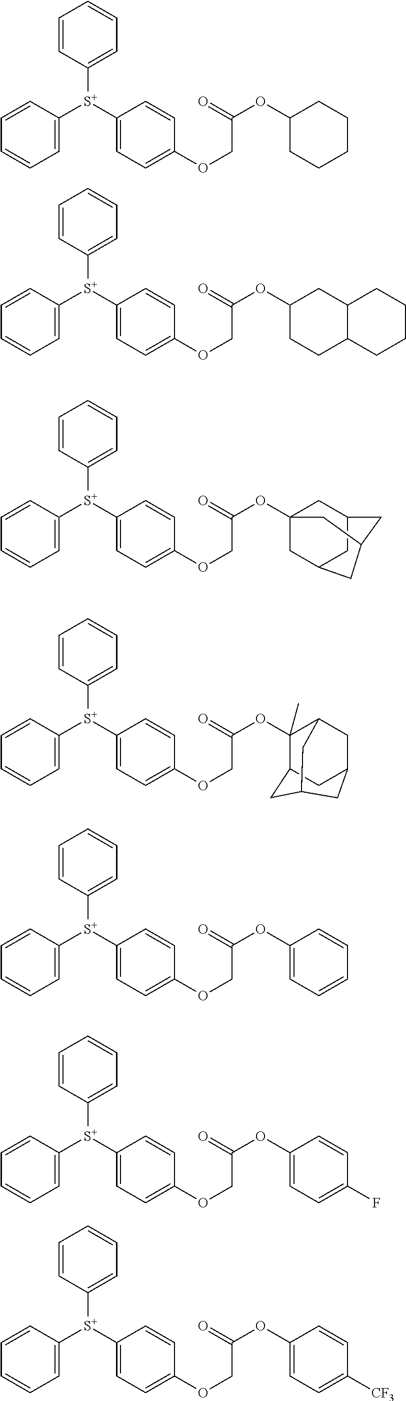

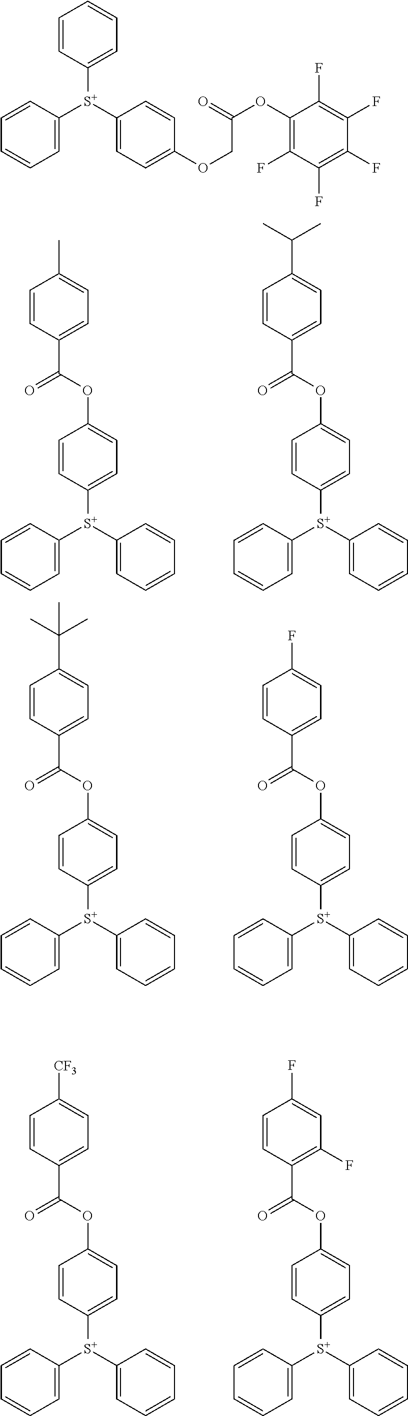

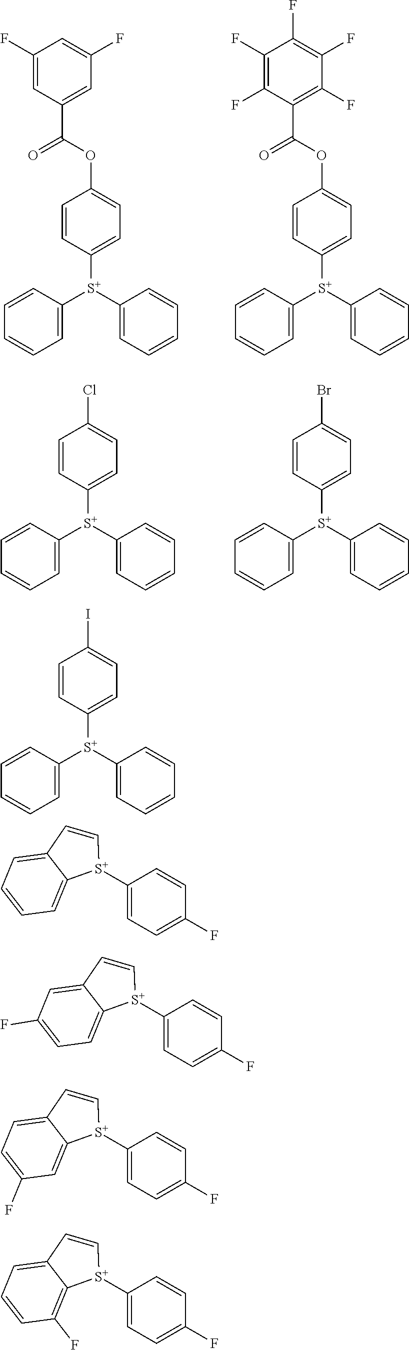

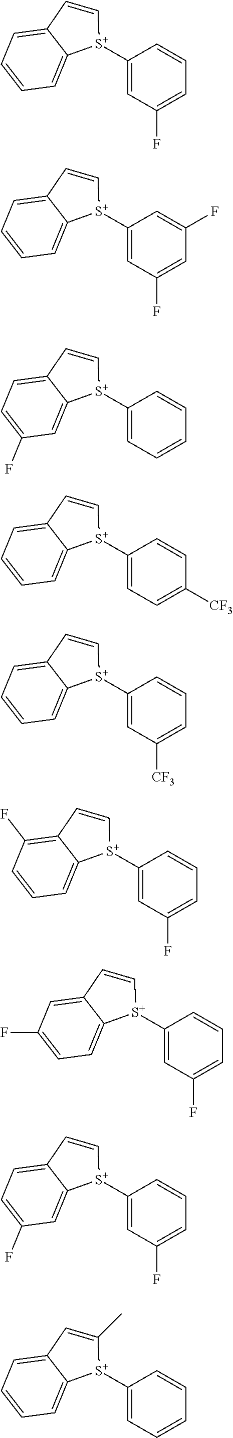

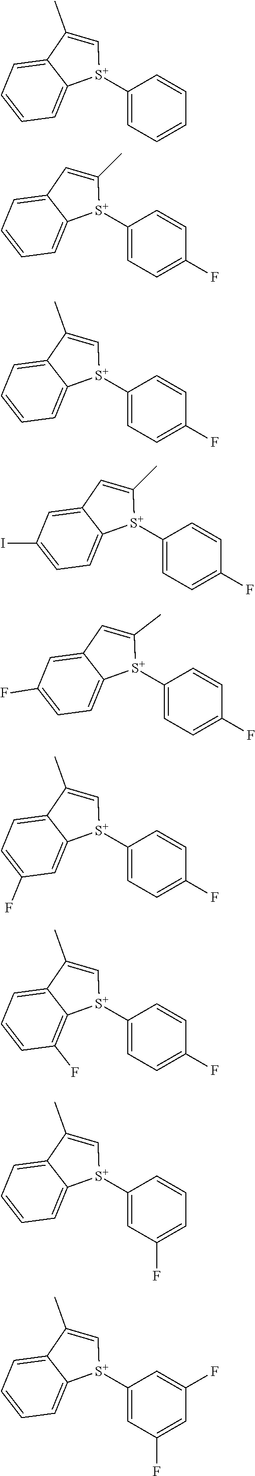

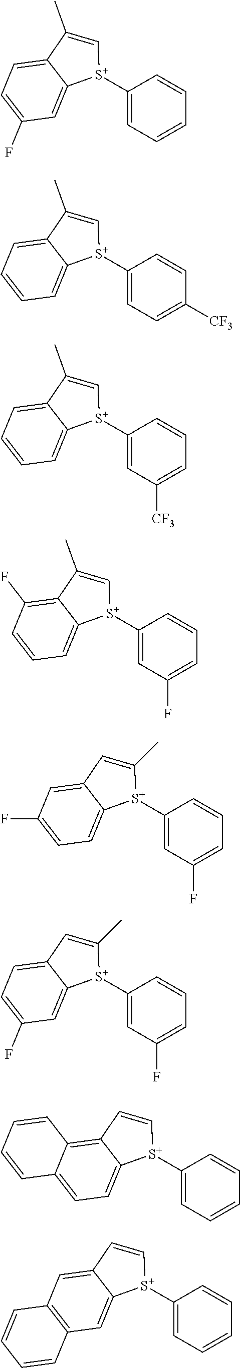

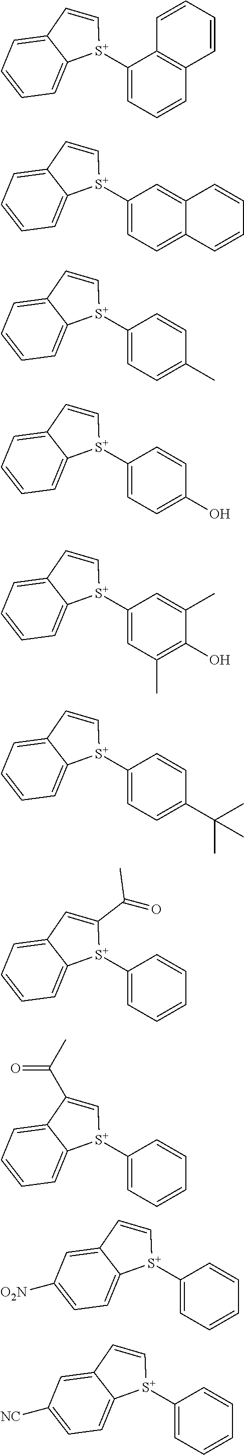

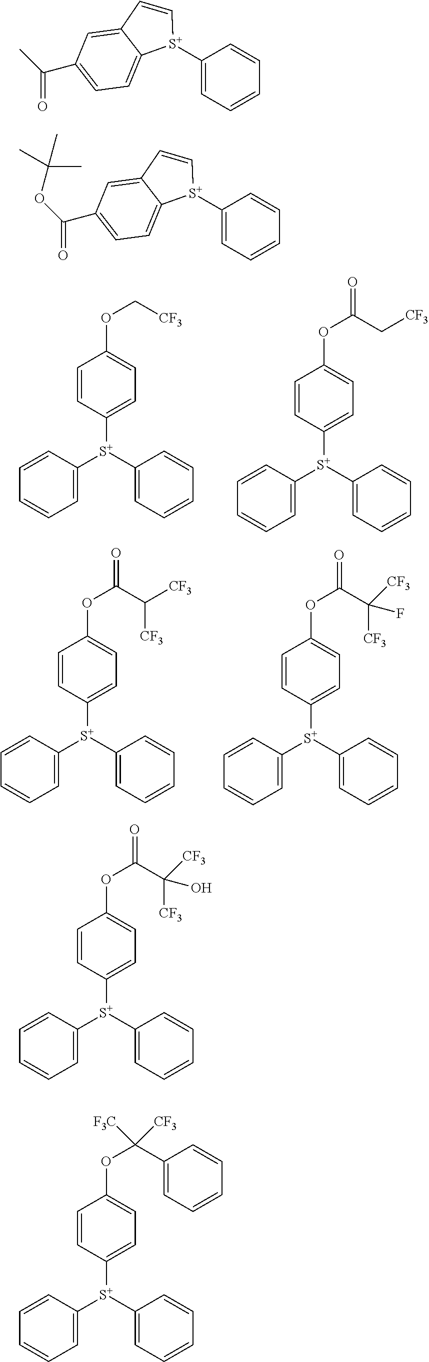

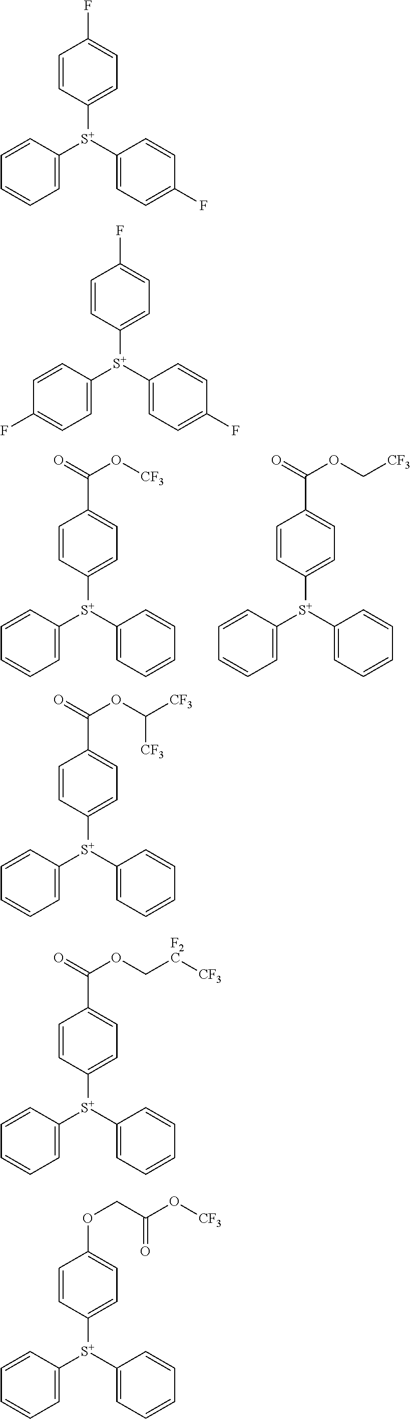

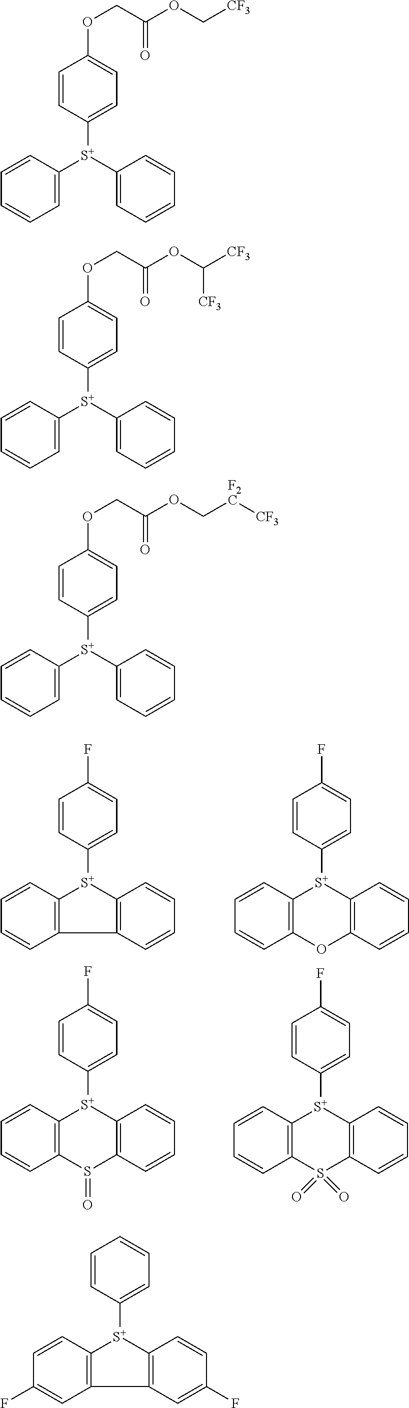

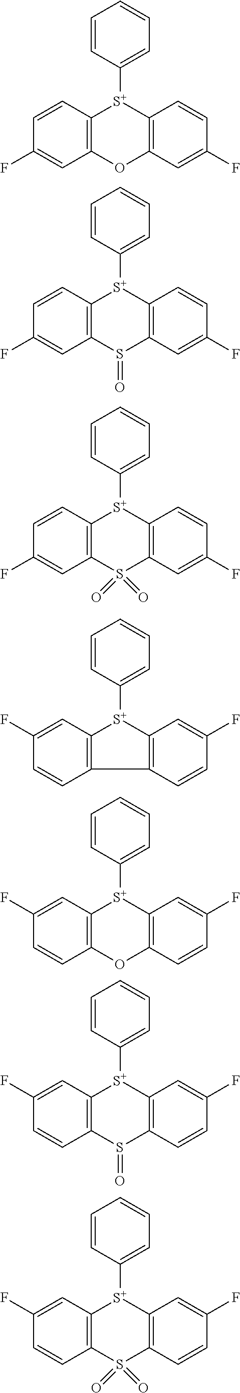

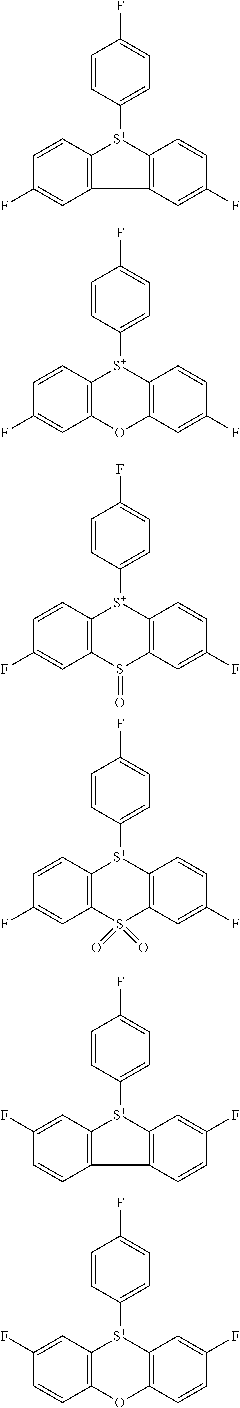

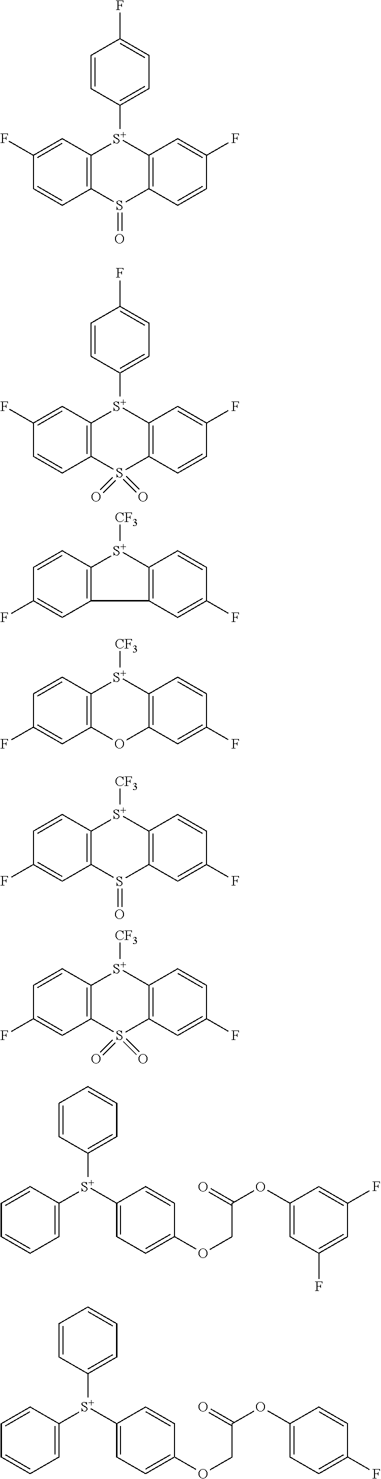

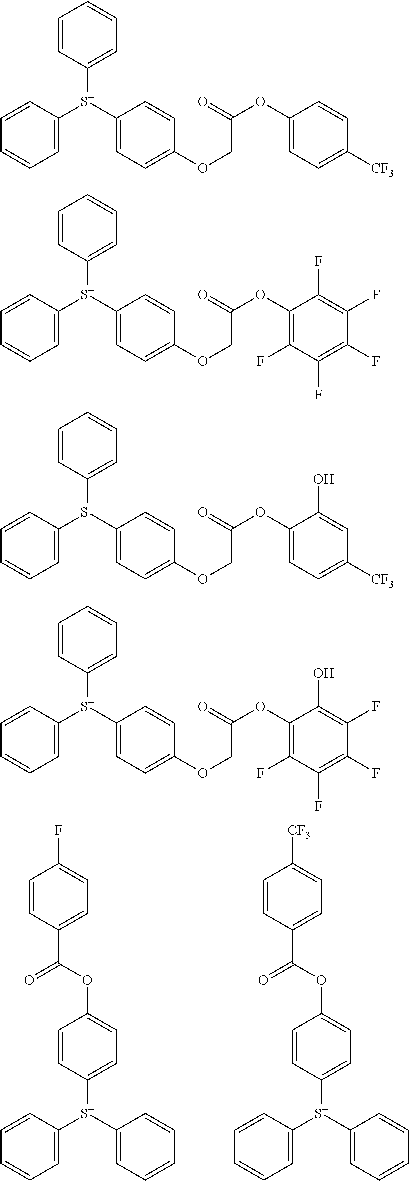

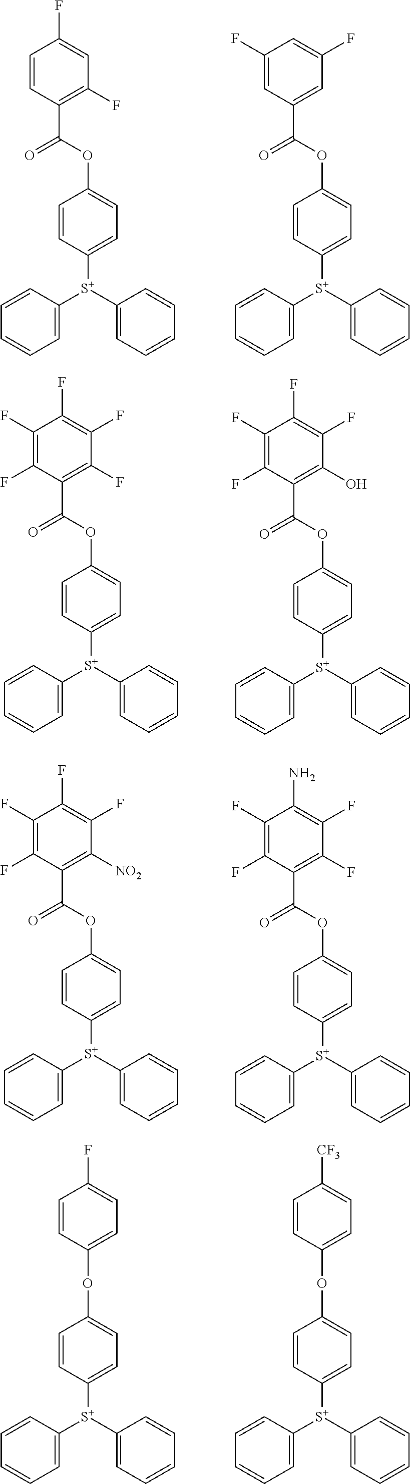

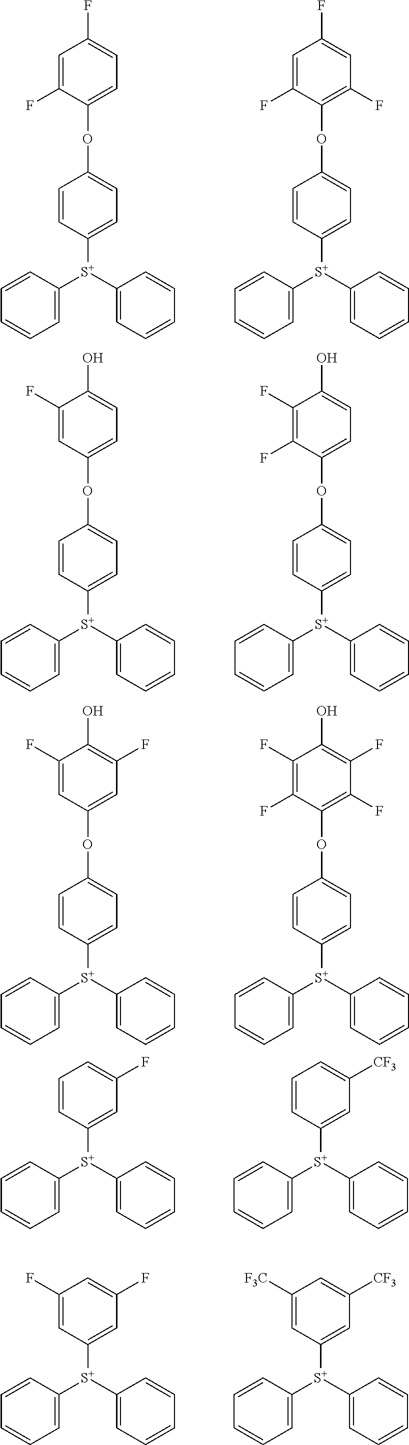

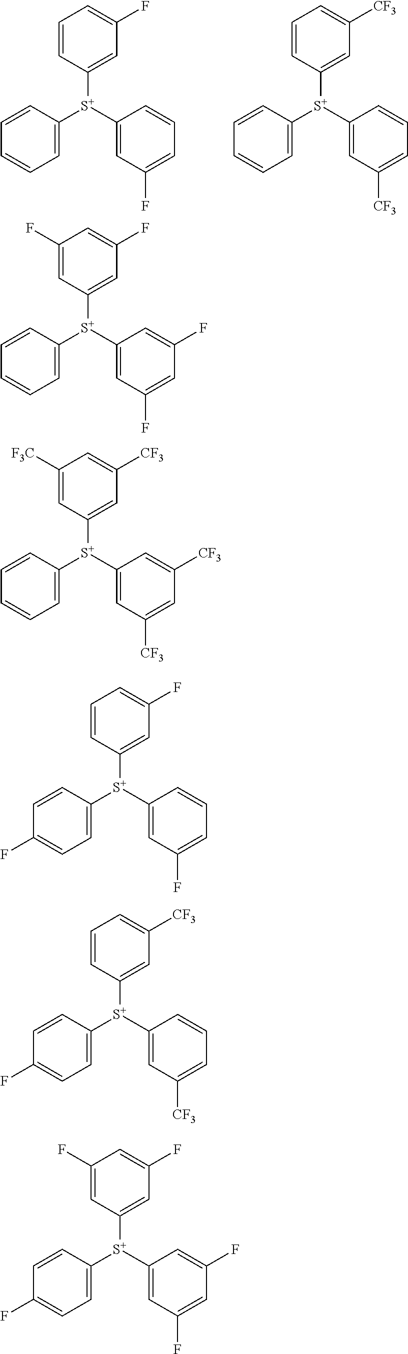

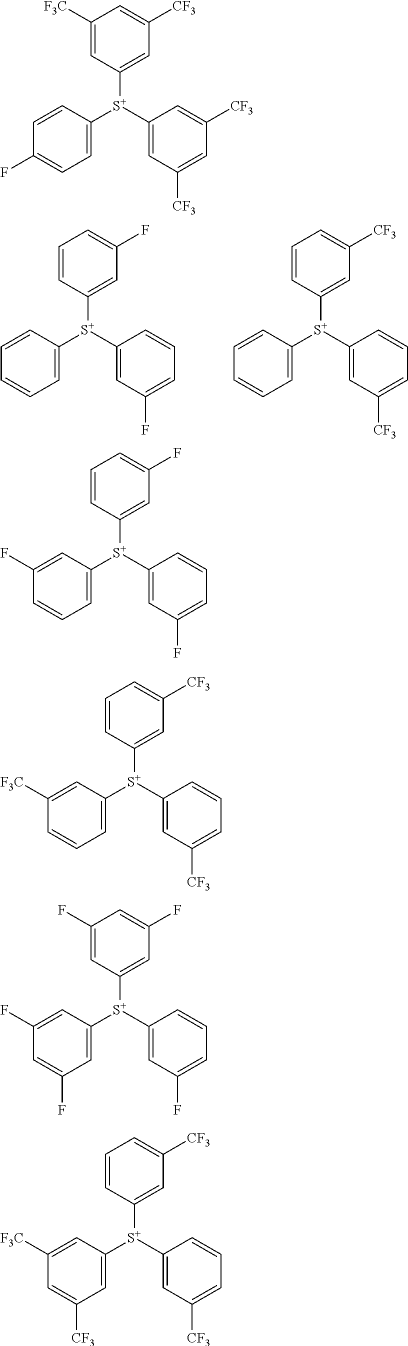

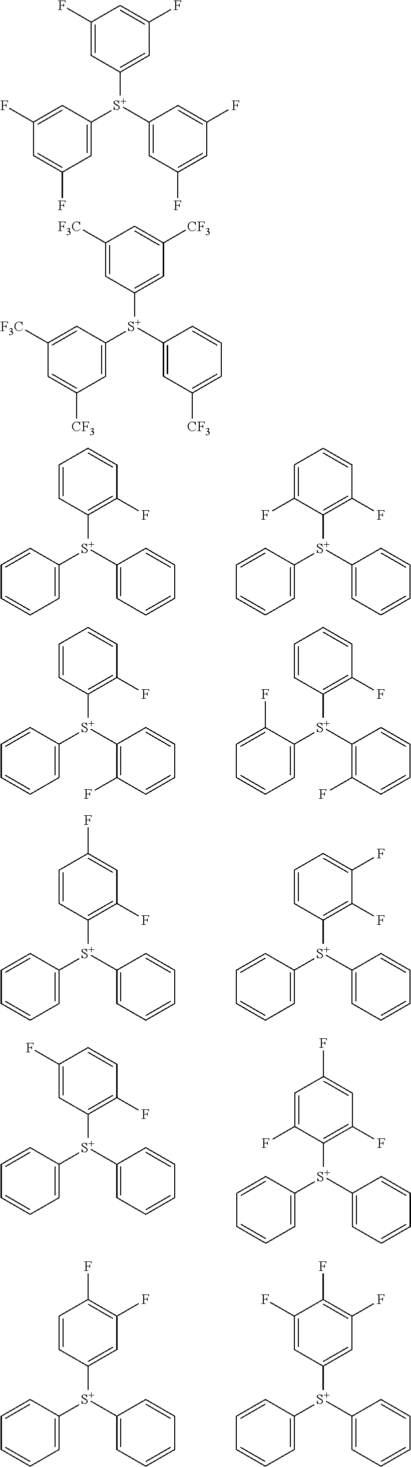

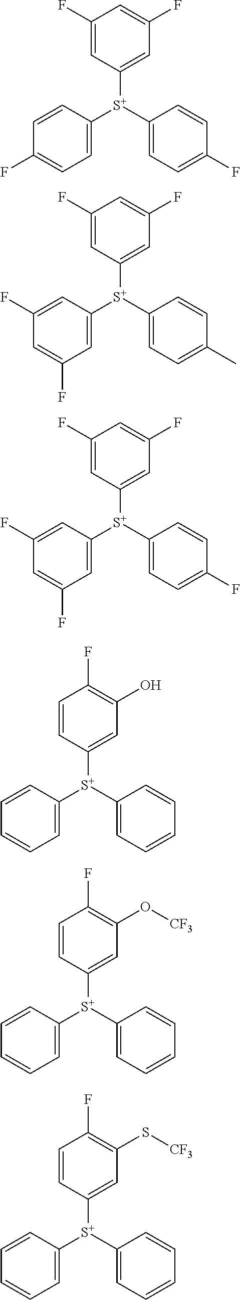

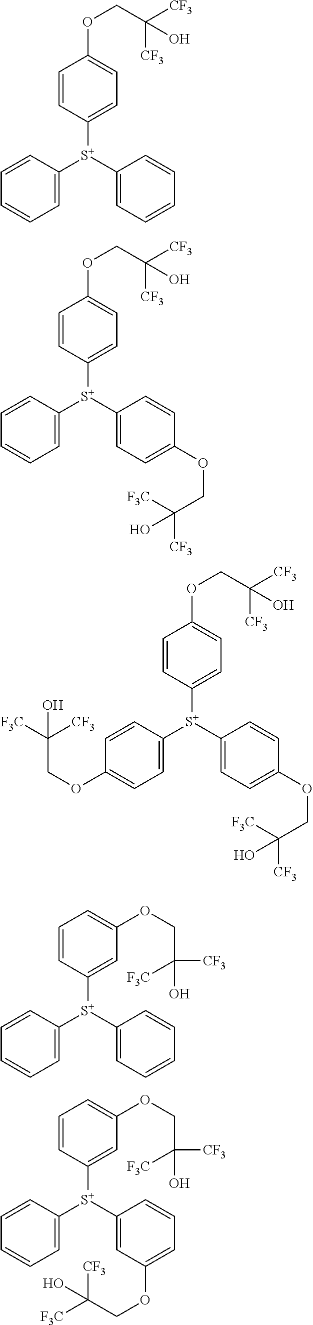

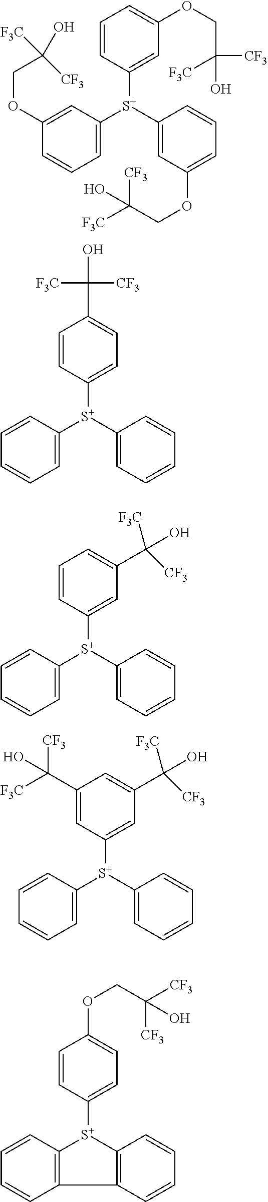

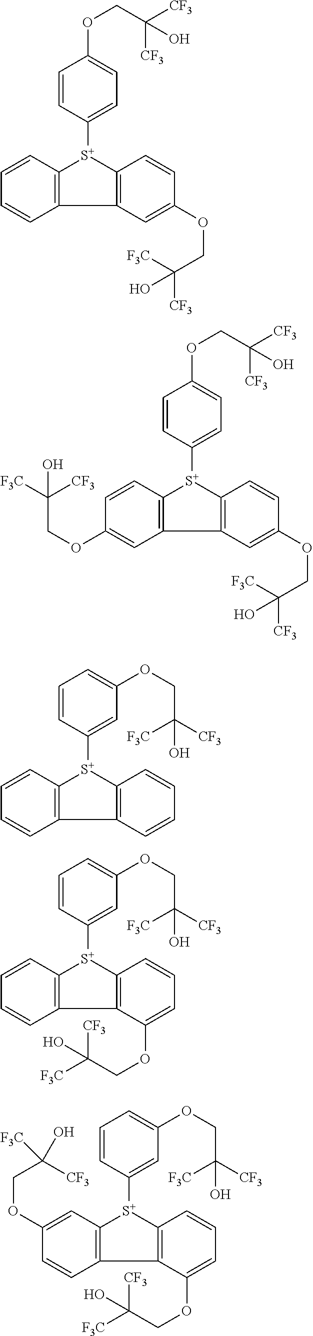

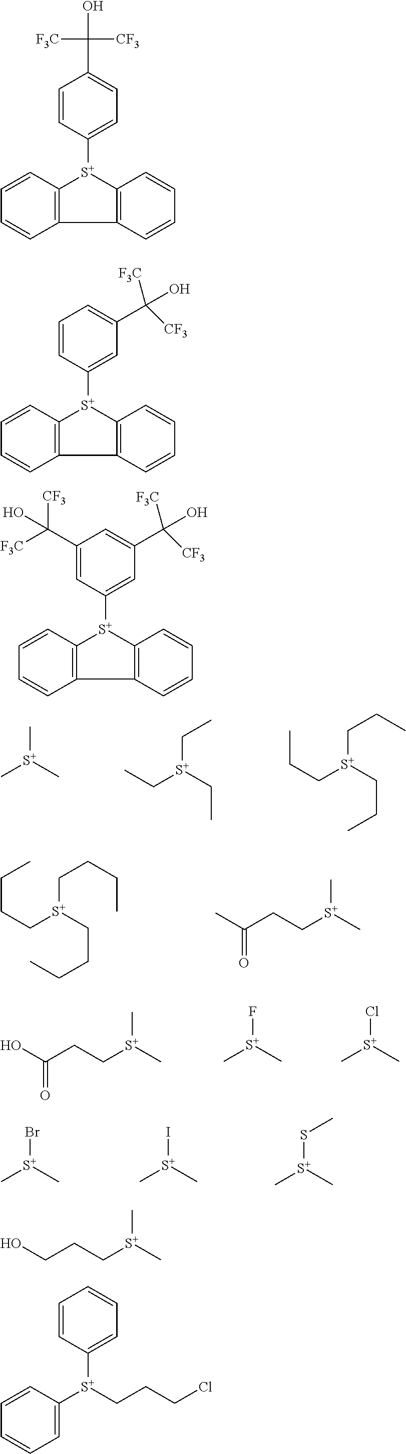

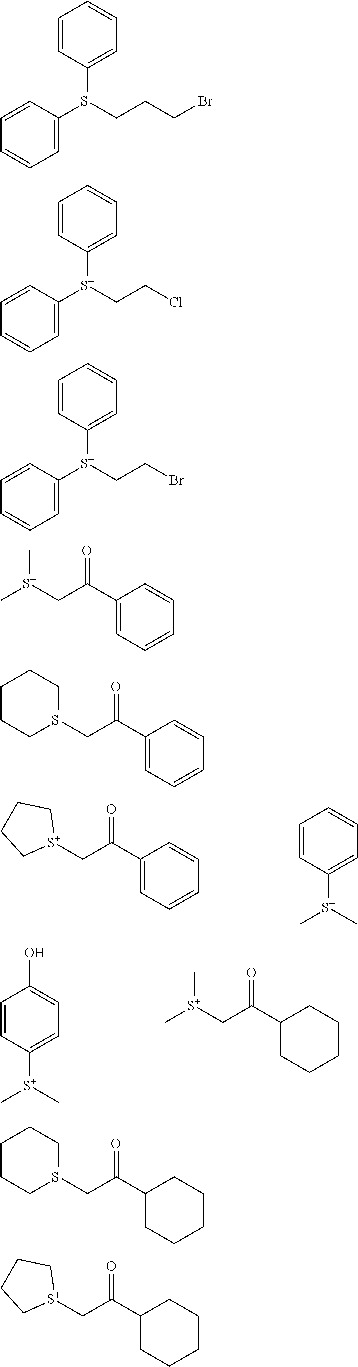

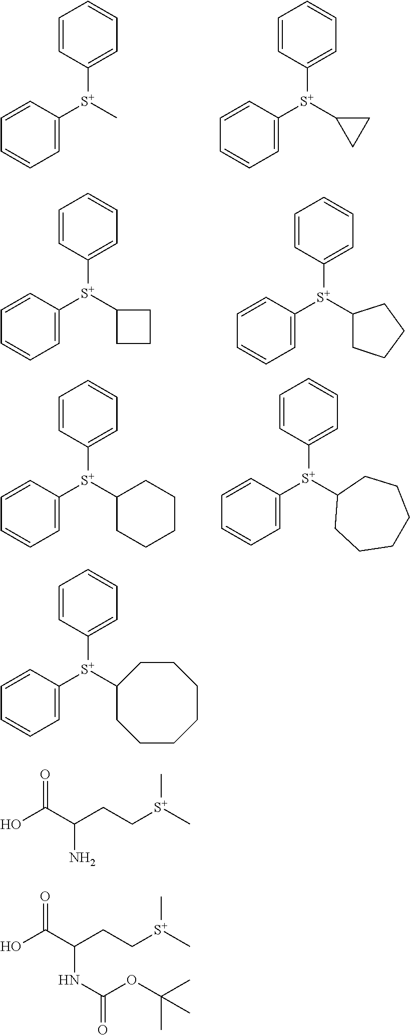

Examples of the iodonium cation in repeat unit (a2) are shown below, but not limited thereto.

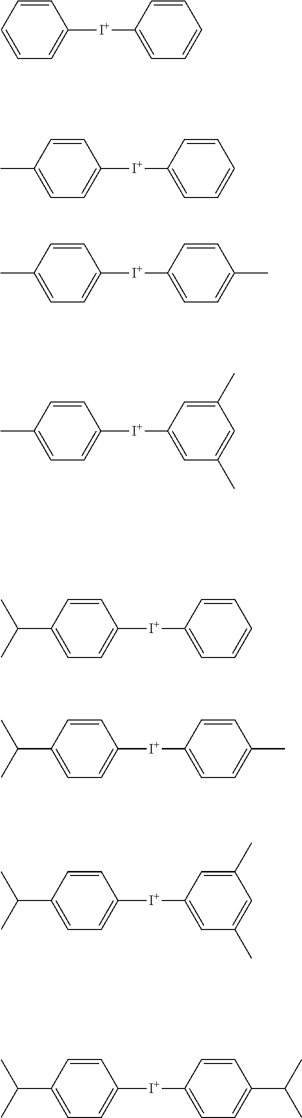

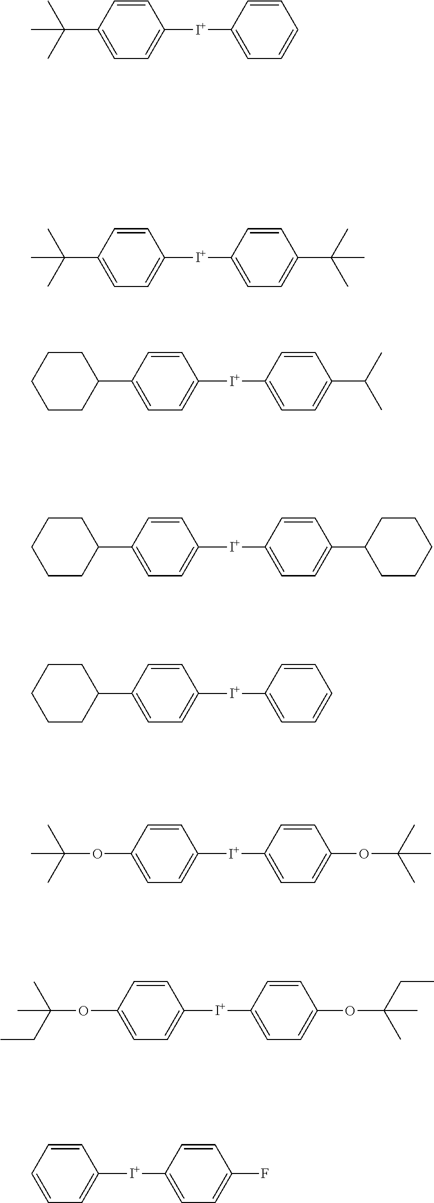

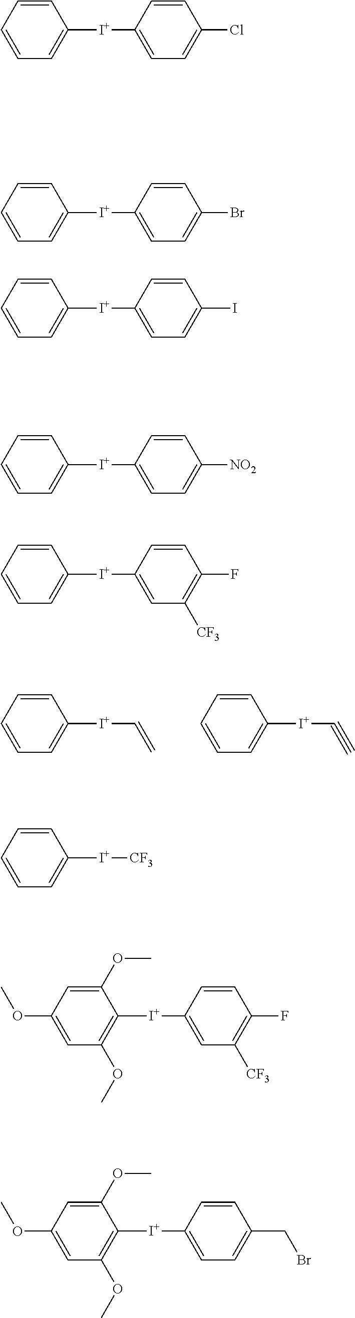

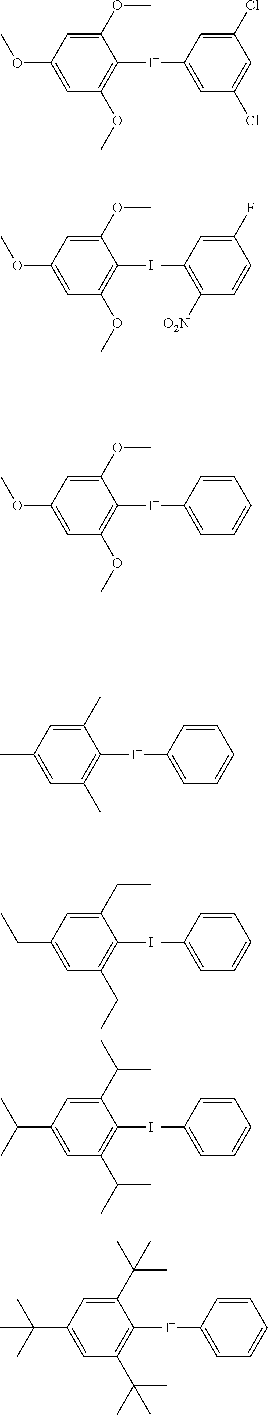

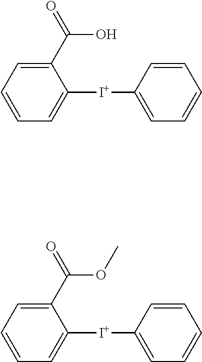

In formulae (a1) and (a2), m is an integer of 0 to 3, and n is 1 or 2.

Of the repeat units (a1) and (a2), units having the formulae (a1-1) and (a2-1) are preferred.

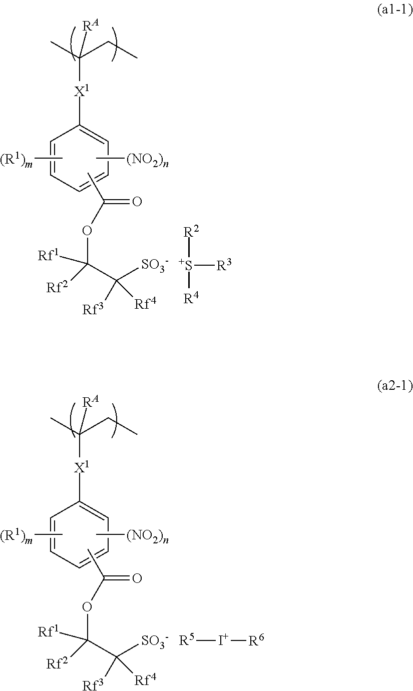

Herein, R^{A}, X¹, Rf¹ to Rf⁴, R¹ to R⁶, m, and n are as defined above.

The monomers from which repeat units (a1) and (a2) are derived may be synthesized, for example, by the same method as the synthesis of the sulfonium salt having a polymerizable anion described in U.S. Pat. No. 8,057,985 (JP 5201363).

The polymer-bound acid generator also functions as a base polymer. In the case of a chemically amplified positive tone resist composition, the polymer-bound acid generator comprises repeat units containing an acid labile group, preferably repeat units having the formula (b1) or repeat units having the formula (b2). These units are simply referred to as repeat units (b1) and (b2).

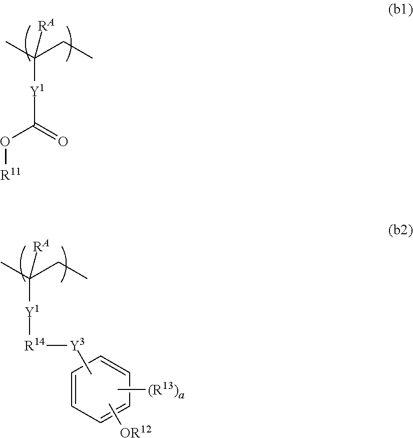

In formulae (b1) and (b2), R^{A} is each independently hydrogen or methyl. Y¹ is a single bond, phenylene or naphthylene group, or C₁-C₁₂ linking group containing at least one moiety selected from ester bond, ether bond and lactone ring. Y² is a single bond or ester bond. R¹¹ and R¹² are each independently an acid labile group. R¹³ is a C₁-C₄ saturated hydrocarbyl group, halogen, C₂-C₅ saturated hydrocarbylcarbonyl group, cyano group, or C₂-C₅ saturated hydrocarbyloxycarbonyl group. R¹⁴ is a single bond or a C₁-C₆ alkanediyl group which may contain an ether bond or ester bond. The subscript “a” is an integer of 0 to 4.

Examples of the monomer from which repeat units (b1) are derived are shown below, but not limited thereto. R^{A} and R¹¹ are as defined above.

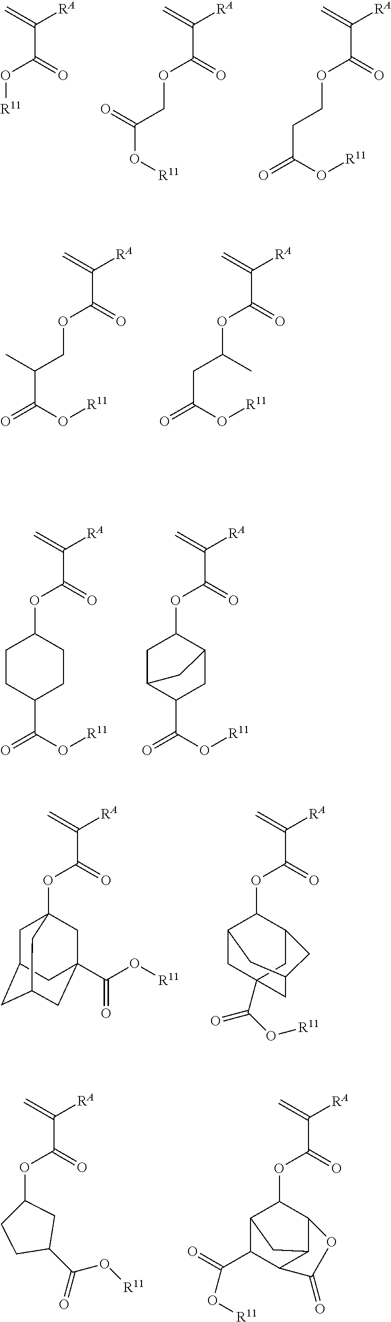

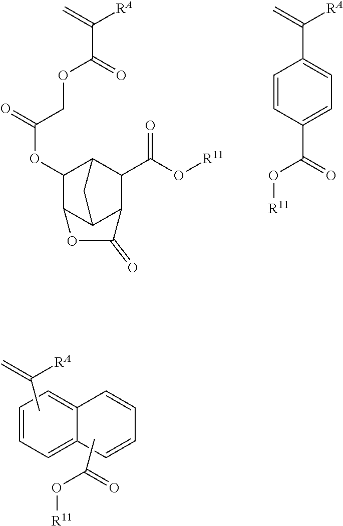

Examples of the monomer from which the repeat units (b2) are derived are shown below, but not limited thereto. R^{A} and R¹² are as defined above.

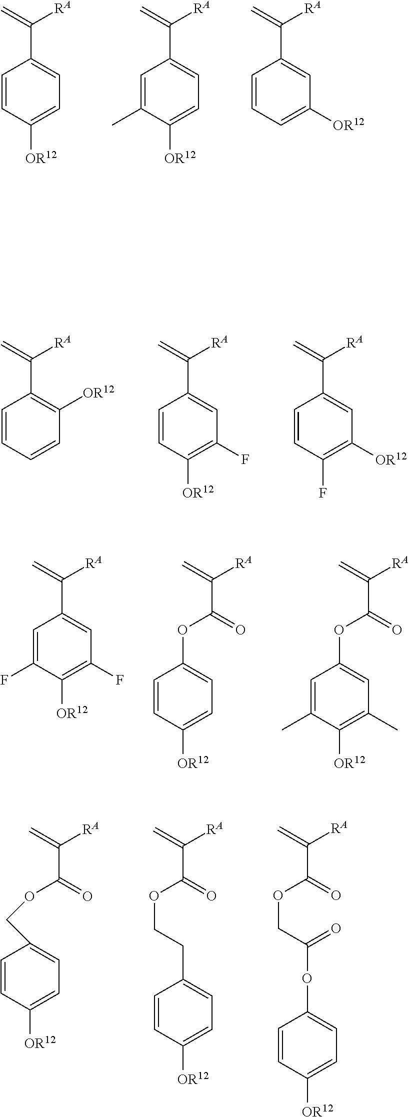

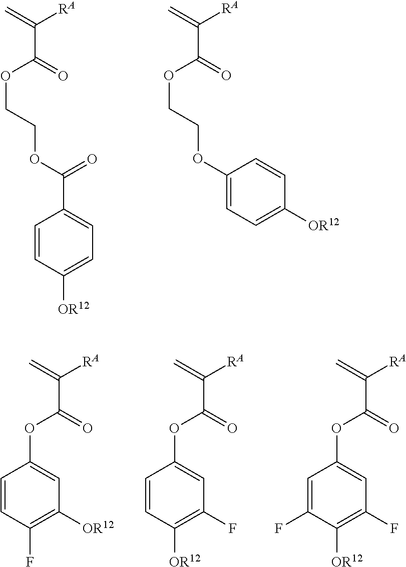

The acid labile groups represented by R¹¹ and R¹² in formulae (b1) and (b2) may be selected from a variety of such groups, for example, those groups described in JP-A 2013-080033 (U.S. Pat. No. 8,574,817) and JP-A 2013-083821 (U.S. Pat. No. 8,846,303).

Typical of the acid labile group are groups of the following formulae (AL-1) to (AL-3).

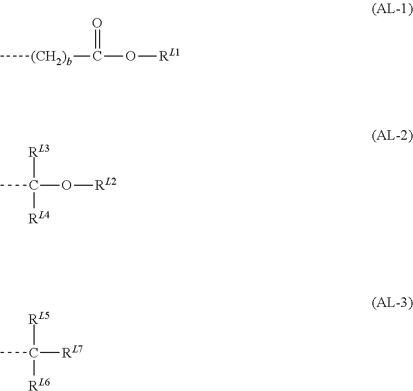

In formulae (AL-1) and (AL-2), R^{L1} and R^{L2} are each independently a C₁-C₄₀ hydrocarbyl group which may contain a heteroatom such as oxygen, sulfur, nitrogen or fluorine. The hydrocarbyl group may be saturated or unsaturated and straight, branched or cyclic. Inter alia, C₁-C₄₀ saturated hydrocarbyl groups are preferred, and C₁-C₂₀ saturated hydrocarbyl groups are more preferred.

In formula (AL-1), b is an integer of 0 to 10, preferably 1 to 5.

In formula (AL-2), R^{L3} and R^{L4} are each independently hydrogen or a C₁-C₂₀ hydrocarbyl group which may contain a heteroatom such as oxygen, sulfur, nitrogen or fluorine. The hydrocarbyl group may be saturated or unsaturated and straight, branched or cyclic. Inter alia, C₁-C₂₀ saturated hydrocarbyl groups are preferred. Any two of R^{L2}, R^{L3} and R^{L4} may bond together to form a C₃-C₂₀ ring with the carbon atom or carbon and oxygen atoms to which they are attached. The ring preferably contains 4 to 16 carbon atoms and is typically alicyclic.

In formula (AL-3), R^{L}, R^{L6} and R^{L7} are each independently a C₁-C₂₀ hydrocarbyl group which may contain a heteroatom such as oxygen, sulfur, nitrogen or fluorine. The hydrocarbyl group may be saturated or unsaturated and straight, branched or cyclic. Inter alia, C₁-C₂₀ saturated hydrocarbyl groups are preferred. Any two of R^{L}, R^{L6} and R^{L7} may bond together to form a C₃-C₂₀ ring with the carbon atom to which they are attached. The ring preferably contains 4 to 16 carbon atoms and is typically alicyclic.

Where the polymer-bound acid generator also functions as a base polymer, it may further comprise repeat units (c) having a phenolic hydroxy group as an adhesive group. Examples of the monomer from which repeat units (c) are derived are given below, but not limited thereto. Herein R^{A} is as defined above.

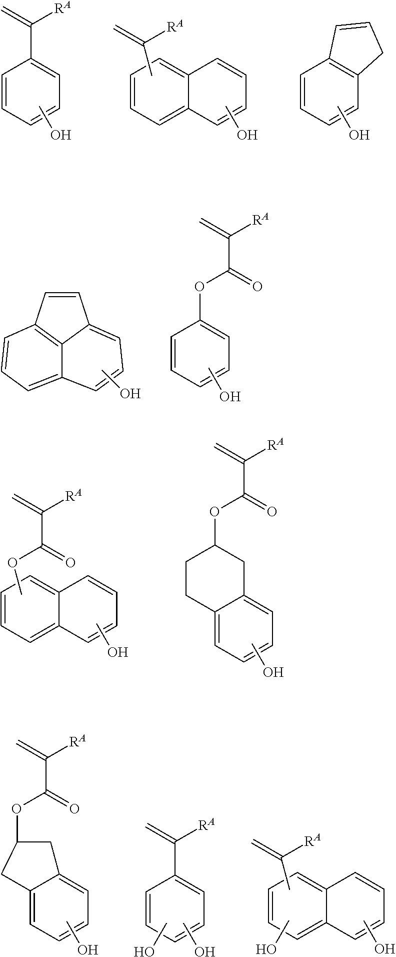

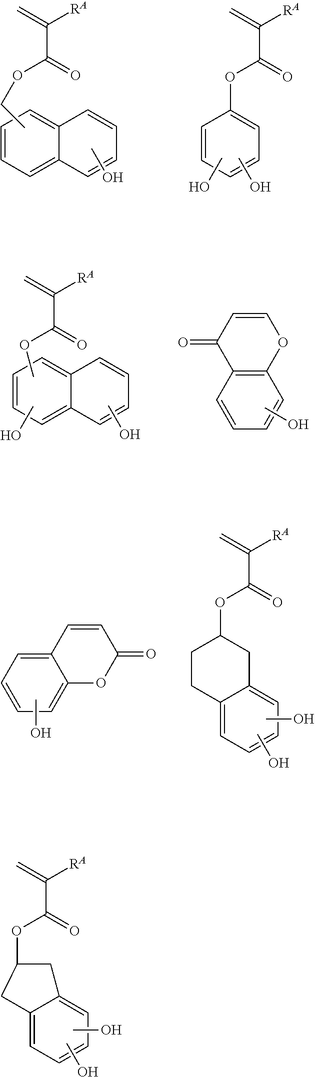

Where the polymer-bound acid generator also functions as a base polymer, it may further comprise repeat units (d) having another adhesive group selected from hydroxy group (other than the foregoing phenolic hydroxy), lactone ring, sultone ring, ether bond, ester bond, sulfonate bond, carbonyl group, sulfonyl group, cyano group, and carboxy group. Examples of the monomer from which repeat units (d) are derived are given below, but not limited thereto. Herein R^{A} is as defined above.

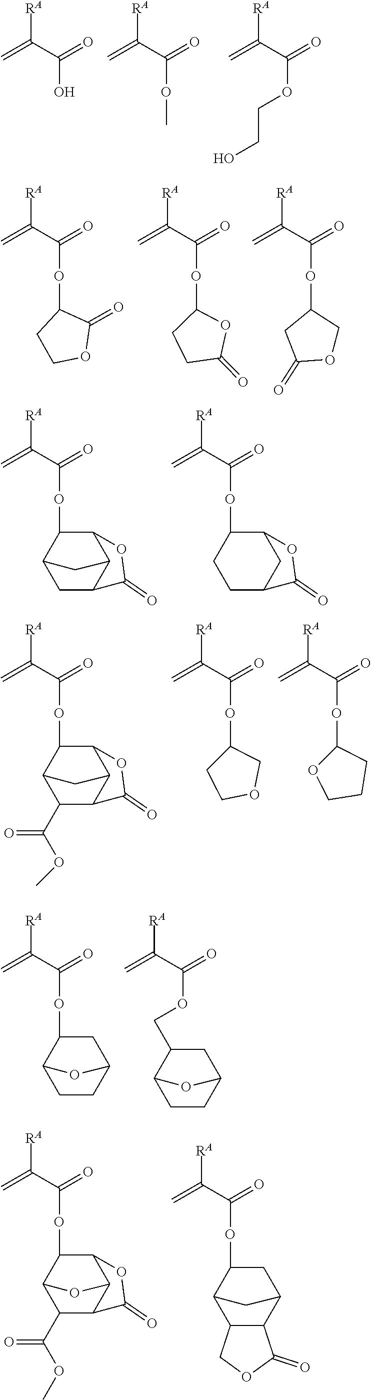

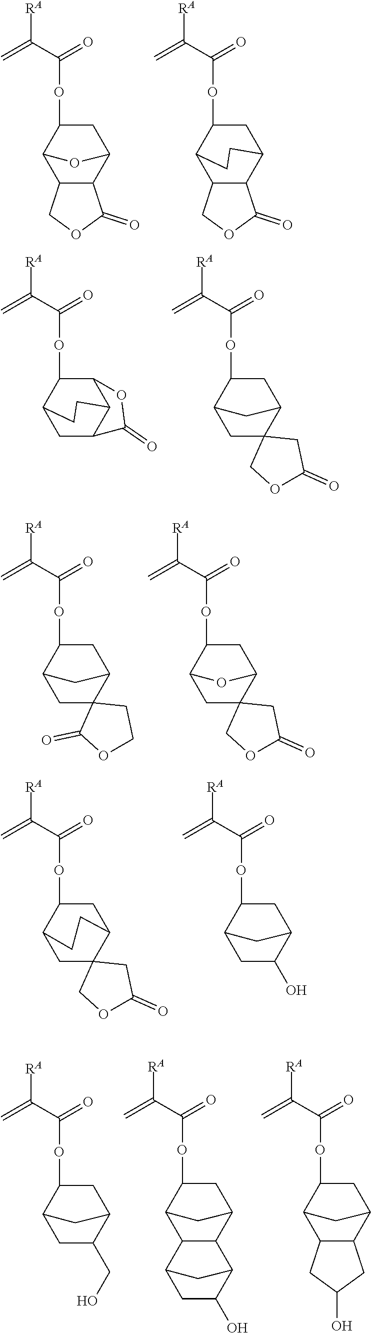

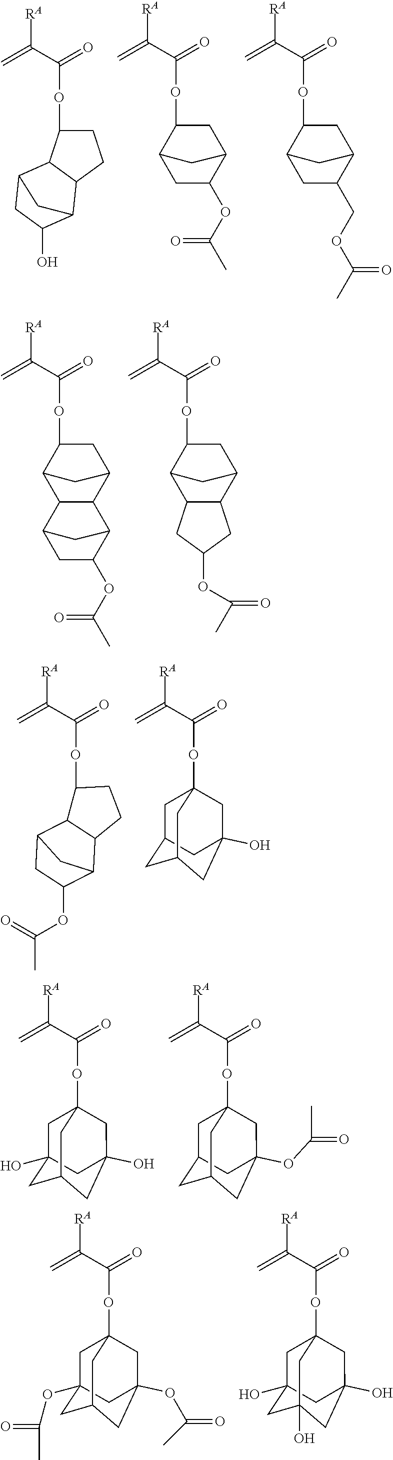

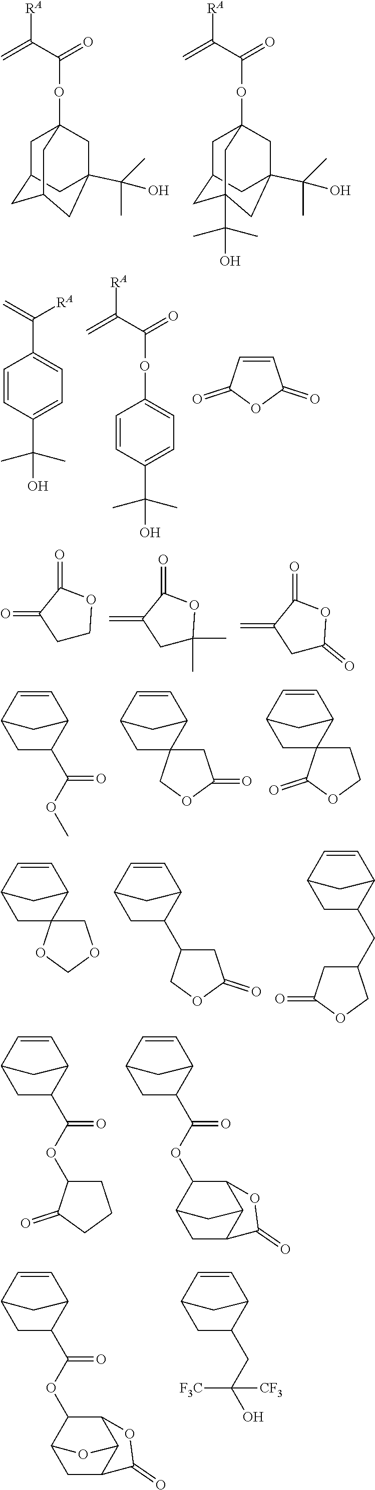

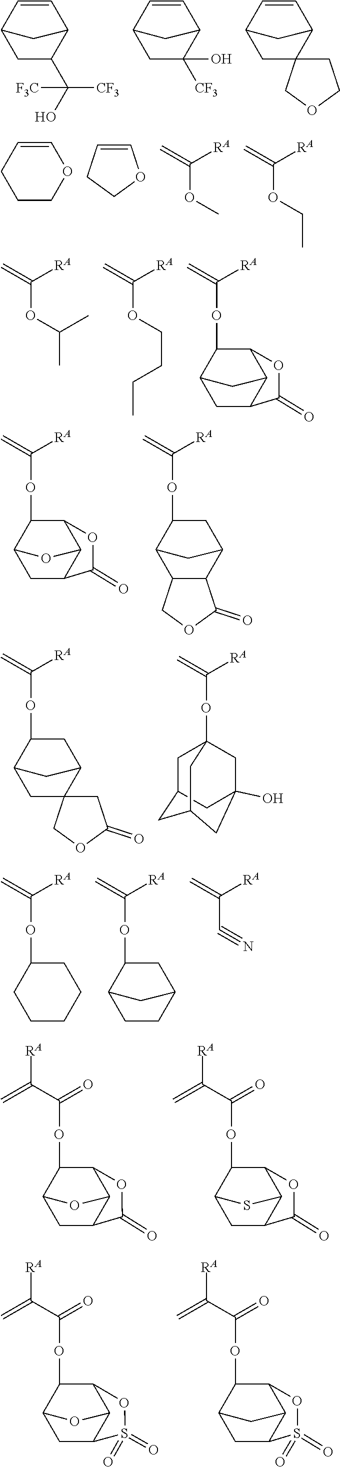

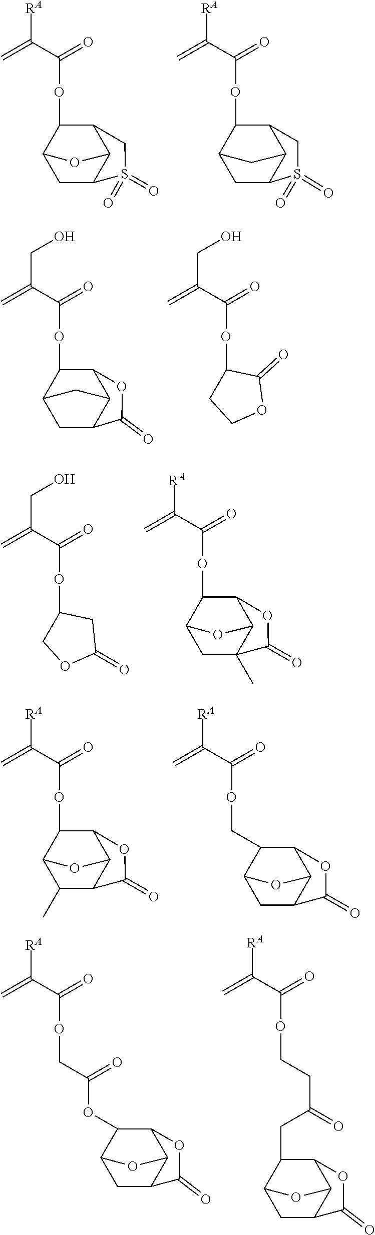

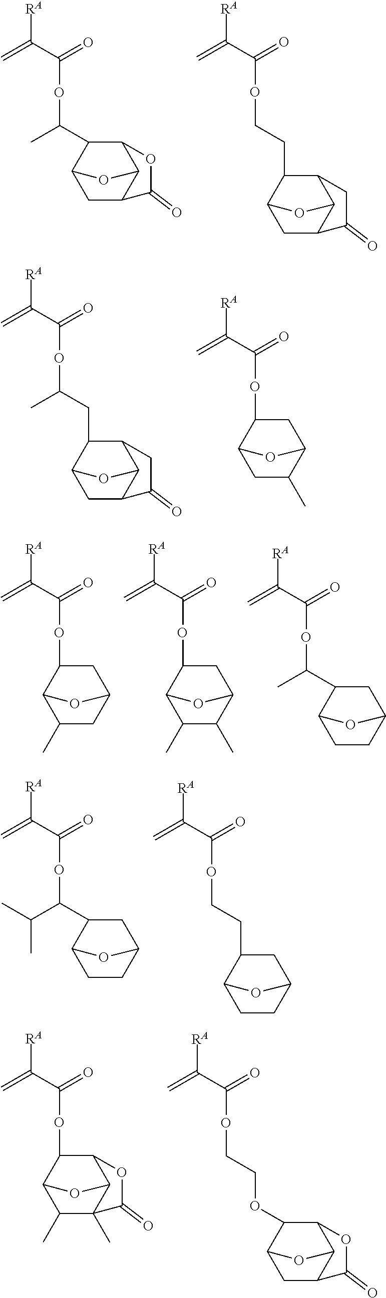

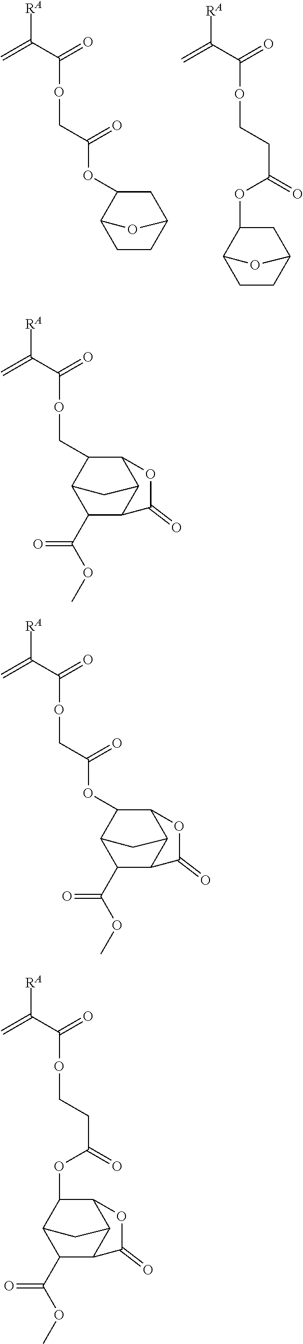

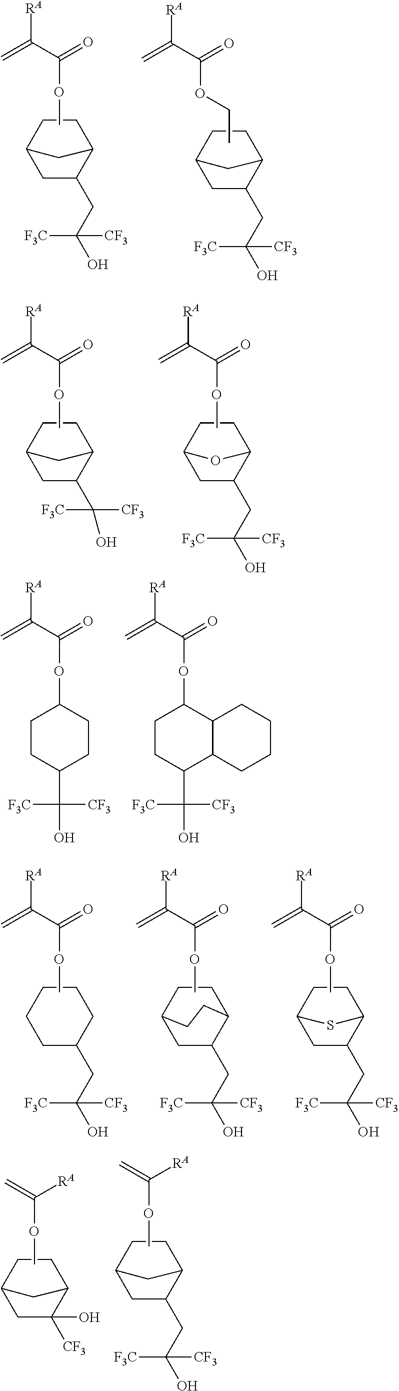

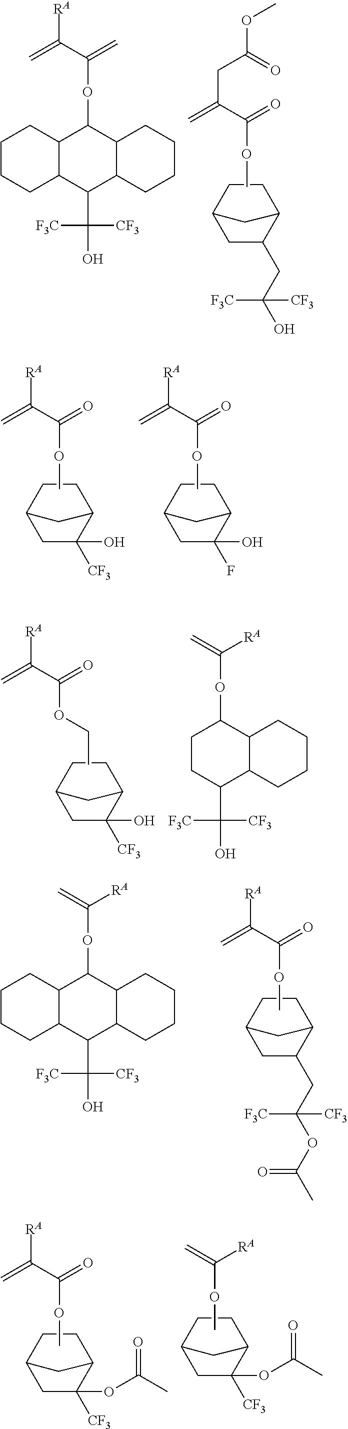

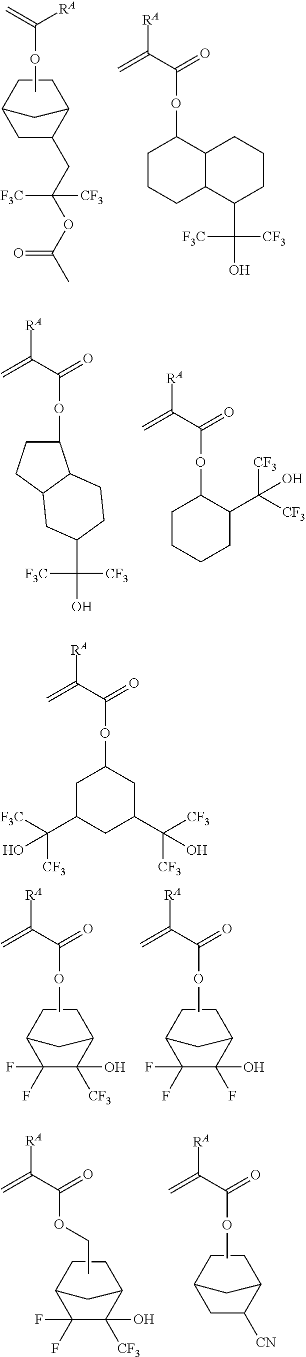

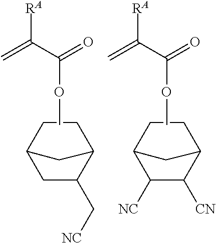

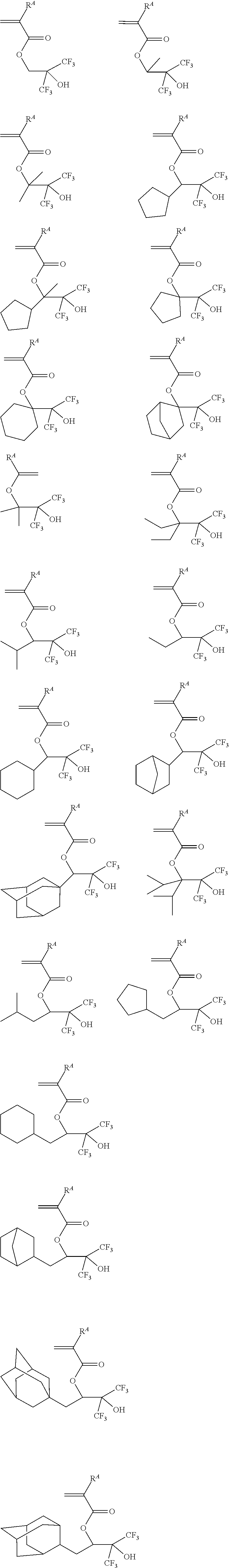

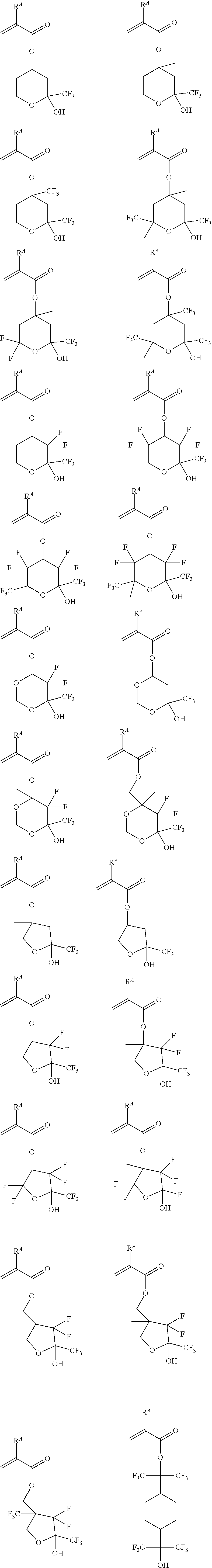

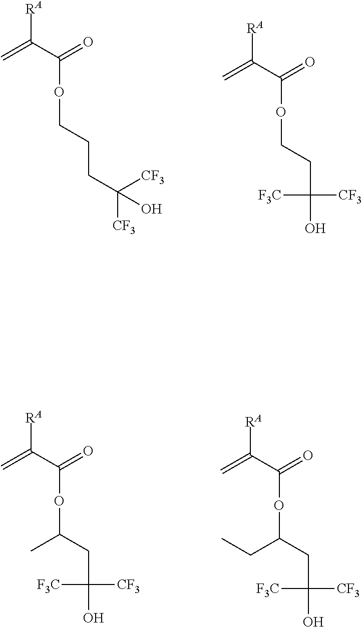

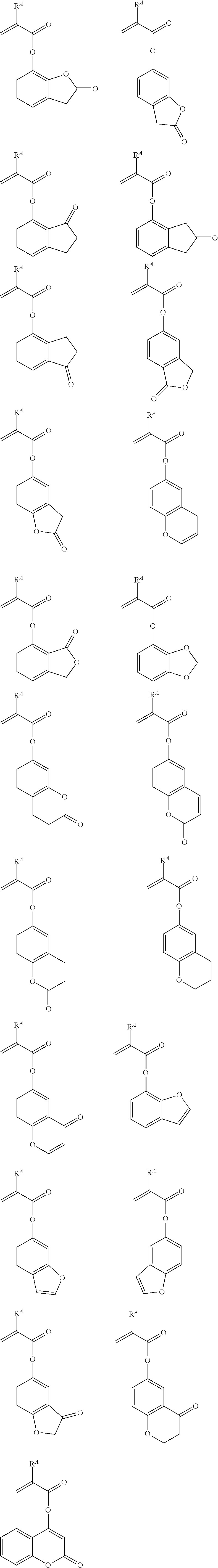

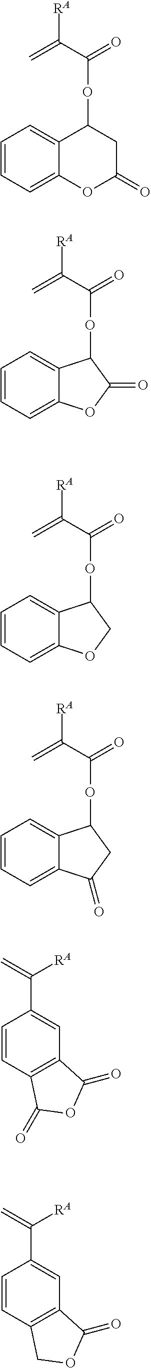

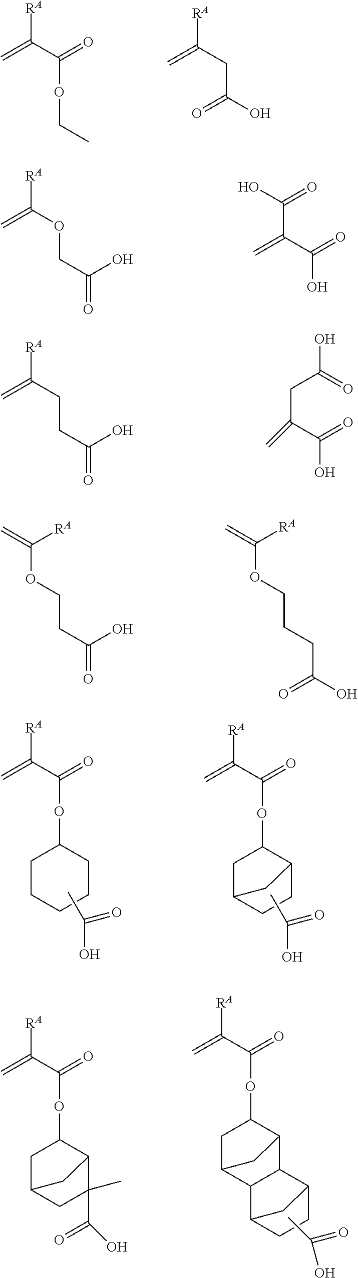

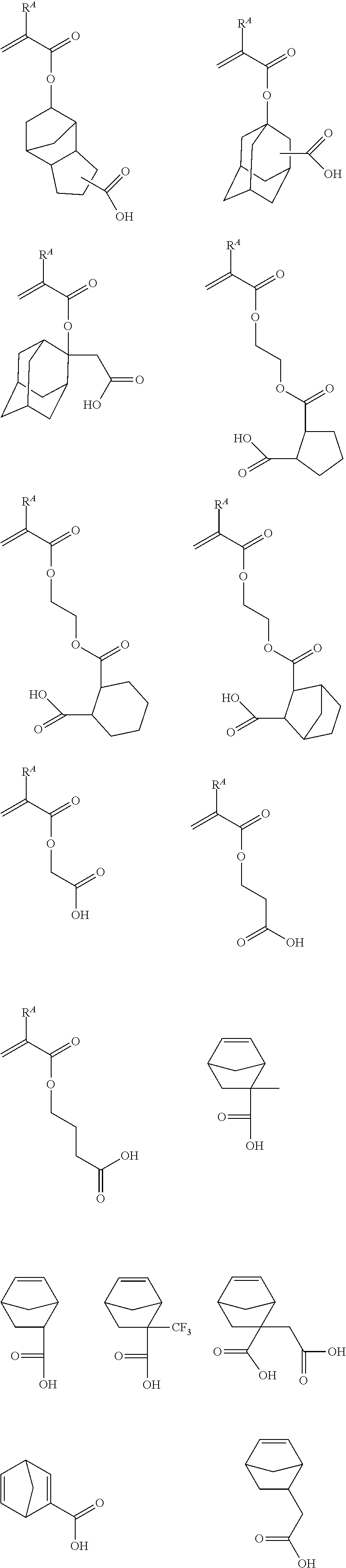

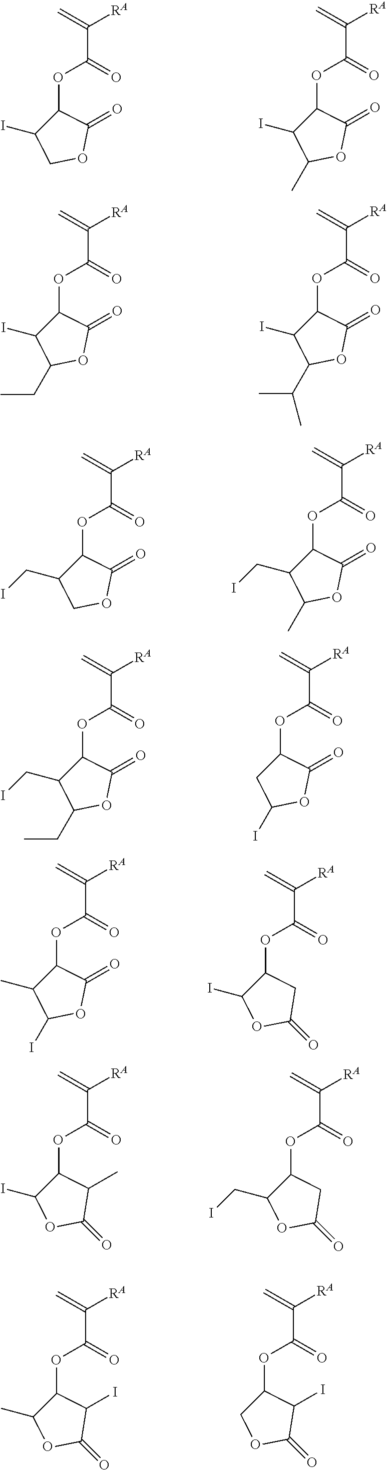

Where the polymer-bound acid generator also functions as a base polymer, it may further comprise repeat units (e) derived from indene, benzofuran, benzothiophene, acenaphthylene, chromone, coumarin, norbornadiene, or derivatives thereof. Examples of the monomer from which repeat units (e) are derived are given below, but not limited thereto.

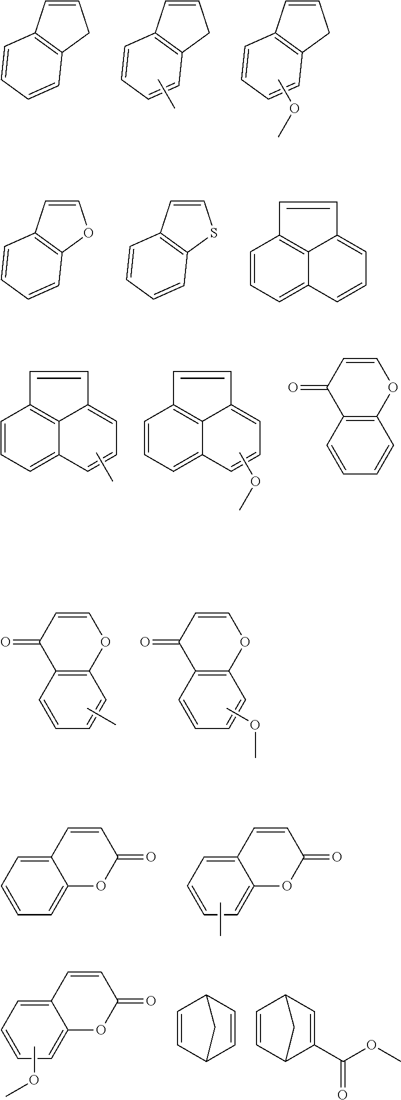

Where the polymer-bound acid generator also functions as a base polymer, it may further comprise repeat units (f) derived from indane, vinylpyridine, vinylcarbazole, or derivatives thereof.

The polymer-bound acid generator may further comprise repeat units (g) derived from an onium salt containing a polymerizable unsaturated bond, other than repeat units (a1) and (a2). Examples of repeat units (g) are described in JP-A 2017-008181, paragraph [0060].

The base polymer for formulating the positive resist composition comprises repeat units (a1) and/or (a2) and repeat units (b1) and/or (b2) having an acid labile group as essential components and additional repeat units (c), (d), (e), (f), and (g) as optional components. A fraction of units (a1), (a2), (b1), (b2), (c), (d), (e), (f), and (g) is: preferably 0≤a1<1.0, 0≤a2<1.0, 0<a1+a2<1.0, 0≤b1<1.0, 0≤b2<1.0, 0<b1+b2<1.0, 0≤c≤0.9, 0≤d≤0.9, 0≤e≤0.8, 0.8≤f≤0.8, and 0≤g≤0.4; more preferably 0≤a1≤0.7, 0≤a2≤0.7, 0.02≤a1+a2≤0.7, 0≤b1≤0.9, 0≤b2≤0.9, 0.1≤b1+b2≤0.9, 0≤c≤0.8, 0≤d≤0.8, 0≤e≤0.7, 0≤f≤0.7, and 0≤g≤0.3; and even more preferably 0≤a1≤0.5, 0≤a2≤0.5, 0.03≤a1+a2≤0.5, 0≤b1≤0.8, 0≤b2<0.8, 0.1≤b1+b2<0.8, 0≤c≤0.7, 0≤d≤0.7, 0≤e≤0.6, ≤f≤0.6, and 0≤g≤0.2. Notably, a1+a2+b1+b2+c+d+e+f+g=1.0.

For the base polymer for formulating the negative resist composition, an acid labile group is not necessarily essential. The base polymer comprises essentially repeat units (a1) and/or (a2), and optionally repeat units (c), (d), (e), (f) and/or (g). A fraction of these units is: preferably 0≤a1<1.0, 0≤a2<1.0, 0<a1+a2<1.0, 0≤c≤1.0, 0≤d≤0.9, 0≤e≤0.8, 0≤f≤0.8, and 0≤g≤0.4; more preferably 0≤a1<0.7, 0≤a2≤0.7, 0.02≤a1+a2≤0.7, 0.2≤c≤1.0, 0≤d≤0.8, 0≤e≤0.7, 0≤f≤0.7, and 0≤g≤0.3; and even more preferably 0≤a1≤0.5, 0≤a2≤0.5, 0.03≤a1+a2≤0.5, 0.3≤c≤1.0, 0≤d≤0.75, 0≤e≤0.6, 0≤f≤0.6, and 0≤g≤0.2. Notably, a1+a2+c+d+e+f+g=1.0.

The polymer-bound acid generator may be synthesized by any desired methods, for example, by dissolving one or more monomers selected from the monomers corresponding to the foregoing repeat units in an organic solvent, adding a radical polymerization initiator thereto, and heating for polymerization. Examples of the organic solvent which can be used for polymerization include toluene, benzene, tetrahydrofuran (THF), diethyl ether, and dioxane. Examples of the polymerization initiator used herein include 2,2′-azobisisobutyronitrile (AIBN), 2,2′-azobis(2,4-dimethylvaleronitrile), dimethyl 2,2-azobis(2-methylpropionate), benzoyl peroxide, and lauroyl peroxide. Preferably, the reaction temperature is 50 to 80° C. and the reaction time is 2 to 100 hours, more preferably 5 to 20 hours.

Where a monomer having a hydroxy group is copolymerized, the hydroxy group may be replaced by an acetal group susceptible to deprotection with acid, typically ethoxyethoxy, prior to polymerization, and the polymerization be followed by deprotection with weak acid and water. Alternatively, the hydroxy group may be replaced by an acetyl, formyl, pivaloyl or similar group prior to polymerization, and the polymerization be followed by alkaline hydrolysis.

When hydroxystyrene or hydroxyvinylnaphthalene is copolymerized, an alternative method is possible. Specifically, acetoxystyrene or acetoxyvinylnaphthalene is used instead of hydroxystyrene or hydroxyvinylnaphthalene, and after polymerization, the acetoxy group is deprotected by alkaline hydrolysis, for thereby converting the polymer product to hydroxystyrene or hydroxyvinylnaphthalene. For alkaline hydrolysis, a base such as aqueous ammonia or triethylamine may be used. Preferably the reaction temperature is −20° C. to 100° C., more preferably 0° C. to 60° C., and the reaction time is 0.2 to 100 hours, more preferably 0.5 to 20 hours.

The polymer-bound acid generator should preferably have a weight average molecular weight (Mw) in the range of 1,000 to 500,000, and more preferably 2,000 to 30,000, as measured by GPC versus polystyrene standards using tetrahydrofuran (THF) solvent. A Mw in the range ensures that a resist film has satisfactory heat resistance.

If a polymer has a wide molecular weight distribution or dispersity (Mw/Mn), which indicates the presence of lower and higher molecular weight polymer fractions, there is a possibility that foreign matter is left on the pattern or the pattern profile is degraded. The influences of Mw and Mw/Mn become stronger as the pattern rule becomes finer. Therefore, the polymer-bound acid generator should preferably have a narrow dispersity (Mw/Mn) of 1.0 to 2.0, especially 1.0 to 1.5, in order to provide a resist composition suitable for micropatterning to a small feature size.

It is understood that a blend of two or more polymer-bound acid generators which differ in compositional ratio, Mw or Mw/Mn is acceptable.

### Organic Solvent

The resist composition may contain an organic solvent. The organic solvent used herein is not particularly limited as long as the foregoing and other components are soluble therein. Examples of the organic solvent are described in JP-A 2008-111103, paragraphs [0144]-[0145] (U.S. Pat. No. 7,537,880). Exemplary solvents include ketones such as cyclohexanone, cyclopentanone, methyl-2-n-pentyl ketone and 2-heptanone; alcohols such as 3-methoxybutanol, 3-methyl-3-methoxybutanol, 1-methoxy-2-propanol, 1-ethoxy-2-propanol, and diacetone alcohol (DAA); ethers such as propylene glycol monomethyl ether (PGME), ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; and lactones such as γ-butyrolactone, which may be used alone or in admixture.

The organic solvent is preferably added in an amount of 100 to 10,000 parts, and more preferably 200 to 8,000 parts by weight per 100 parts by weight of the base polymer.

### Quencher

The resist composition may further contain a quencher. As used herein, the quencher refers to a compound capable of trapping the acid, which is generated by the acid generator in the resist composition upon light exposure, to prevent the acid from diffusing to the unexposed region.

The quencher is typically selected from conventional basic compounds. Conventional basic compounds include primary, secondary, and tertiary aliphatic amines, mixed amines, aromatic amines, heterocyclic amines, nitrogen-containing compounds with carboxy group, nitrogen-containing compounds with sulfonyl group, nitrogen-containing compounds with hydroxy group, nitrogen-containing compounds with hydroxyphenyl group, alcoholic nitrogen-containing compounds, amide derivatives, imide derivatives, and carbamate derivatives. Also included are primary, secondary, and tertiary amine compounds, specifically amine compounds having a hydroxy group, ether bond, ester bond, lactone ring, cyano group, or sulfonic ester bond as described in JP-A 2008-111103, paragraphs [0146]-[0164], and compounds having a carbamate group as described in JP 3790649. Addition of a basic compound may be effective for further suppressing the diffusion rate of acid in the resist film or correcting the pattern profile.

Onium salts such as sulfonium salts, iodonium salts and ammonium salts of sulfonic acids which are not fluorinated at α-position may also be used as the quencher. While an α-fluorinated sulfonic acid, imide acid, and methide acid are necessary to deprotect the acid labile group of carboxylic acid ester, an α-non-fluorinated sulfonic acid or carboxylic acid is released by salt exchange with an α-non-fluorinated onium salt. An α-non-fluorinated sulfonic acid and a carboxylic acid function as a quencher because they do not induce deprotection reaction.

Also, onium salts of carboxylic acid having the formula (1) are useful quenchers.

R¹⁰¹—CO₂⁻Mq⁺ (1)

In formula (1), R¹⁰¹ is a C₁-C₄₀ hydrocarbyl group which may contain a heteroatom. The hydrocarbyl group may be saturated or unsaturated and straight, branched or cyclic. Examples thereof include C₁-C₄₀ alkyl groups such as methyl, ethyl, n-propyl, isopropyl, n-butyl, sec-butyl, tert-butyl, tert-pentyl, n-pentyl, n-hexyl, n-octyl, 2-ethylhexyl, n-nonyl, and n-decyl; C₃-C₄₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decanyl, adamantyl, and adamantylmethyl; C₂-C₄₀ alkenyl groups such as vinyl, allyl, propenyl, butenyl, and hexenyl; C₃-C₄₀ cyclic unsaturated aliphatic hydrocarbyl groups such as cyclohexenyl; C₆-C₄₀ aryl groups such as phenyl, naphthyl, alkylphenyl groups, e.g., 2-methylphenyl, 3-methylphenyl, 4-methylphenyl, 4-ethylphenyl, 4-tert-butylphenyl, 4-n-butylphenyl, dialkylphenyl groups, e.g., 2,4-dimethylphenyl and 2,4,6-triisopropylphenyl, alkylnaphthyl groups, e.g., methylnaphthyl and ethylnaphthyl, dialkylnaphthyl groups, e.g., dimethylnaphthyl and diethylnaphthyl; heteroaryl groups such as thienyl; and C₇-C₄₀ aralkyl groups such as benzyl, 1-phenylethyl and 2-phenylethyl.

In the hydrocarbyl group, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy moiety, fluorine, chlorine, bromine, iodine, cyano moiety, carbonyl moiety, ether bond, ester bond, sulfonic ester bond, carbonate bond, lactone ring, sultone ring, carboxylic anhydride (—C(═O)—O—C(═O)—), or haloalkyl moiety. Examples of the heteroatom-containing hydrocarbyl group include fluoroalkyl groups such as trifluoromethyl, trifluoroethyl, 2,2,2-trifluoro-1-methyl-1-hydroxyethyl, 2,2,2-trifluoro-1-(trifluoromethyl)-1-hydroxyethyl; fluoroaryl groups such as pentafluorophenyl and 4-trifluoromethylphenyl; heteroaryl groups such as thienyl and indolyl; 4-hydroxyphenyl, alkoxyphenyl groups such as 4-methoxyphenyl, 3-methoxyphenyl, 2-methoxyphenyl, 4-ethoxyphenyl, 4-tert-butoxyphenyl, and 3-tert-butoxyphenyl; alkoxynaphthyl groups such as methoxynaphthyl, ethoxynaphthyl, n-propoxynaphthyl and n-butoxynaphthyl; dialkoxynaphthyl groups such as dimethoxynaphthyl and diethoxynaphthyl; and aryloxoalkyl groups, typically 2-aryl-2-oxoethyl groups such as 2-phenyl-2-oxoethyl, 2-(1-naphthyl)-2-oxoethyl, and 2-(2-naphthyl)-2-oxoethyl.

In the onium salt of carboxylic acid, an anion having the formula (TA) is preferred.

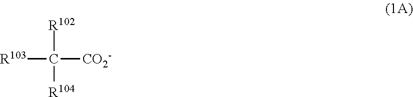

Herein R¹⁰² and R¹⁰³ are each independently hydrogen, fluorine, or trifluoromethyl. R¹⁰⁴ is hydrogen, hydroxy, or a C₁-C₃₅ hydrocarbyl group which may contain a heteroatom. Examples of the hydrocarbyl group which may contain a heteroatom are as exemplified above for R¹⁰¹.

In formula (1), Mq⁺ is an onium cation. The preferred onium cations are sulfonium, iodonium and ammonium cations, with the sulfonium and iodonium cations being more preferred. Examples of the sulfonium cations are as exemplified above for the cation in the repeat unit having formula (a1). Examples of the iodonium cations are as exemplified above for the cation in the repeat unit having formula (a2).

Also useful are quenchers of polymer type as described in U.S. Pat. No. 7,598,016 (JP-A 2008-239918). The polymeric quencher segregates at the resist film surface after coating and thus enhances the rectangularity of resist pattern. When a protective film is applied as is often the case in the immersion lithography, the polymeric quencher is also effective for preventing a film thickness loss of resist pattern or rounding of pattern top.

When the resist composition contains a quencher, the quencher is preferably added in an amount of 0 to 5 parts by weight, more preferably 0 to 4 parts by weight per 100 parts by weight of the base polymer. The quencher may be used alone or in admixture.

### Other Components

In addition to the foregoing components, the resist composition may further contain other components such as an acid generator other than the polymer-bound acid generator, surfactant, dissolution inhibitor, crosslinker, water repellency improver, and acetylene alcohol. Each additional component may be used alone or in admixture of two or more.

The other acid generator is typically a compound (PAG) capable of generating an acid upon exposure to actinic ray or radiation. Although the PAG used herein may be any compound capable of generating an acid upon exposure to high-energy radiation, those compounds capable of generating sulfonic acid, imide acid (imidic acid) or methide acid are preferred. Suitable PAGs include sulfonium salts, iodonium salts, sulfonyldiazomethane, N-sulfonyloxyimide, and oxime-O-sulfonate acid generators. Exemplary PAGs are described in JP-A 2008-111103, paragraphs [0122]-[0142] (U.S. Pat. No. 7,537,880).

Sulfonium salts having the formula (2-1) and iodonium salts having the formula (2-2) are also useful as the PAG.

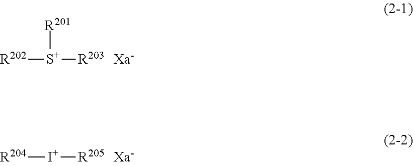

In formulae (2-1) and (2-2), R²⁰¹ to R²⁰⁵ are each independently halogen or a C₁-C₂₀ hydrocarbyl group which may contain a heteroatom. Suitable halogen atoms are as exemplified above. Examples of the C₁-C₂₀ hydrocarbyl group are as exemplified above for the hydrocarbyl groups R² to R⁶ in formulae (a1) and (a2). In the hydrocarbyl group, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy moiety, fluorine, chlorine, bromine, iodine, cyano moiety, nitro moiety, carbonyl moiety, ether bond, ester bond, sulfonic ester bond, carbonate bond, lactone ring, sultone ring, carboxylic anhydride (—C(═O)—O—C(═O)—), or haloalkyl moiety. Also, R²⁰¹ and R²⁰² may bond together to form a ring with the sulfur atom to which they are attached. Examples of the ring are as exemplified above for the ring that R² and R³ in formula (a1), taken together, form with the sulfur atom to which they are attached.

Examples of the cation of the sulfonium salt having formula (2-1) are as exemplified above for the cation in repeat unit (a1). Examples of the cation of the iodonium salt having formula (2-2) are as exemplified above for the cation in repeat unit (a2).

In formulae (2-1) and (2-2), Xa⁻ is an anion selected from the formulae (2A) to (2D).

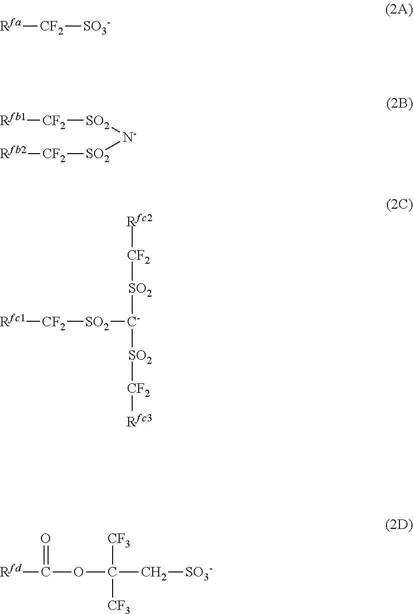

In formula (2A), R^{fa} is fluorine or a C₁-C₄₀ hydrocarbyl group which may contain a heteroatom. The hydrocarbyl group may be saturated or unsaturated and straight, branched or cyclic. Examples thereof are as will be exemplified later for R²¹¹ in formula (2A′).

Of the anions of formula (2A), a structure having formula (2A′) is preferred.

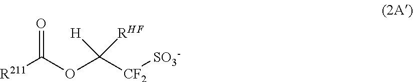

In formula (2A′), R^{HF} is hydrogen or trifluoromethyl, preferably trifluoromethyl.

R²¹¹ is a C₁-C₃₈ hydrocarbyl group which may contain a heteroatom. Suitable heteroatoms include oxygen, nitrogen, sulfur and halogen, with oxygen being preferred. Of the hydrocarbyl groups, those of 6 to 30 carbon atoms are preferred because a high resolution is available in fine pattern formation. The hydrocarbyl group R²¹¹ may be saturated or unsaturated and straight, branched or cyclic. Suitable hydrocarbyl groups include C₁-C₃₈ alkyl groups such as methyl, ethyl, n-propyl, isopropyl, butyl, isobutyl, sec-butyl, tert-butyl, pentyl, neopentyl, hexyl, heptyl, 2-ethylhexyl, nonyl, undecyl, tridecyl, pentadecyl, heptadecyl, icosanyl; C₃-C₃₈ cyclic saturated hydrocarbyl groups such as cyclopentyl, cyclohexyl, 1-adamantyl, 2-adamantyl, 1-adamantylmethyl, norbornyl, norbornylmethyl, tricyclodecanyl, tetracyclododecanyl, tetracyclododecanylmethyl, dicyclohexylmethyl; C₂-C₃₈ unsaturated aliphatic hydrocarbyl groups such as allyl and 3-cyclohexenyl; C₆-C₃₈ aryl groups such as phenyl, 1-naphthyl, 2-naphthyl; C₇-C₃₈ aralkyl groups such as benzyl and diphenylmethyl, and combinations thereof.

In the hydrocarbyl group, some or all of the hydrogen atoms may be substituted by a moiety containing a heteroatom such as oxygen, sulfur, nitrogen or halogen, or some constituent —CH₂— may be replaced by a moiety containing a heteroatom such as oxygen, sulfur or nitrogen, so that the group may contain a hydroxy, fluorine, chlorine, bromine, iodine, cyano, nitro, carbonyl, ether bond, ester bond, sulfonic ester bond, carbonate bond, lactone ring, sultone ring, carboxylic anhydride (—C(═O)—O—C(═O)—) or haloalkyl moiety. Examples of the heteroatom-containing hydrocarbyl group include tetrahydrofuryl, methoxymethyl, ethoxymethyl, methylthiomethyl, acetamidomethyl, trifluoroethyl, (2-methoxyethoxy)methyl, acetoxymethyl, 2-carboxy-1-cyclohexyl, 2-oxopropyl, 4-oxo-1-adamantyl, and 3-oxocyclohexyl.

With respect to the synthesis of the sulfonium salt having an anion of formula (2A′), reference is made to JP-A 2007-145797, JP-A 2008-106045, JP-A 2009-007327, and JP-A 2009-258695. Also useful are the sulfonium salts described in JP-A 2010-215608, JP-A 2012-041320, JP-A 2012-106986, and JP-A 2012-153644.

Examples of the anion having formula (2A) are as exemplified for the anion having formula (TA) in JP-A 2018-197853.

In formula (2B), R^{fb1} and R^{fb2} are each independently fluorine or a C₁-C₄₀ hydrocarbyl group which may contain a heteroatom. The hydrocarbyl group may be saturated or unsaturated and straight, branched or cyclic. Suitable hydrocarbyl groups are as exemplified above for R²¹¹ in formula (2A′). Preferably R^{fb1} and R^{fb2} each are fluorine or a straight C₁-C₄ fluorinated alkyl group. A pair of R^{fb1} and R^{fb2} may bond together to form a ring with the linkage (—CF₂—SO₂—N⁻—SO₂—CF₂—) to which they are attached, and the ring-forming pair is preferably a fluorinated ethylene or fluorinated propylene group.

In formula (2C), R^{fc1}, R^{fc2} and R^{fc3} are each independently fluorine or a C₁-C₄₀ hydrocarbyl group which may contain a heteroatom. The hydrocarbyl group may be saturated or unsaturated and straight, branched or cyclic. Suitable hydrocarbyl groups are as exemplified above for R²¹¹ in formula (2A′). Preferably R^{fc1}, R^{fc2} and R^{fc3} each are fluorine or a straight C₁-C₄ fluorinated alkyl group. A pair of R^{fc1} and R^{fc2} may bond together to form a ring with the linkage (—CF₂—SO₂—C⁻—SO₂—CF₂—) to which they are attached, and the ring-forming pair is preferably a fluorinated ethylene or fluorinated propylene group.

In formula (2D), R^{fd} is a C₁-C₄₀ hydrocarbyl group which may contain a heteroatom. The hydrocarbyl group may be saturated or unsaturated and straight, branched or cyclic. Suitable hydrocarbyl groups are as exemplified above for R²¹¹.

With respect to the synthesis of the sulfonium salt having an anion of formula (2D), reference is made to JP-A 2010-215608 and JP-A 2014-133723.

Examples of the anion having formula (2D) are as exemplified for the anion having formula (1D) in JP-A 2018-197853.

The compound having the anion of formula (2D) has a sufficient acid strength to cleave acid labile groups in the base polymer because it is free of fluorine at α-position of sulfo group, but has two trifluoromethyl groups at β-position. Thus the compound is a useful PAG.

Also compounds having the formula (3) are useful as the PAG.

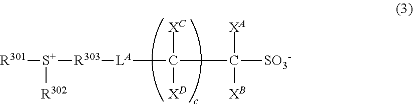

In formula (3), R³⁰¹ and R³⁰² are each independently halogen or a C₁-C₃₀ hydrocarbyl group which may contain a heteroatom. R³⁰³ is a C₁-C₃₀ hydrocarbylene group which may contain a heteroatom. R³⁰¹ and R³⁰², or R³⁰¹ and R³⁰³ may bond together to form a ring with the sulfur atom to which they are attached. Exemplary rings are the same as described above for the ring that R² and R³ in formula (a1), taken together, form with the sulfur atom to which they are attached.

The hydrocarbyl groups R³⁰¹ and R³⁰² may be saturated or unsaturated and straight, branched or cyclic. Examples thereof include C₁-C₃₀ alkyl groups such as methyl, ethyl, n-propyl, isopropyl, n-butyl, isobutyl, sec-butyl, tert-butyl, n-pentyl, tert-pentyl, n-hexyl, n-octyl, 2-ethylhexyl, n-nonyl, and n-decyl; C₃-C₃₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decanyl, and adamantyl; C₆-C₃₀ aryl groups such as phenyl, methylphenyl, ethylphenyl, n-propylphenyl, isopropylphenyl, n-butylphenyl, isobutylphenyl, sec-butylphenyl, tert-butylphenyl, naphthyl, methylnaphthyl, ethylnaphthyl, n-propylnaphthyl, isopropylnaphthyl, n-butylnaphthyl, isobutylnaphthyl, sec-butylnaphthyl, tert-butylnaphthyl, and anthracenyl; and combinations thereof. In the hydrocarbyl group, some or all of the hydrogen atoms may be substituted by a moiety containing a heteroatom such as oxygen, sulfur, nitrogen or halogen, or some constituent —CH₂— may be replaced by a moiety containing a heteroatom such as oxygen, sulfur or nitrogen, so that the group may contain a hydroxy moiety, fluorine, chlorine, bromine, iodine, cyano moiety, nitro moiety, carbonyl moiety, ether bond, ester bond, sulfonic ester bond, carbonate bond, lactone ring, sultone ring, carboxylic anhydride (—C(═O)—O—C(═O)—) or haloalkyl moiety.

The hydrocarbylene group R³⁰³ may be saturated or unsaturated and straight, branched or cyclic. Examples thereof include C₁-C₃₀ alkanediyl groups such as methanediyl, ethane-1,1-diyl, ethane-1,2-diyl, propane-1,3-diyl, butane-1,4-diyl, pentane-1,5-diyl, hexane-1,6-diyl, heptane-1,7-diyl, octane-1,8-diyl, nonane-1,9-diyl, decane-1,10-diyl, undecane-1,11-diyl, dodecane-1,12-diyl, tridecane-1,13-diyl, tetradecane-1,14-diyl, pentadecane-1,15-diyl, hexadecane-1,16-diyl, and heptadecane-1,17-diyl; C₃-C₃₀ cyclic saturated hydrocarbylene groups such as cyclopentanediyl, cyclohexanediyl, norbornanediyl and adamantanediyl; C₆-C₃₀ arylene groups such as phenylene, methylphenylene, ethylphenylene, n-propylphenylene, isopropylphenylene, n-butylphenylene, isobutylphenylene, sec-butylphenylene, tert-butylphenylene, naphthylene, methylnaphthylene, ethylnaphthylene, n-propylnaphthylene, isopropylnaphthylene, n-butylnaphthylene, isobutylnaphthylene, sec-butylnaphthylene, and tert-butylnaphthylene; and combinations thereof. In the hydrocarbylene group, some or all of the hydrogen atoms may be substituted by a moiety containing a heteroatom such as oxygen, sulfur, nitrogen or halogen, or some constituent —CH₂— may be replaced by a moiety containing a heteroatom such as oxygen, sulfur or nitrogen, so that the group may contain a hydroxy moiety, fluorine, chlorine, bromine, iodine, cyano moiety, nitro moiety, carbonyl moiety, ether bond, ester bond, sulfonic ester bond, carbonate bond, lactone ring, sultone ring, carboxylic anhydride (—C(═O)—O—C(═O)—) or haloalkyl moiety. Of the heteroatoms, oxygen is preferred.

In formula (3), L^{A} is a single bond, ether bond or a C₁-C₂₀ hydrocarbylene group which may contain a heteroatom. The hydrocarbylene group may be saturated or unsaturated and straight, branched or cyclic. Examples thereof are as exemplified above for R³⁰³.

In formula (3), X^{A}, X^{B}, X^{C} and X^{D} are each independently hydrogen, fluorine or trifluoromethyl, with the proviso that at least one of X^{A}, X^{B}, X^{C} and X^{D} is fluorine or trifluoromethyl, and c is an integer of 0 to 3.

Of the PAGs having formula (3), those having formula (3′) are preferred.

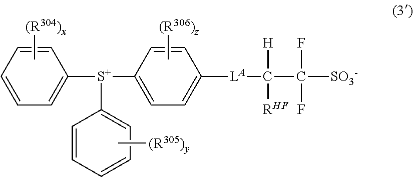

In formula (3′), L^{A} is as defined above. R^{HF} is hydrogen or trifluoromethyl, preferably trifluoromethyl. R³⁰⁴, R³⁰⁵ and R³⁰⁶ are each independently hydrogen or a C₁-C₂₀ hydrocarbyl group which may contain a heteroatom. The hydrocarbyl group may be saturated or unsaturated and straight, branched or cyclic. Examples thereof are as exemplified above for R²¹¹ in formula (2A′). The subscripts x and y are each independently an integer of 0 to 5, and z is an integer of 0 to 4.

Examples of the PAG having formula (3) are as exemplified for the PAG having formula (2) in JP-A 2017-026980.

Of the foregoing PAGs, those having an anion of formula (2A′) or (2D) are especially preferred because of reduced acid diffusion and high solubility in the resist solvent. Also, those having formula (3′) are especially preferred because of extremely reduced acid diffusion.

A sulfonium or iodonium salt having an anion containing an iodized or brominated aromatic ring may also be used as the PAG. Suitable are sulfonium and iodonium salts having the formulae (4-1) and (4-2).

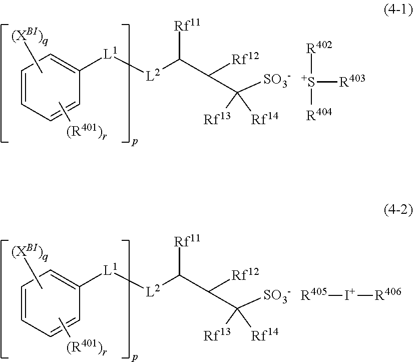

In formulae (4-1) and (4-2), p is an integer of 1 to 3, q is an integer of 1 to 5, and r is an integer of 0 to 3, and 1≤q+r≤5. Preferably, q is 1, 2 or 3, more preferably 2 or 3, and r is 0, 1 or 2.

In formulae (4-1) and (4-2), X^{B1} is iodine or bromine, and may be the same or different when p and/or q is 2 or more.

L¹ is a single bond, ether bond, ester bond, or a C₁-C₆ saturated hydrocarbylene group which may contain an ether bond or ester bond. The saturated hydrocarbylene group may be straight, branched or cyclic.

L² is a single bond or a C₁-C₂₀ divalent linking group when p is 1, and a C₁-C₂₀ (p+1)-valent linking group which may contain oxygen, sulfur or nitrogen when p is 2 or 3.

R⁴⁰¹ is a hydroxy group, carboxy group, fluorine, chlorine, bromine, amino group, or a C₁-C₂₀ saturated hydrocarbyl, C₁-C₂₀ saturated hydrocarbyloxy, C₂-C₁₀ saturated hydrocarbylcarbonyl, C₂-C₁₀ saturated hydrocarbyloxycarbonyl, C₂-C₂₀ saturated hydrocarbylcarbonyloxy or C₁-C₂₀ saturated hydrocarbylsulfonyloxy group, which may contain fluorine, chlorine, hydroxy, amino or ether bond, or —N(R^{401A})(R^{401B}), —N(R^{401C})—C(═O)—R^{401D} or —N(R^{401C})—C(═O)—O—R⁴⁰¹. R^{401A} and R^{401B} are each independently hydrogen or a C₁-C₆ saturated hydrocarbyl group. R^{401C} is hydrogen or a C₁-C₆ saturated hydrocarbyl group which may contain halogen, hydroxy, C₁-C₆ saturated hydrocarbyloxy, C₂-C₆ saturated hydrocarbylcarbonyl or C₂-C₆ saturated hydrocarbylcarbonyloxy moiety. R^{401D} is a C₁-C₁₆ aliphatic hydrocarbyl, C₆-C₁₂ aryl or C₇-C₁₅ aralkyl group, which may contain halogen, hydroxy, C₁-C₆ saturated hydrocarbyloxy, C₂-C₆ saturated hydrocarbylcarbonyl or C₂-C₆ saturated hydrocarbylcarbonyloxy moiety. The aliphatic hydrocarbyl group may be saturated or unsaturated and straight, branched or cyclic. The hydrocarbyl, hydrocarbyloxy, hydrocarbylcarbonyl, hydrocarbyloxycarbonyl, hydrocarbylcarbonyloxy, and hydrocarbylsulfonyloxy groups may be straight, branched or cyclic. Groups R⁴⁰¹ may be the same or different when p and/or r is 2 or more. Of these, R⁴⁰¹ is preferably hydroxy, —N(R^{401A})—C(═O)—R^{401B}, —N(R^{401A})—C(═O)—O—R^{401B}, fluorine, chlorine, bromine, methyl or methoxy.

In formulae (4-1) and (4-2), Rf¹ to Rf⁴ are each independently hydrogen, fluorine or trifluoromethyl, at least one of Rf¹ to Rf⁴ is fluorine or trifluoromethyl. Rf¹ and Rf², taken together, may form a carbonyl group. Preferably, both Rf³ and Rf⁴ are fluorine.

R⁴⁰² to R⁴⁰⁶ are each independently halogen or a C₁-C₂₀ hydrocarbyl group which may contain a heteroatom. The hydrocarbyl group may be saturated or unsaturated and straight, branched or cyclic. Examples thereof are as exemplified above for the hydrocarbyl groups R² to R⁶ in formulae (a1) and (a2). In the hydrocarbyl group, some or all of the hydrogen atoms may be substituted by hydroxy, carboxy, halogen, cyano, nitro, mercapto, sultone, sulfone, or sulfonium salt-containing moiety, and some constituent —CH₂— may be replaced by an ether bond, ester bond, carbonyl moiety, amide bond, carbonate bond or sulfonic ester bond. R⁴⁰² and R⁴⁰³ may bond together to form a ring with the sulfur atom to which they are attached. Exemplary rings are the same as described above for the ring that R² and R³ in formula (a1), taken together, form with the sulfur atom to which they are attached.

Examples of the cation in the sulfonium salt having formula (4-1) include those exemplified above as the cation in repeat unit (a1). Examples of the cation in the iodonium salt having formula (4-2) include those exemplified above as the cation in repeat unit (a2).

Examples of the anion in the onium salts having formulae (4-1) and (4-2) are shown below, but not limited thereto. Herein X^{BI} is as defined above.

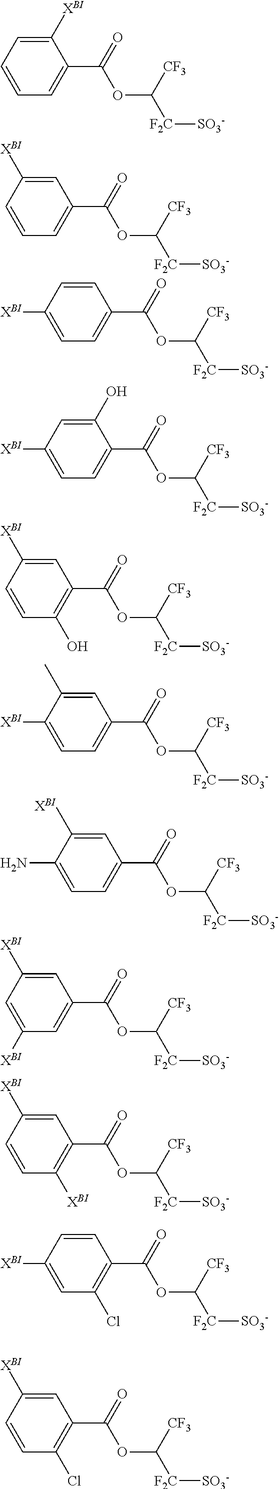

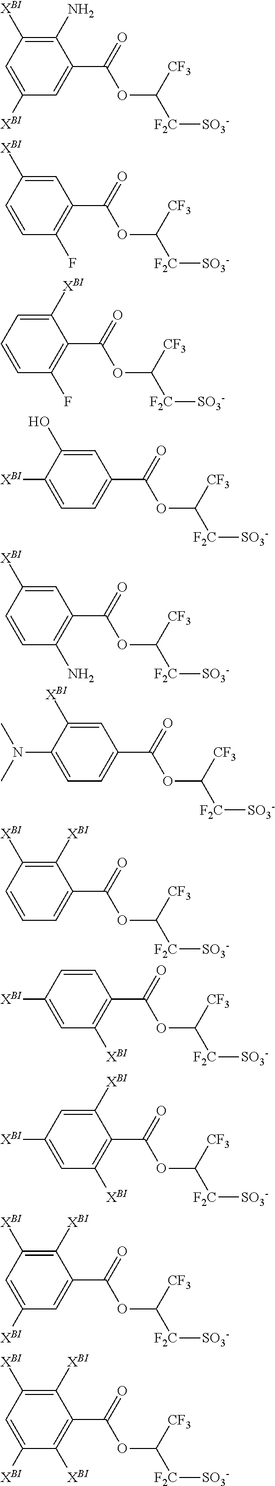

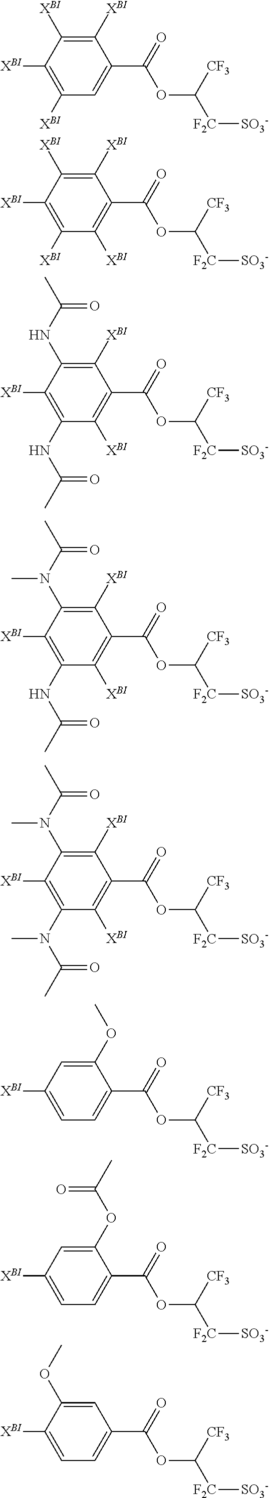

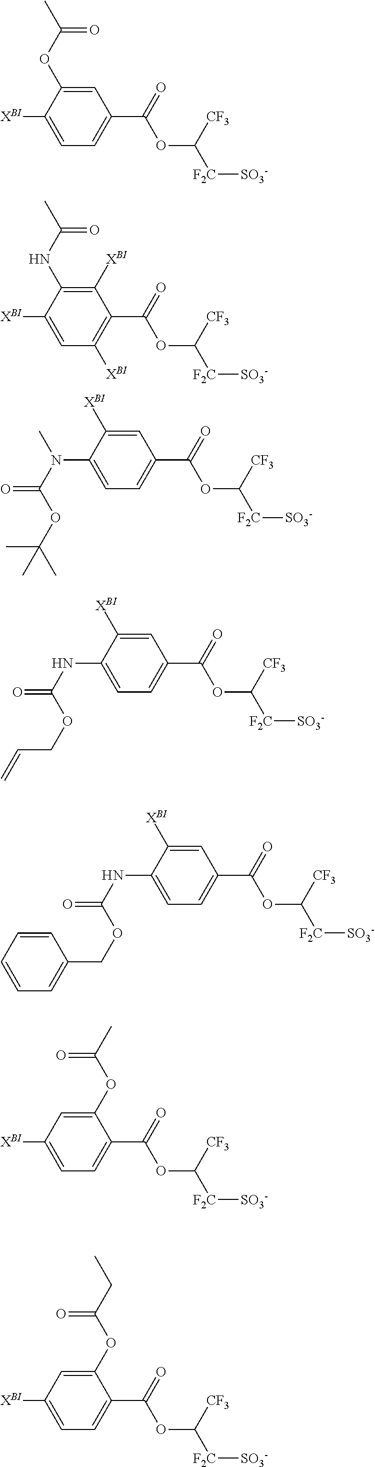

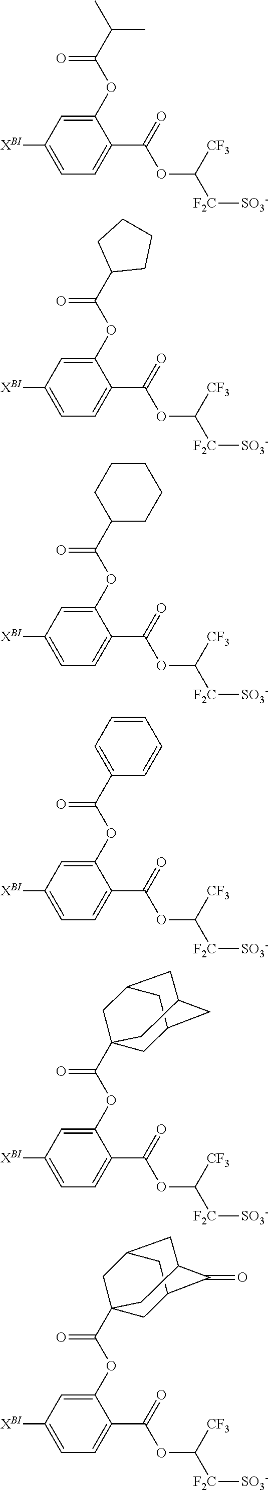

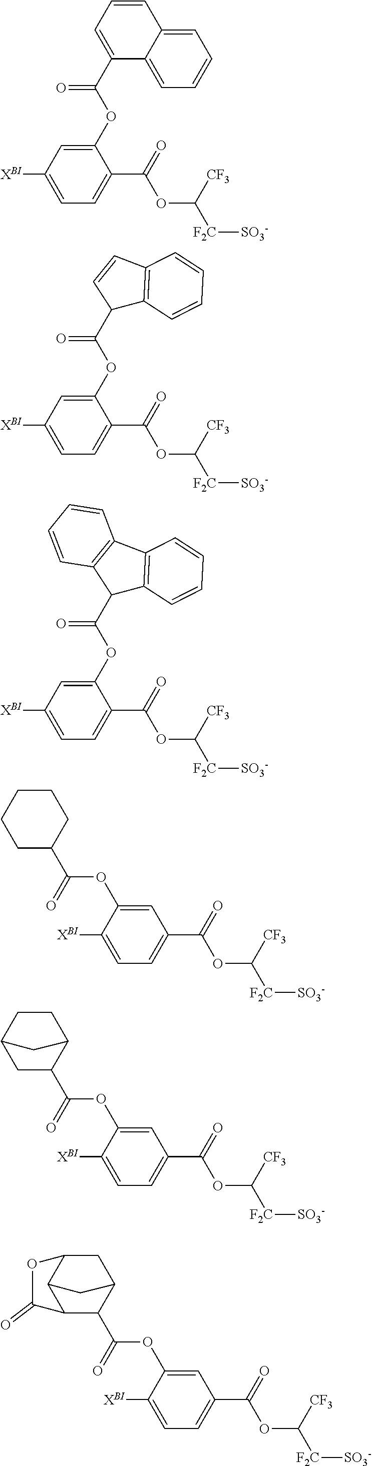

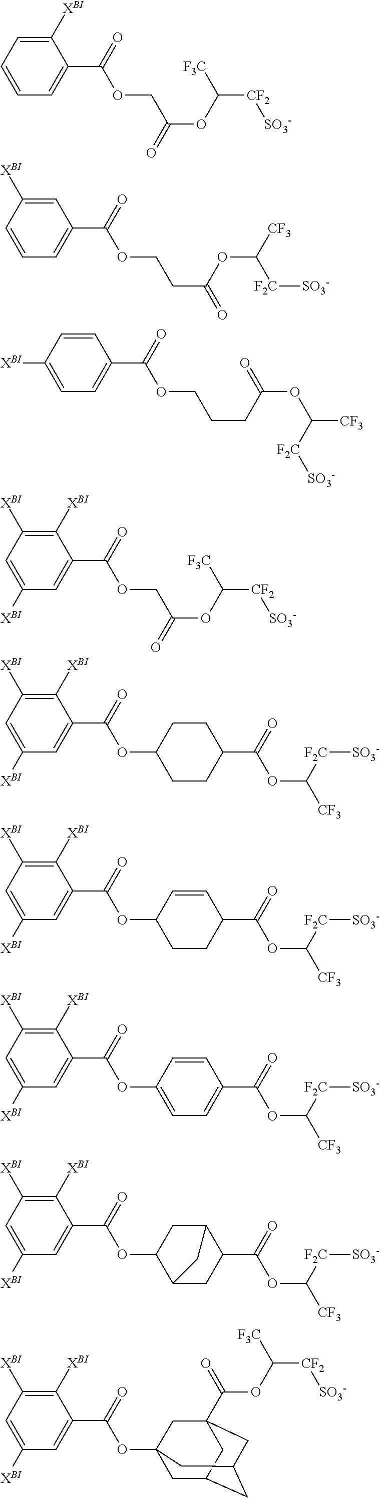

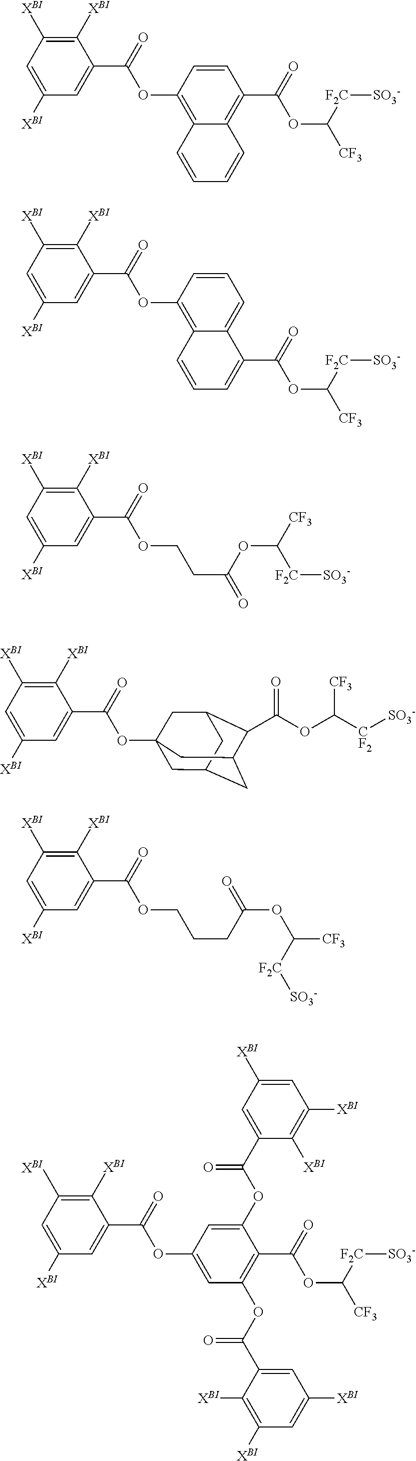

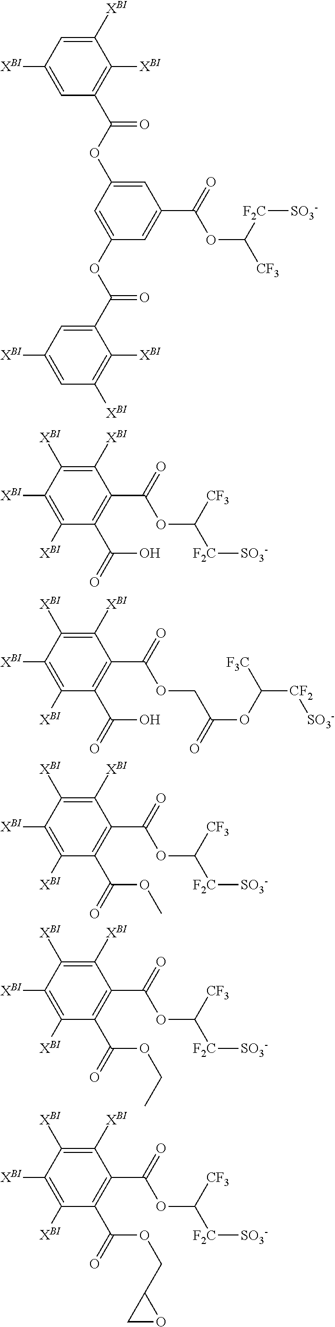

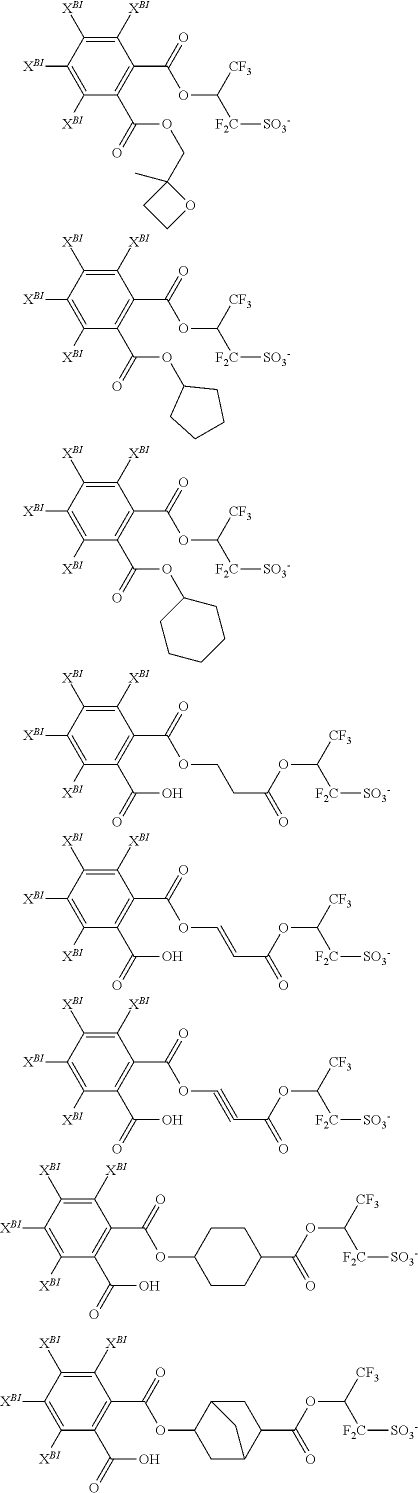

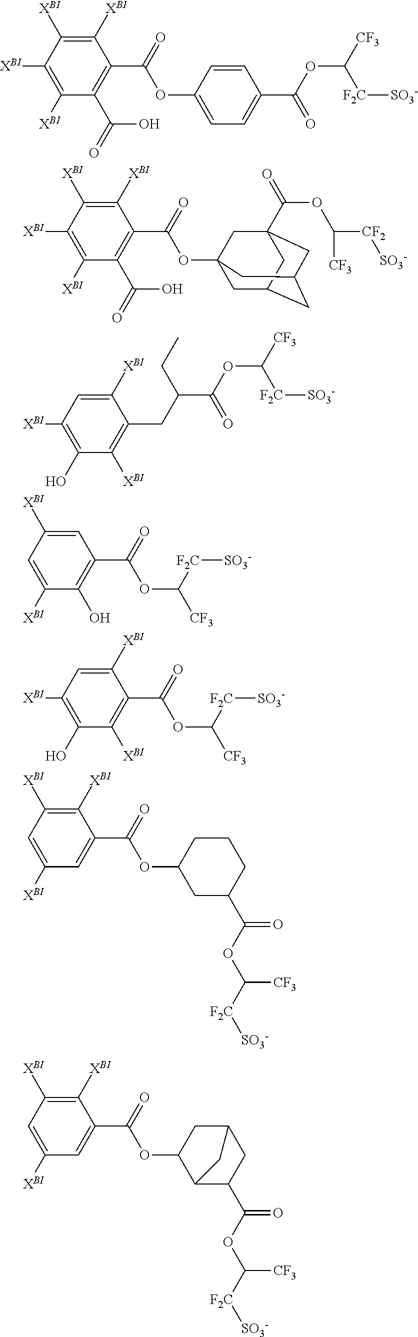

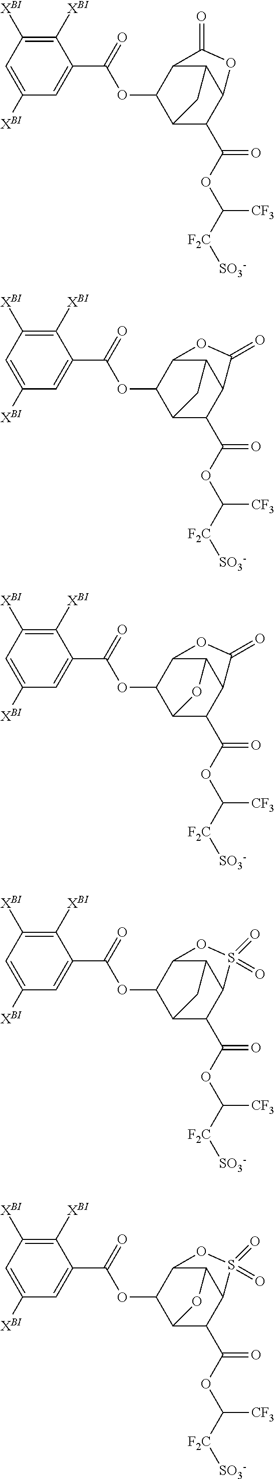

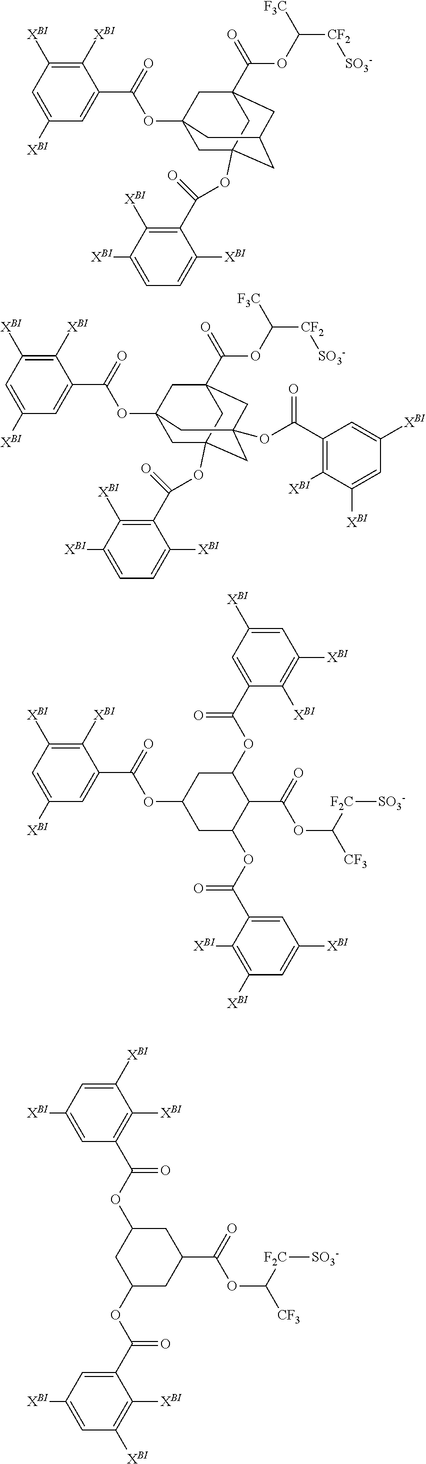

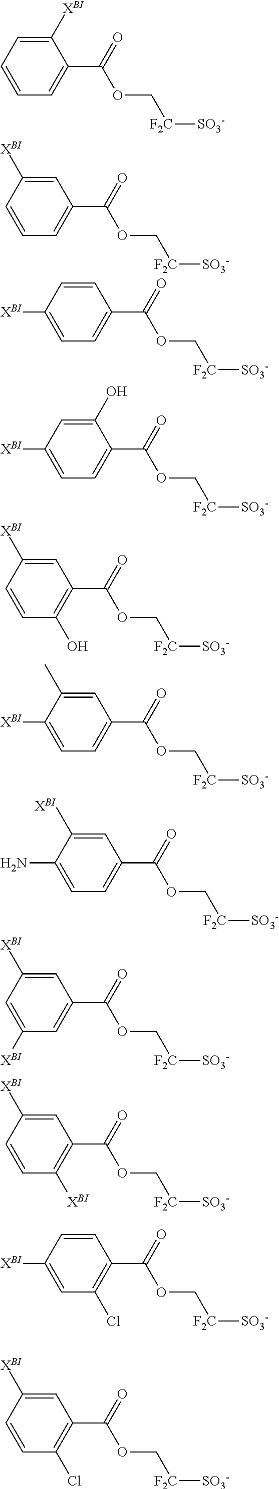

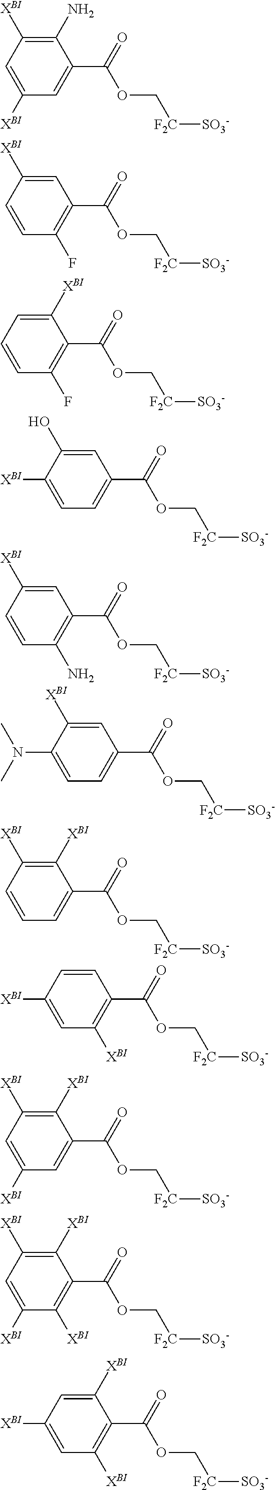

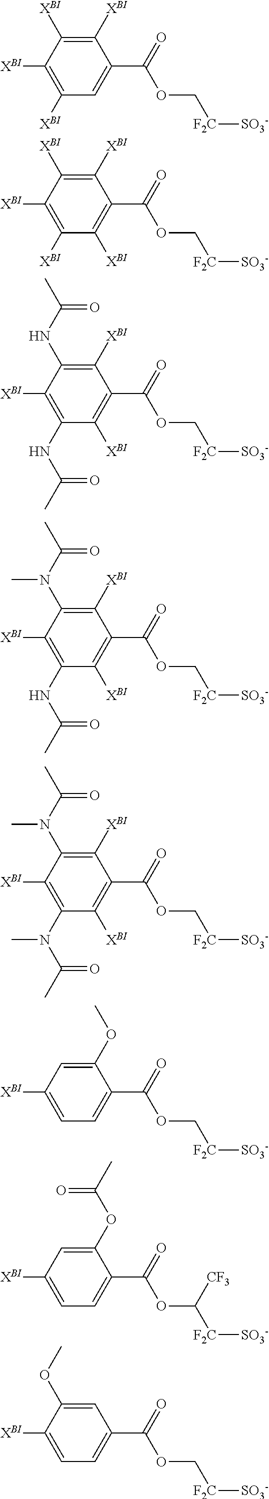

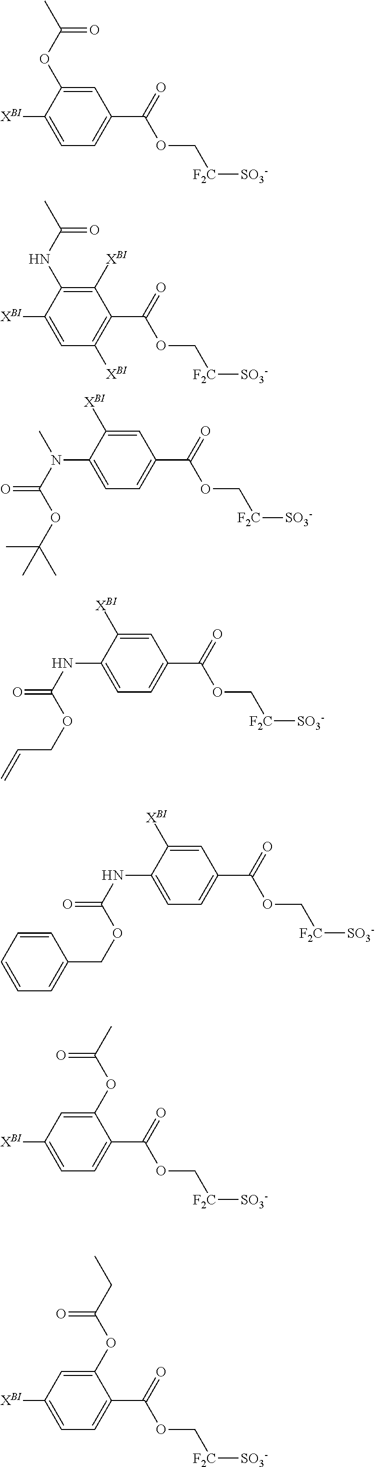

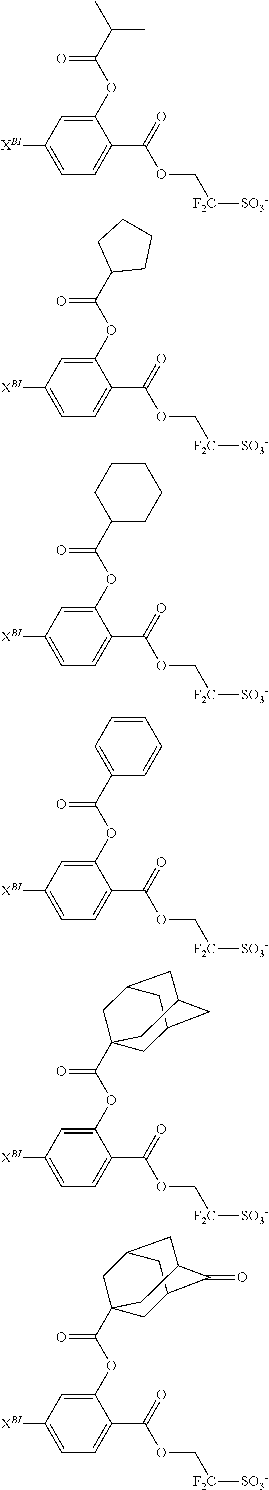

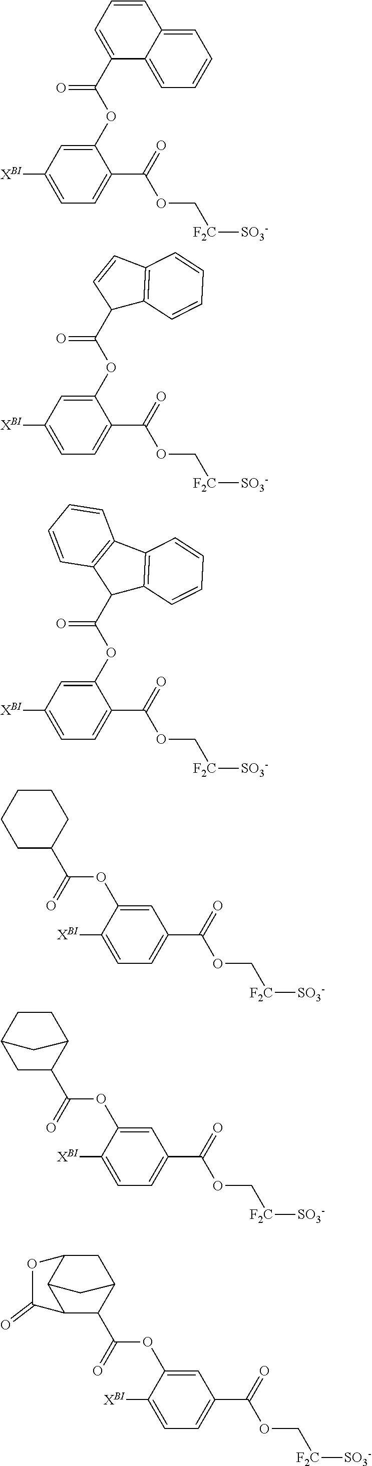

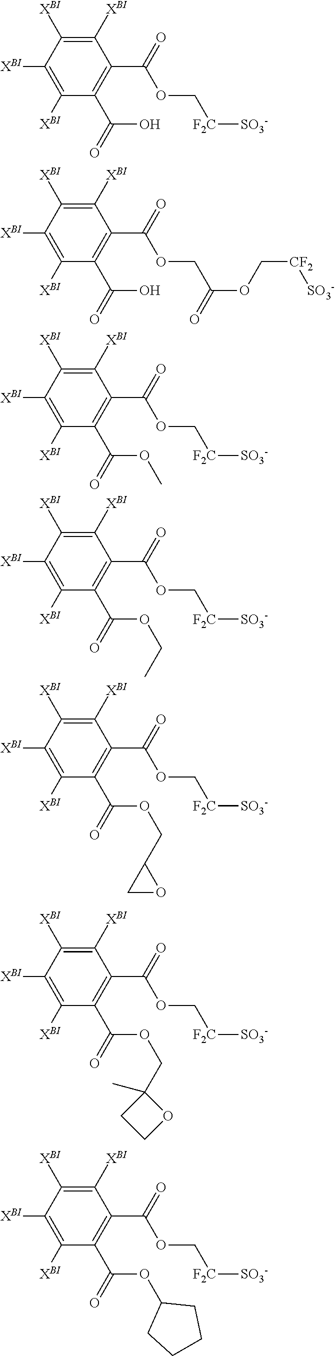

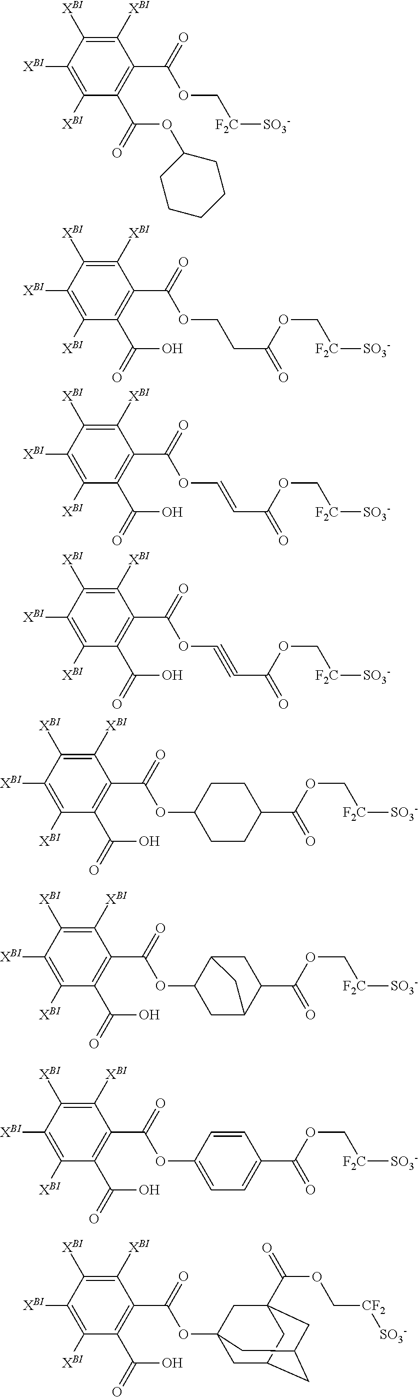

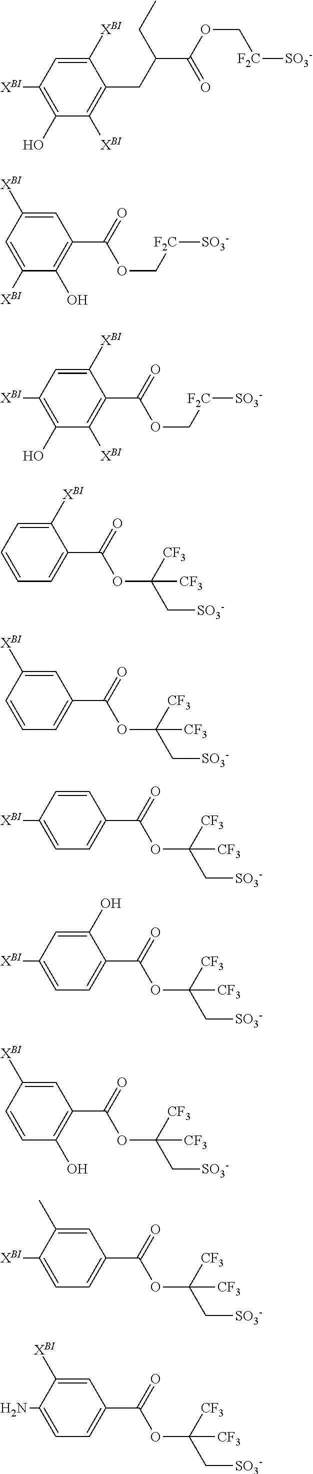

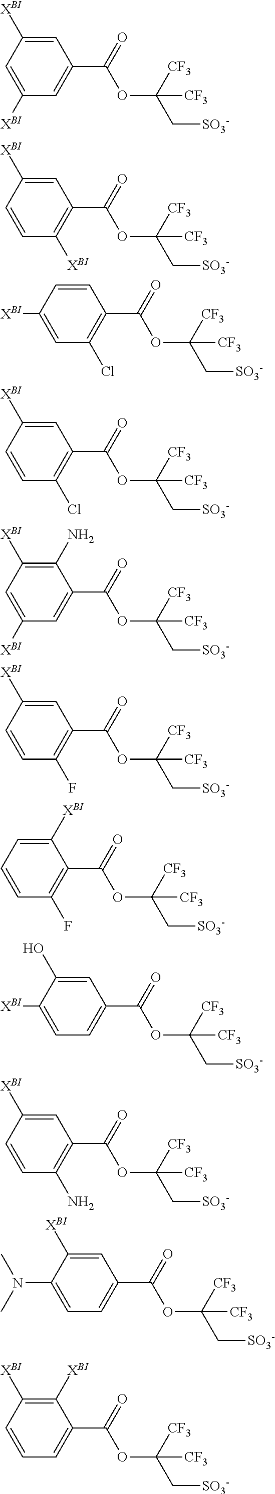

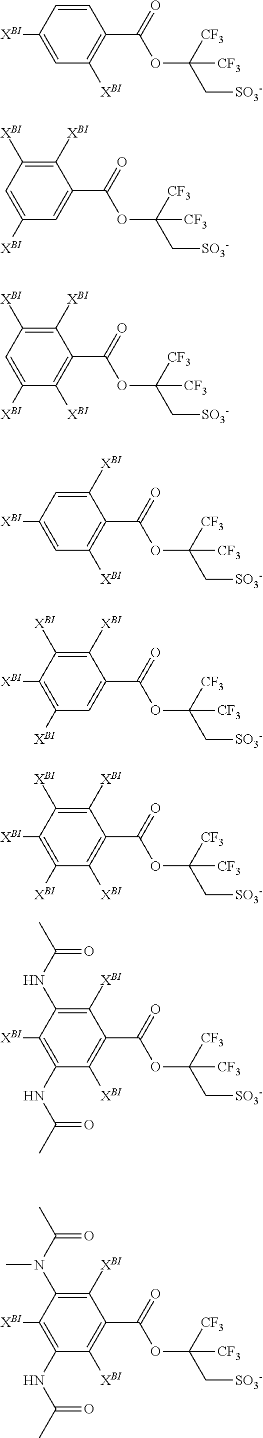

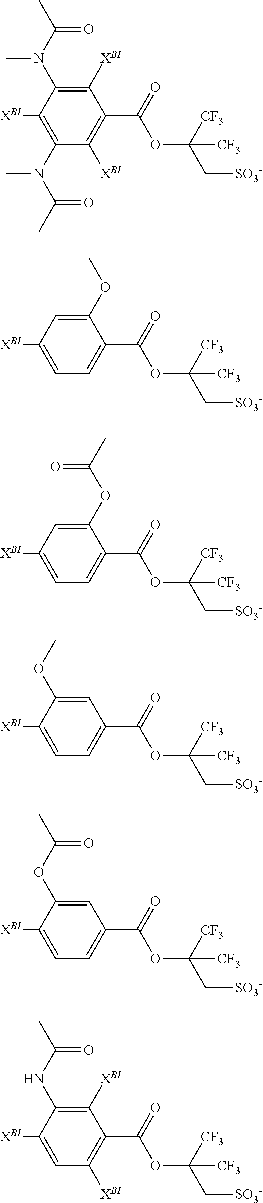

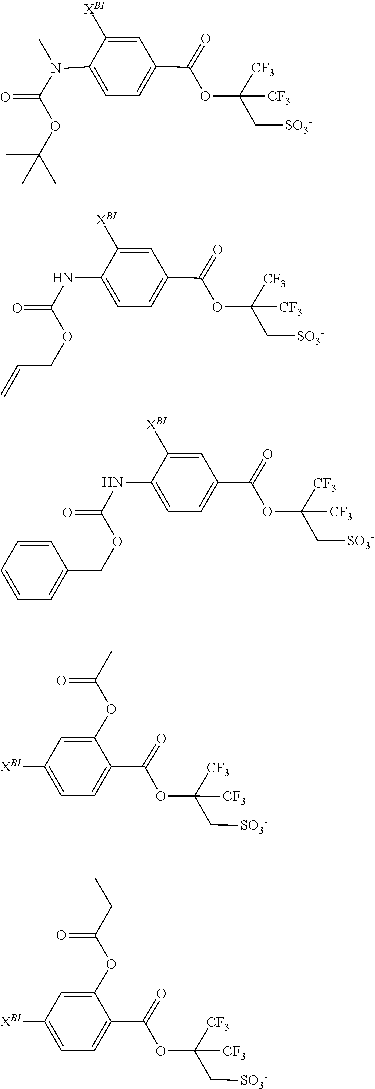

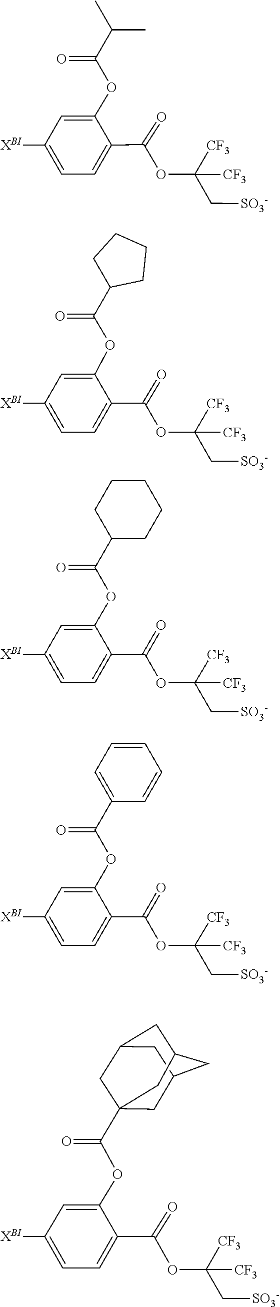

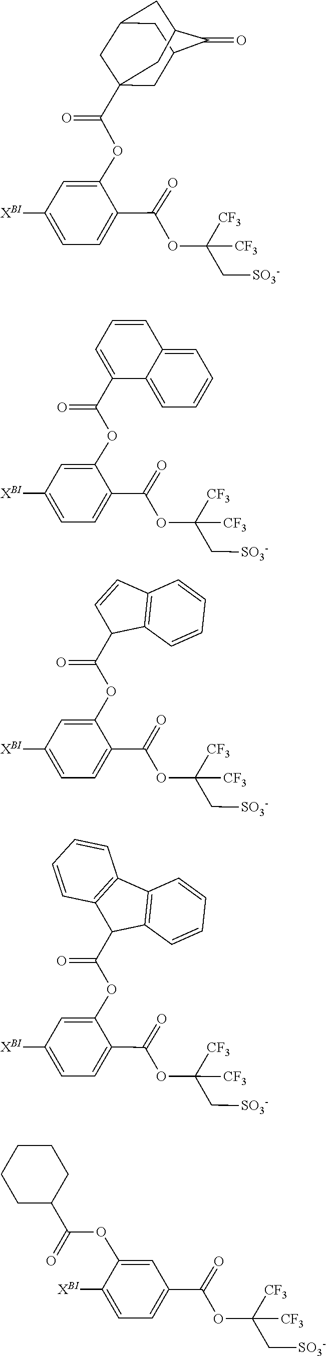

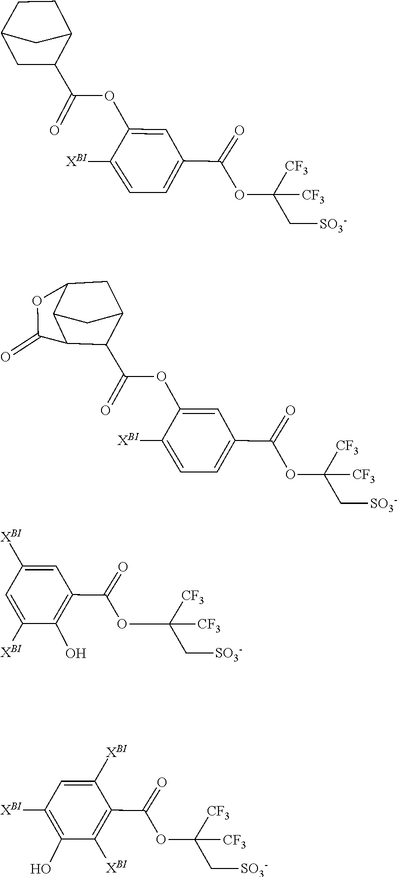

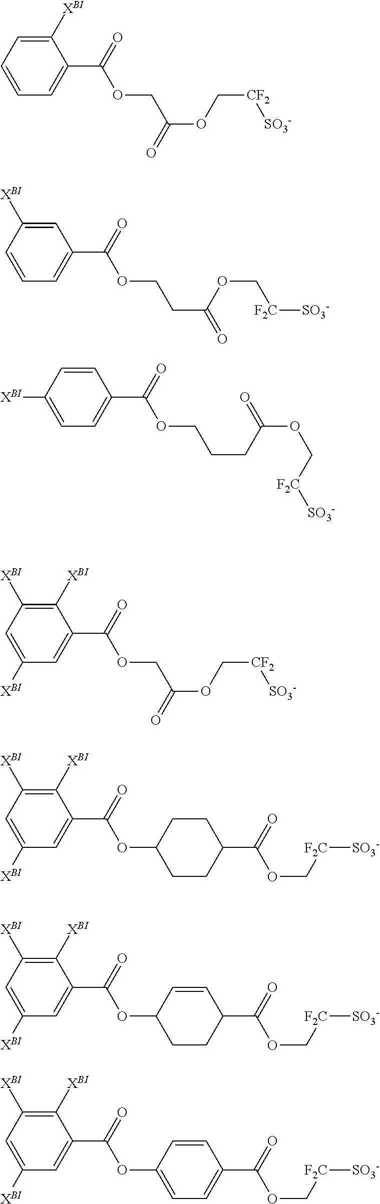

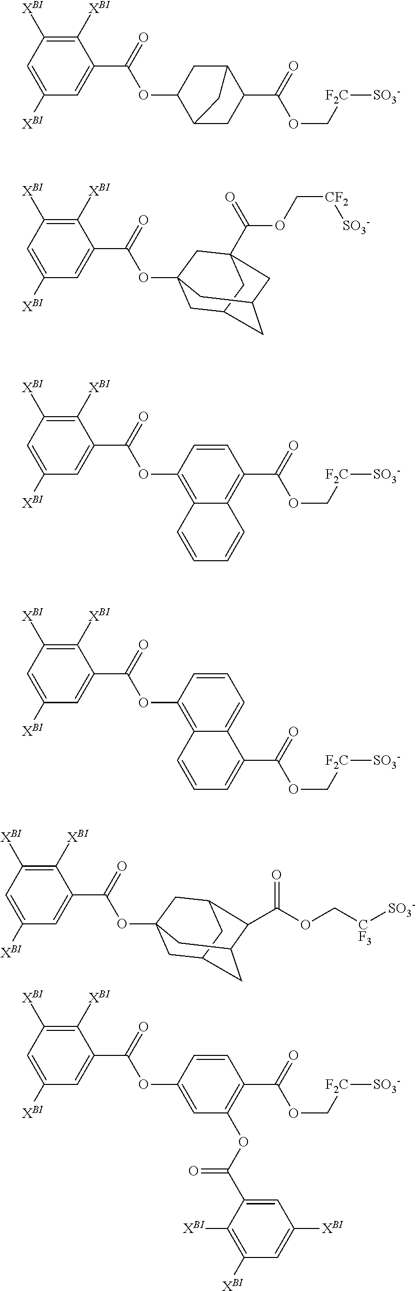

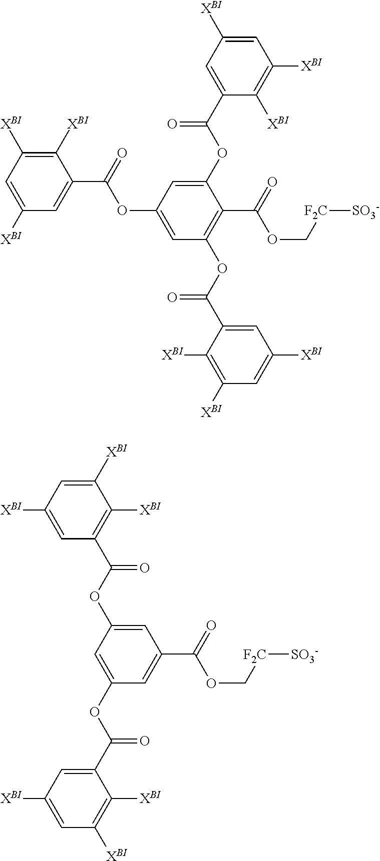

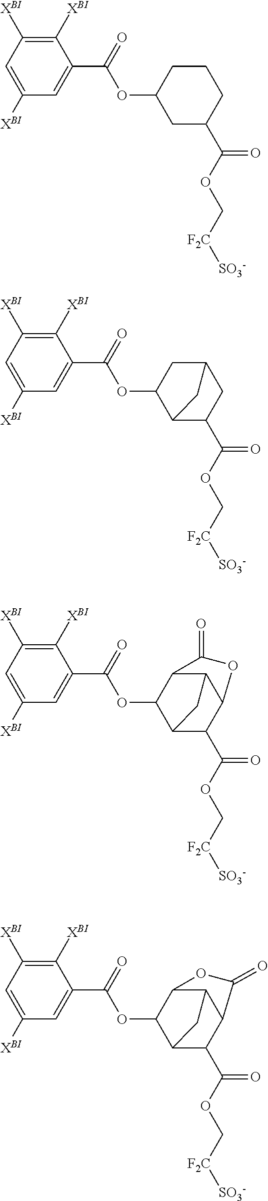

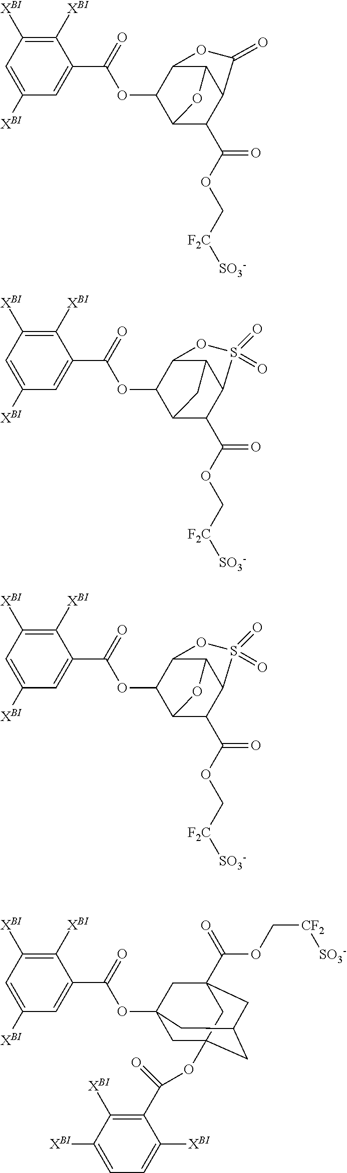

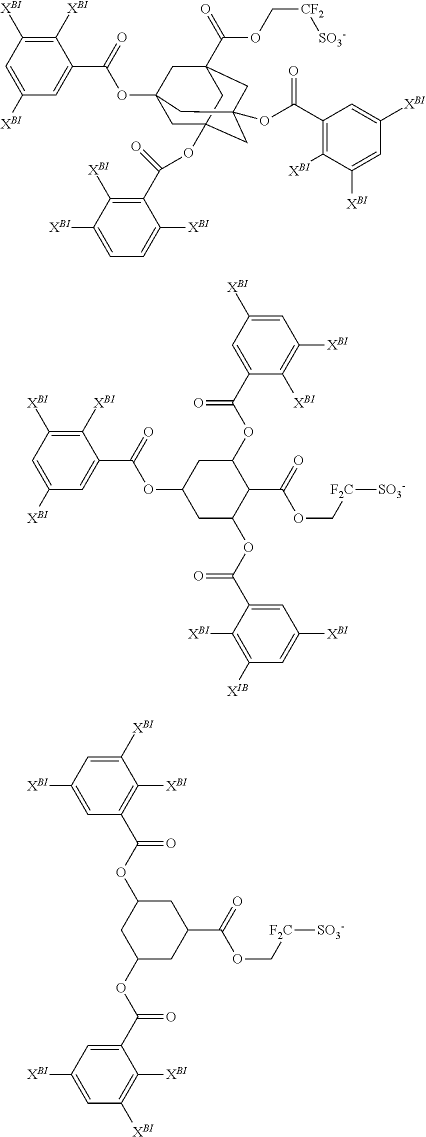

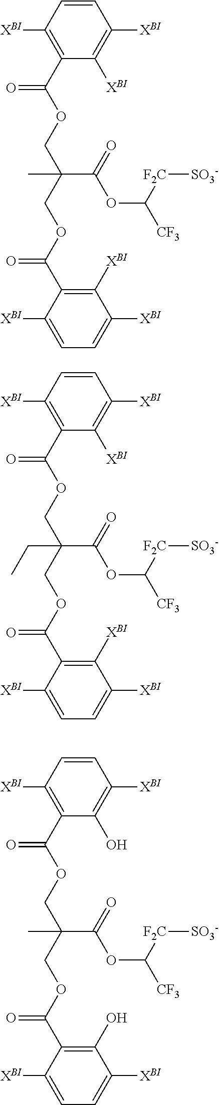

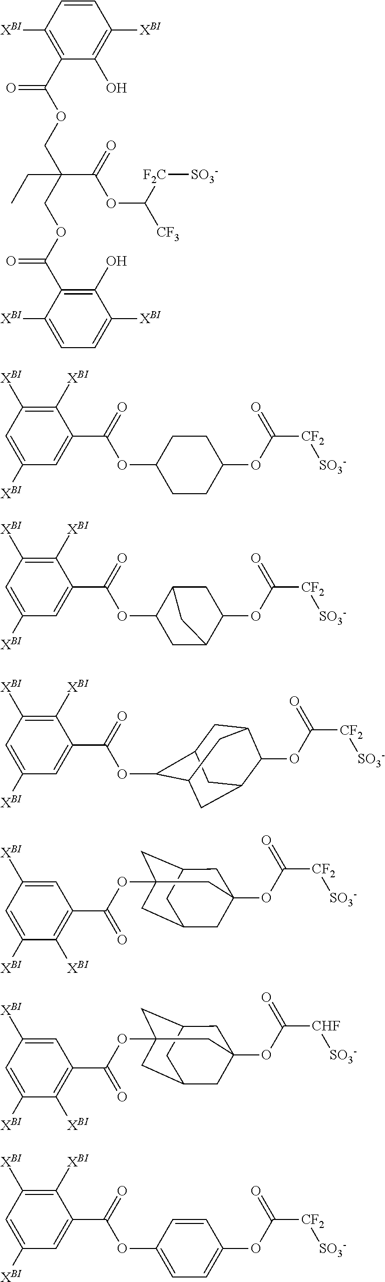

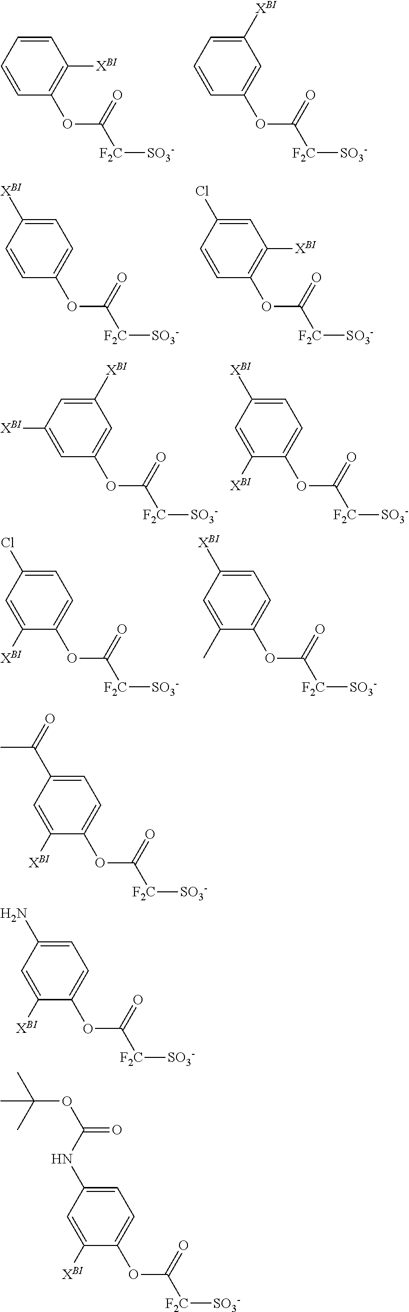

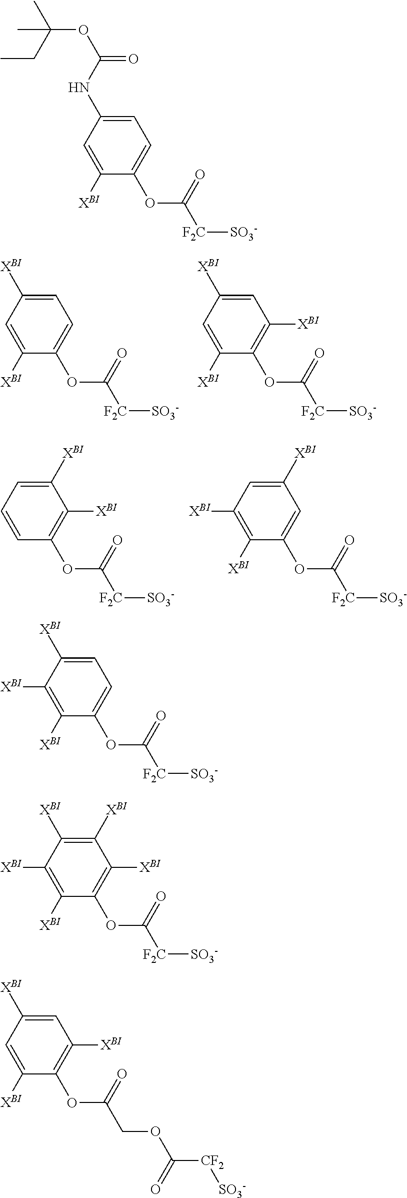

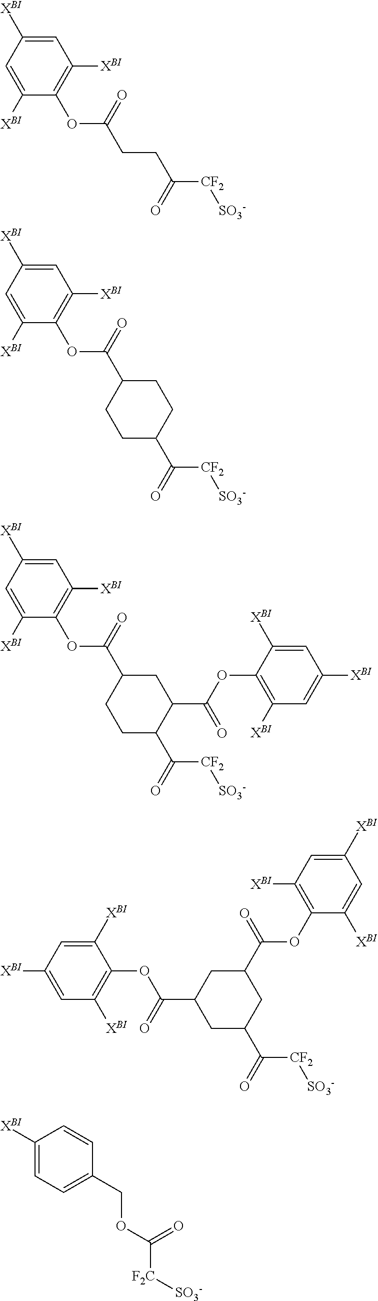

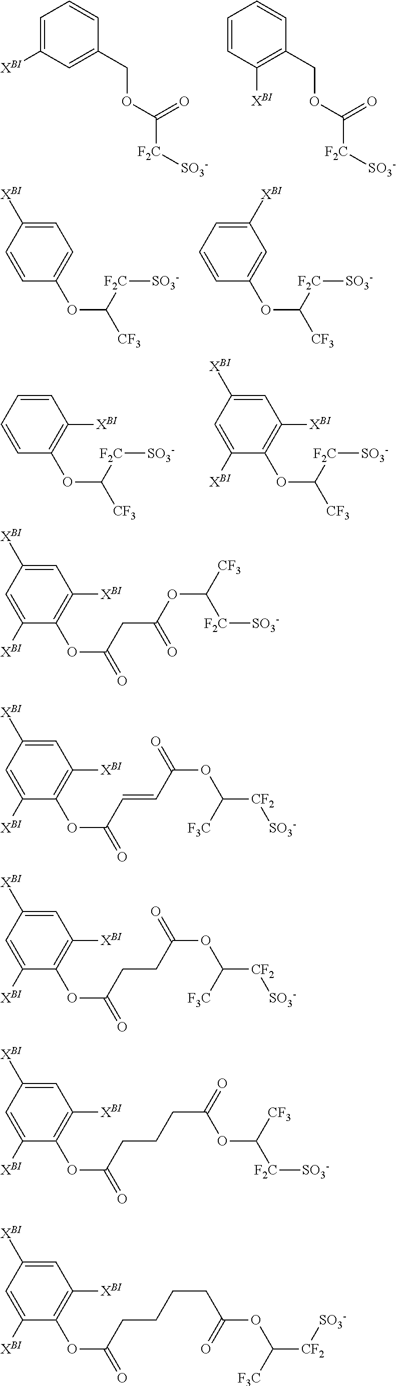

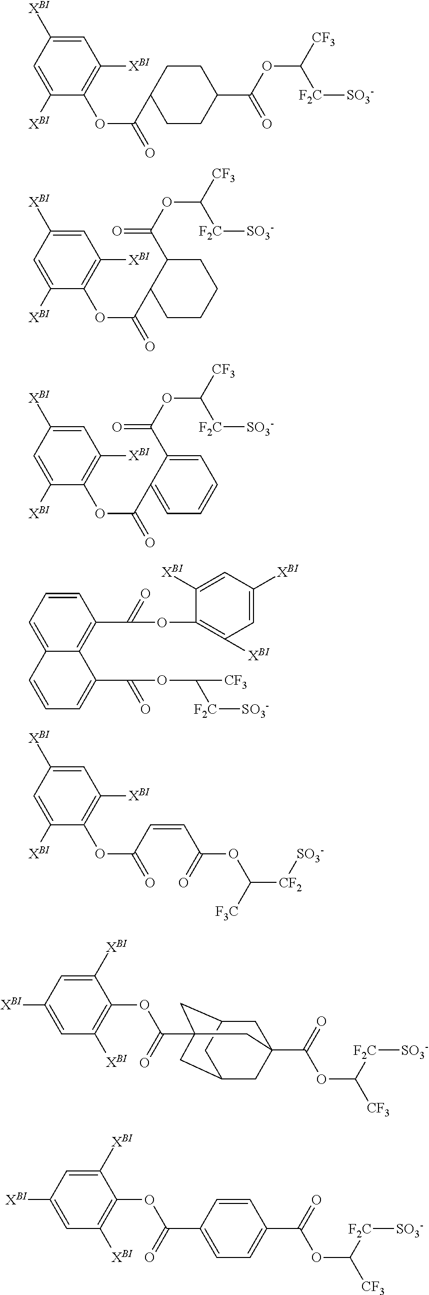

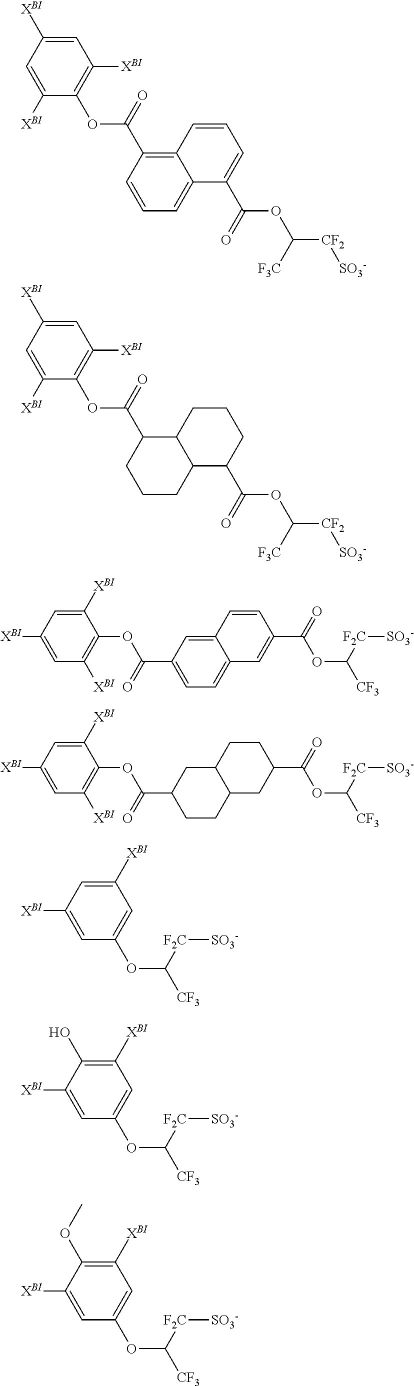

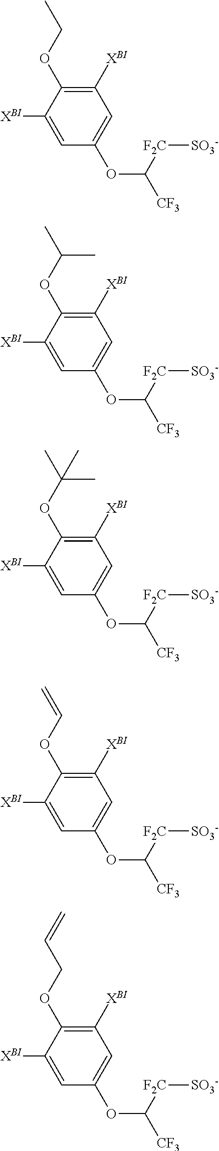

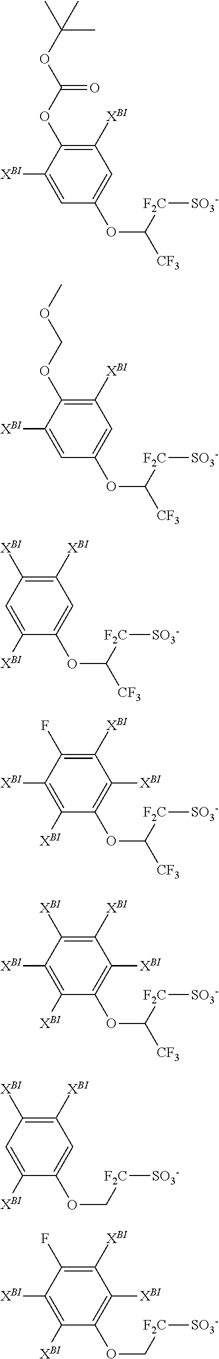

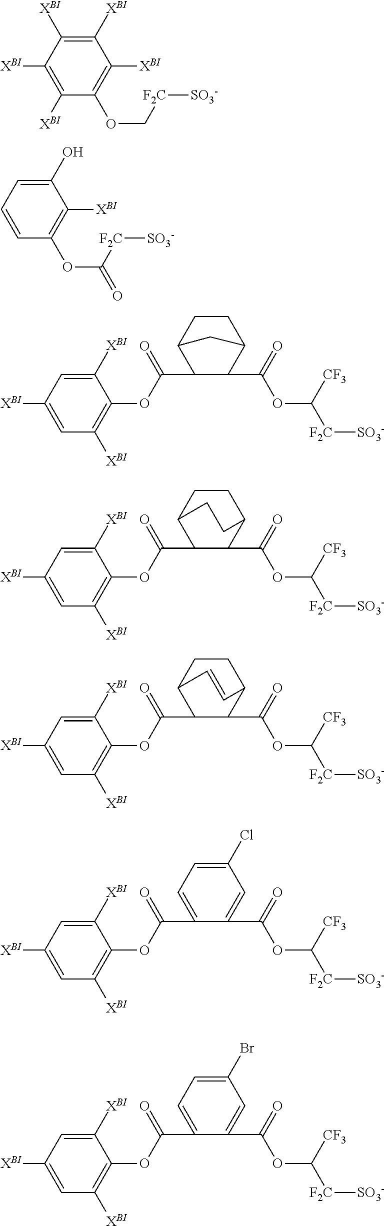

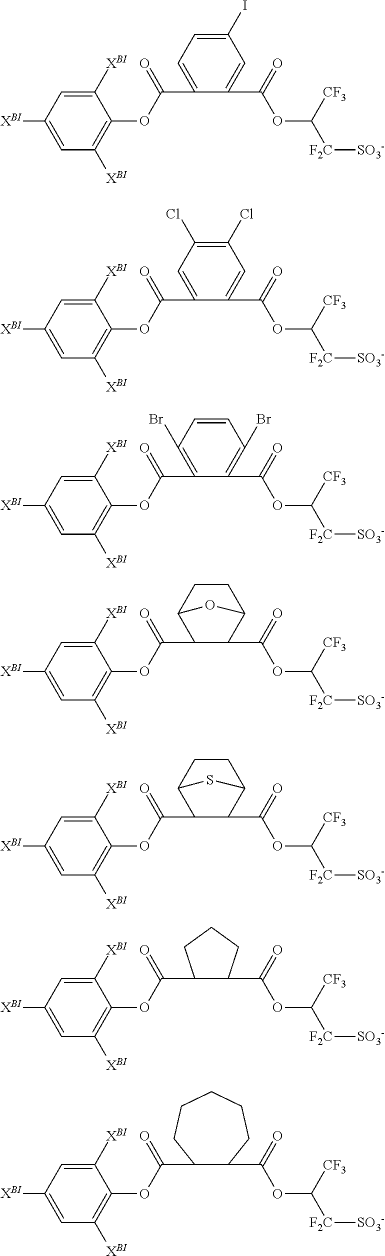

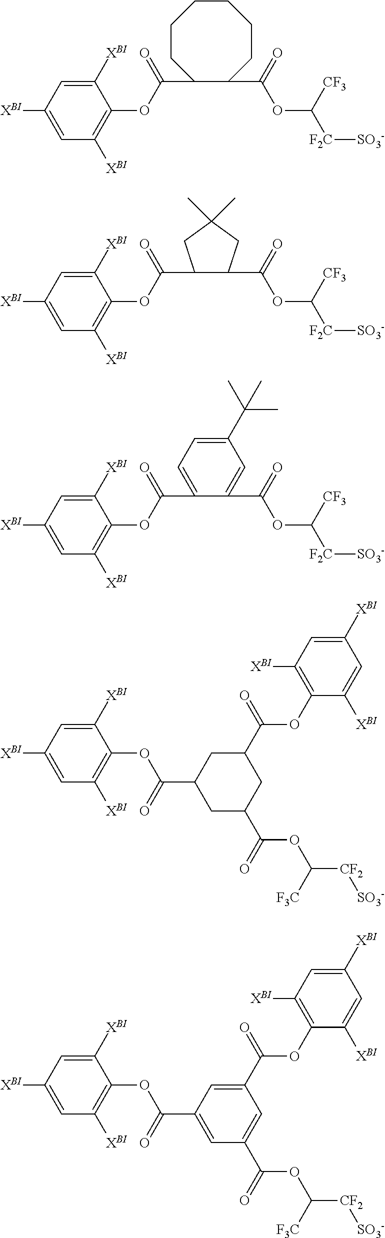

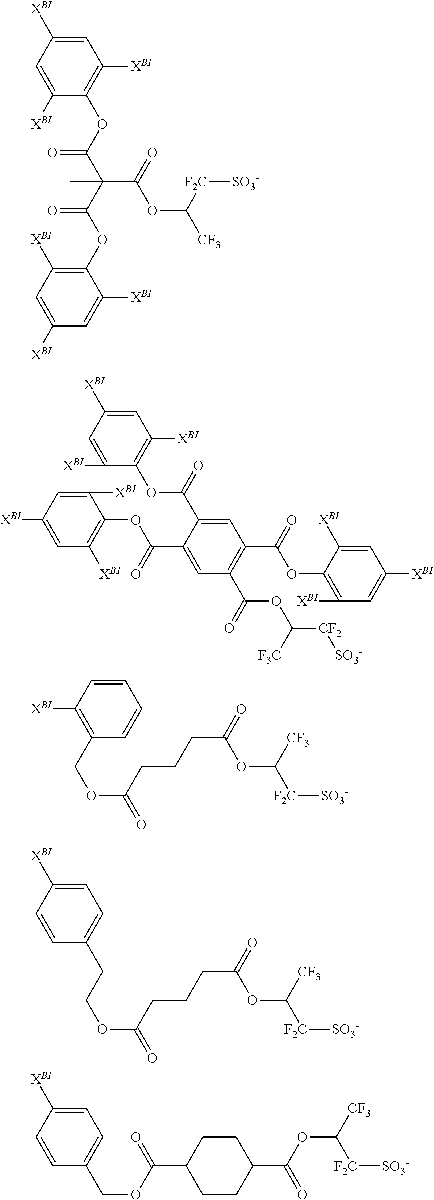

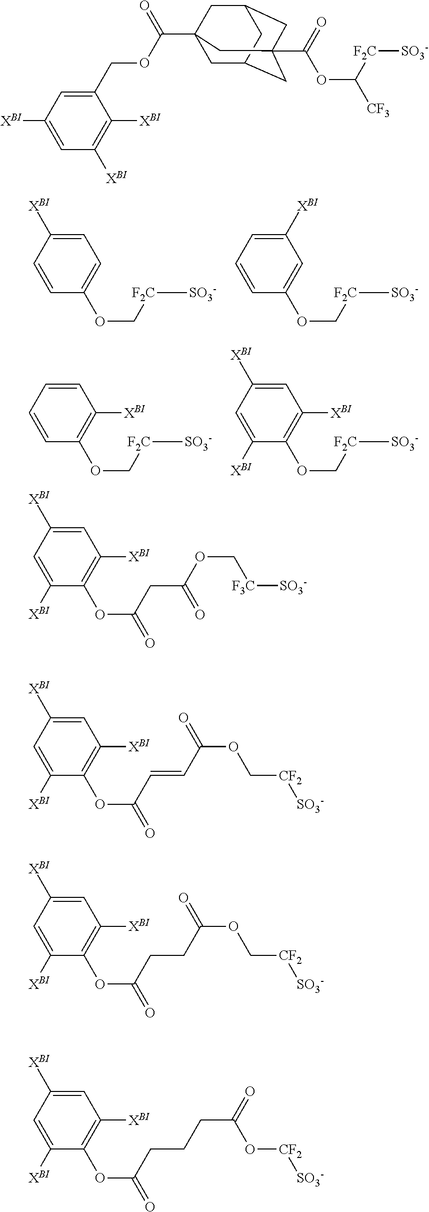

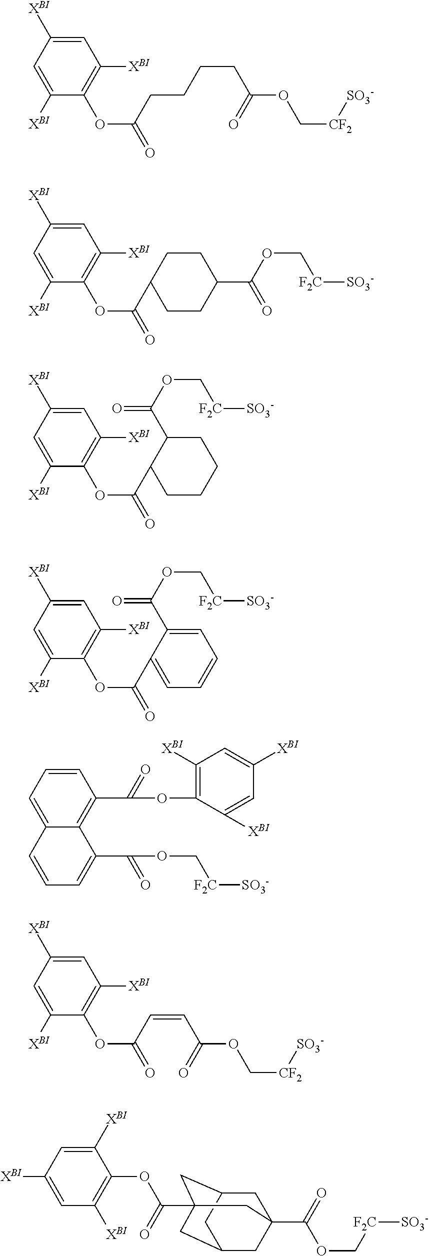

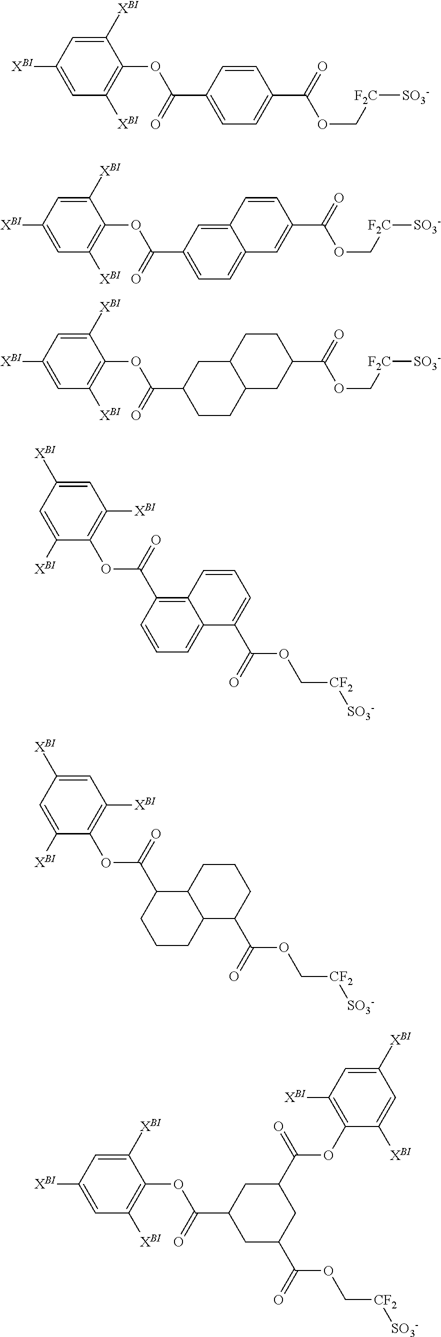

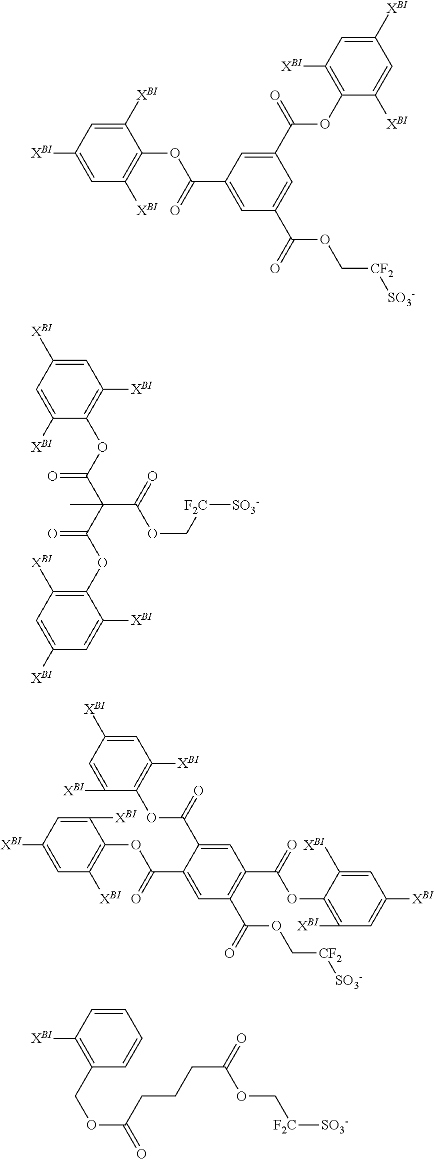

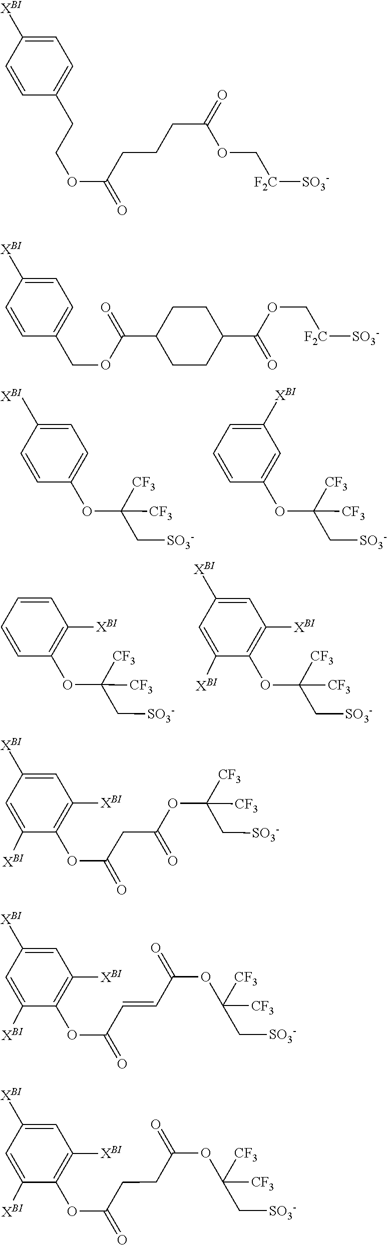

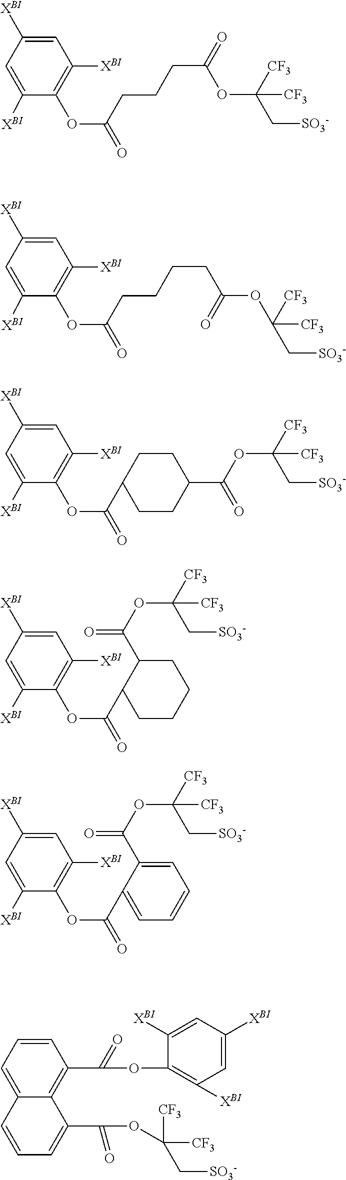

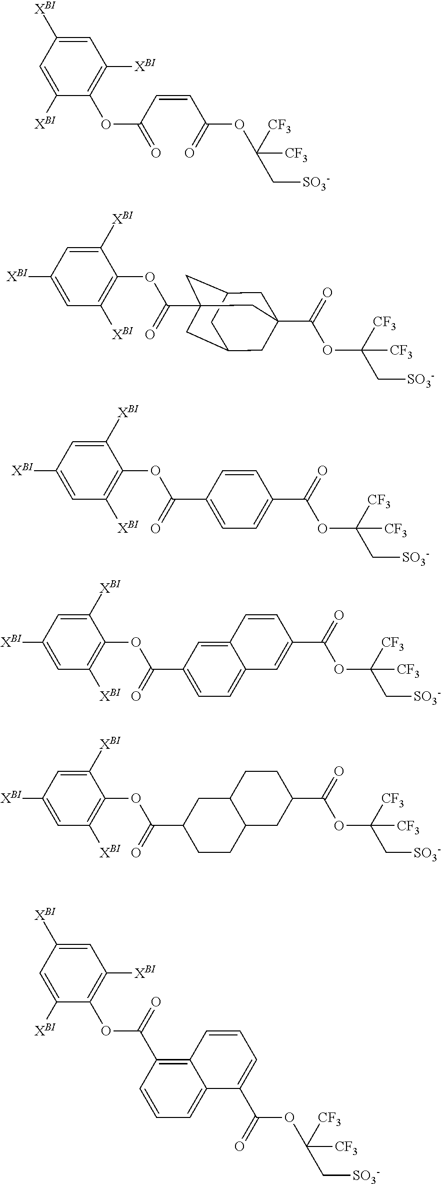

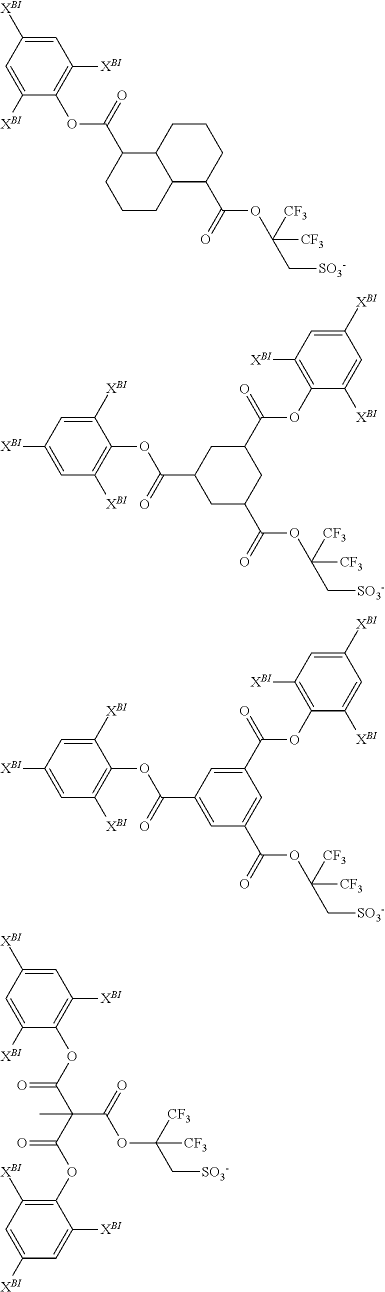

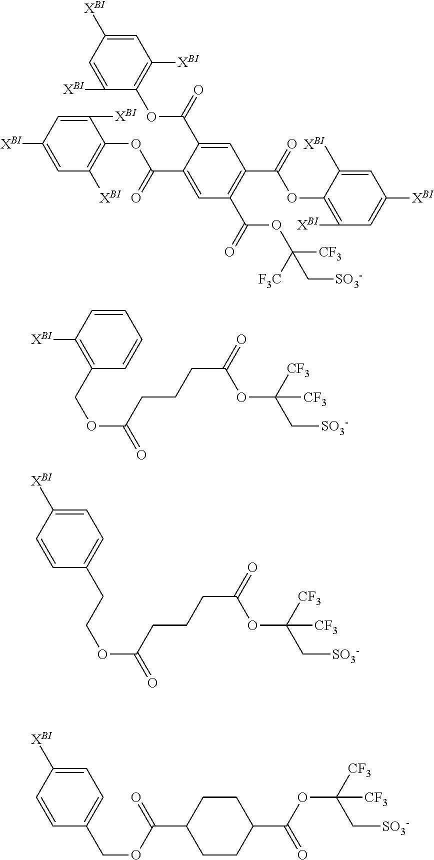

When the resist composition contains the other acid generator, it is preferably used in an amount of 0.1 to 50 parts, more preferably 1 to 40 parts by weight per 100 parts by weight of the base polymer.

Exemplary surfactants are described in JP-A 2008-111103, paragraphs [0165]-[0166]. Inclusion of a surfactant may improve or control the coating characteristics of the resist composition. The surfactant is preferably added in an amount of 0.0001 to 10 parts by weight per 100 parts by weight of the base polymer.

In the case of positive resist compositions, inclusion of a dissolution inhibitor may lead to an increased difference in dissolution rate between exposed and unexposed areas and a further improvement in resolution. The dissolution inhibitor which can be used herein is a compound having at least two phenolic hydroxy groups on the molecule, in which an average of from 0 to 100 mol % of all the hydrogen atoms on the phenolic hydroxy groups are replaced by acid labile groups or a compound having at least one carboxy group on the molecule, in which an average of 50 to 100 mol % of all the hydrogen atoms on the carboxy groups are replaced by acid labile groups, both the compounds having a molecular weight of 100 to 1,000, and preferably 150 to 800. Typical are bisphenol A, trisphenol, phenolphthalein, cresol novolac, naphthalenecarboxylic acid, adamantanecarboxylic acid, and cholic acid derivatives in which the hydrogen atom on the hydroxy or carboxy group is replaced by an acid labile group, as described in U.S. Pat. No. 7,771,914 (JP-A 2008-122932, paragraphs [0155]-[0178]).

In the positive resist composition, the dissolution inhibitor is preferably added in an amount of 0 to 50 parts, more preferably 5 to 40 parts by weight per 100 parts by weight of the base polymer.

In the case of negative resist compositions, a negative pattern may be formed by adding a crosslinker to reduce the dissolution rate of exposed area. Suitable crosslinkers which can be used herein include epoxy compounds, melamine compounds, guanamine compounds, glycoluril compounds and urea compounds having substituted thereon at least one group selected from among methylol, alkoxymethyl and acyloxymethyl groups, isocyanate compounds, azide compounds, and compounds having a double bond such as an alkenyloxy group. These compounds may be used as an additive or introduced into a polymer side chain as a pendant. Hydroxy-containing compounds may also be used as the crosslinker.

Suitable epoxy compounds include tris(2,3-epoxypropyl) isocyanurate, trimethylolmethane triglycidyl ether, trimethylolpropane triglycidyl ether, and triethylolethane triglycidyl ether. Examples of the melamine compound include hexamethylol melamine, hexamethoxymethyl melamine, hexamethylol melamine compounds having 1 to 6 methylol groups methoxymethylated and mixtures thereof, hexamethoxyethyl melamine, hexaacyloxymethyl melamine, hexamethylol melamine compounds having 1 to 6 methylol groups acyloxymethylated and mixtures thereof. Examples of the guanamine compound include tetramethylol guanamine, tetramethoxymethyl guanamine, tetramethylol guanamine compounds having 1 to 4 methylol groups methoxymethylated and mixtures thereof, tetramethoxyethyl guanamine, tetraacyloxyguanamine, tetramethylol guanamine compounds having 1 to 4 methylol groups acyloxymethylated and mixtures thereof. Examples of the glycoluril compound include tetramethylol glycoluril, tetramethoxyglycoluril, tetramethoxymethyl glycoluril, tetramethylol glycoluril compounds having 1 to 4 methylol groups methoxymethylated and mixtures thereof, tetramethylol glycoluril compounds having 1 to 4 methylol groups acyloxymethylated and mixtures thereof. Examples of the urea compound include tetramethylol urea, tetramethoxymethyl urea, tetramethylol urea compounds having 1 to 4 methylol groups methoxymethylated and mixtures thereof, and tetramethoxyethyl urea.

Suitable isocyanate compounds include tolylene diisocyanate, diphenylmethane diisocyanate, hexamethylene diisocyanate and cyclohexane diisocyanate. Suitable azide compounds include 1,1′-biphenyl-4,4′-bisazide, 4,4′-methylidenebisazide, and 4,4′-oxybisazide. Examples of the alkenyloxy-containing compound include ethylene glycol divinyl ether, triethylene glycol divinyl ether, 1,2-propanediol divinyl ether, 1,4-butanediol divinyl ether, tetramethylene glycol divinyl ether, neopentyl glycol divinyl ether, trimethylol propane trivinyl ether, hexanediol divinyl ether, 1,4-cyclohexanediol divinyl ether, pentaerythritol trivinyl ether, pentaerythritol tetravinyl ether, sorbitol tetravinyl ether, sorbitol pentavinyl ether, and trimethylol propane trivinyl ether.

In the negative resist composition, the crosslinker is preferably added in an amount of 0.1 to 50 parts, more preferably 1 to 40 parts by weight per 100 parts by weight of the base polymer.

To the resist composition, a water repellency improver may also be added for improving the water repellency on surface of a resist film. The water repellency improver may be used in the topcoatless immersion lithography. Suitable water repellency improvers include polymers having a fluoroalkyl group and polymers having a specific structure with a 1,1,1,3,3,3-hexafluoro-2-propanol residue and are described in JP-A 2007-297590 and JP-A 2008-111103, for example. The water repellency improver to be added to the resist composition should be soluble in alkaline developers and organic solvent developers. The water repellency improver of specific structure with a 1,1,1,3,3,3-hexafluoro-2-propanol residue is well soluble in the developer. A polymer comprising repeat units having an amino group or amine salt serves as the water repellency improver and is effective for preventing evaporation of acid during PEB, thus preventing any hole pattern opening failure after development. An appropriate amount of the water repellency improver is 0 to 20 parts, preferably 0.5 to 10 parts by weight per 100 parts by weight of the base polymer.

Also, an acetylene alcohol may be blended in the resist composition. Suitable acetylene alcohols are described in JP-A 2008-122932, paragraphs [0179]-[0182]. An appropriate amount of the acetylene alcohol blended is 0 to 5 parts by weight per 100 parts by weight of the base polymer.

### Process

The resist composition is used in the fabrication of various integrated circuits. Pattern formation using the resist composition may be performed by well-known lithography processes. The process generally involves the steps of applying the resist composition onto a substrate to form a resist film thereon, exposing the resist film to high-energy radiation, and developing the exposed resist film in a developer. If necessary, any additional steps may be added.

For example, the resist composition is first applied onto a substrate on which an integrated circuit is to be formed (e.g., Si, SiO₂, SiN, SiON, TiN, WSi, BPSG, SOG, or organic antireflective coating) or a substrate on which a mask circuit is to be formed (e.g., Cr, CrO, CrON, MoSi₂, or SiO₂) by a suitable coating technique such as spin coating, roll coating, flow coating, dipping, spraying or doctor coating. The coating is prebaked on a hotplate at a temperature of 60 to 150° C. for 10 seconds to 30 minutes, preferably at 80 to 120° C. for 30 seconds to 20 minutes. The resulting resist film is generally 0.01 to 2 μm thick.

Then the resist film is exposed to high-energy radiation. Examples of the high-energy radiation include UV, deep-UV, EB, EUV of wavelength 3 to 15 nm, x-ray, soft x-ray, excimer laser light, γ-ray or synchrotron radiation. On use of UV, deep UV, EUV, x-ray, soft x-ray, excimer laser, γ-ray or synchrotron radiation, the resist film is exposed directly or through a mask having a desired pattern, preferably in a dose of about 1 to 200 mJ/cm², more preferably about 10 to 100 mJ/cm². On use of EB, a pattern may be written directly or through a mask having a desired pattern, preferably in a dose of about 0.1 to 100 μC/cm², more preferably about 0.5 to 50 μC/cm². The resist composition is suited for micropatterning using high-energy radiation such as KrF excimer laser, ArF excimer laser, EB, EUV, x-ray, soft x-ray, γ-ray or synchrotron radiation, especially EB or EUV.

After the exposure, the resist film may be baked (PEB) on a hotplate or in an oven at 60 to 150° C. for 10 seconds to 30 minutes, preferably at 80 to 120° C. for 30 seconds to 20 minutes.

After the exposure or PEB, the resist film is developed with a developer in the form of an aqueous base solution for 3 seconds to 3 minutes, preferably 5 seconds to 2 minutes by conventional techniques such as dip, puddle and spray techniques. A typical developer is a 0.1 to 10 wt %, preferably 2 to 5 wt % aqueous solution of tetramethylammonium hydroxide (TMAH), tetraethylammonium hydroxide (TEAH), tetrapropylammonium hydroxide (TPAH), or tetrabutylammonium hydroxide (TBAH). The resist film in the exposed area is dissolved in the developer whereas the resist film in the unexposed area is not dissolved. In this way, the desired positive pattern is formed on the substrate. Inversely in the case of negative resist, the exposed area of resist film is insolubilized and the unexposed area is dissolved in the developer.

In an alternative embodiment, a negative pattern may be formed via organic solvent development using a positive resist composition comprising a base polymer having an acid labile group. The developer used herein is preferably selected from among 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, benzyl formate, phenylethyl formate, methyl 3-phenylpropionate, benzyl propionate, ethyl phenylacetate, and 2-phenylethyl acetate, and mixtures thereof.

At the end of development, the resist film is rinsed. As the rinsing liquid, a solvent which is miscible with the developer and does not dissolve the resist film is preferred. Suitable solvents include alcohols of 3 to 10 carbon atoms, ether compounds of 8 to 12 carbon atoms, alkanes, alkenes, and alkynes of 6 to 12 carbon atoms, and aromatic solvents. Specifically, suitable alcohols of 3 to 10 carbon atoms include n-propyl alcohol, isopropyl alcohol, 1-butyl alcohol, 2-butyl alcohol, isobutyl alcohol, t-butyl alcohol, 1-pentanol, 2-pentanol, 3-pentanol, t-pentyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, and 1-octanol. Suitable ether compounds of 8 to 12 carbon atoms include di-n-butyl ether, diisobutyl ether, di-s-butyl ether, di-n-pentyl ether, diisopentyl ether, di-s-pentyl ether, di-t-pentyl ether, and di-n-hexyl ether. Suitable alkanes of 6 to 12 carbon atoms include hexane, heptane, octane, nonane, decane, undecane, dodecane, methylcyclopentane, dimethylcyclopentane, cyclohexane, methylcyclohexane, dimethylcyclohexane, cycloheptane, cyclooctane, and cyclononane. Suitable alkenes of 6 to 12 carbon atoms include hexene, heptene, octene, cyclohexene, methylcyclohexene, dimethylcyclohexene, cycloheptene, and cyclooctene. Suitable alkynes of 6 to 12 carbon atoms include hexyne, heptyne, and octyne. Suitable aromatic solvents include toluene, xylene, ethylbenzene, isopropylbenzene, t-butylbenzene and mesitylene. The solvents may be used alone or in admixture.

Rinsing is effective for minimizing the risks of resist pattern collapse and defect formation. However, rinsing is not essential. If rinsing is omitted, the amount of solvent used may be reduced.

A hole or trench pattern after development may be shrunk by the thermal flow, RELACS® or DSA process. A hole pattern is shrunk by coating a shrink agent thereto, and baking such that the shrink agent may undergo crosslinking at the resist surface as a result of the acid catalyst diffusing from the resist layer during bake, and the shrink agent may attach to the sidewall of the hole pattern. The bake is preferably at a temperature of 70 to 180° C., more preferably 80 to 170° C., for a time of 10 to 300 seconds. The extra shrink agent is stripped and the hole pattern is shrunk.

### EXAMPLES

Examples of the invention are given below by way of illustration and not by way of limitation. The abbreviation “pbw” is parts by weight.

In Synthesis Examples, Monomers PM-1 to PM-13, cPM-1, AM-1, AM-2 and FM-1 having the structure shown below were used.

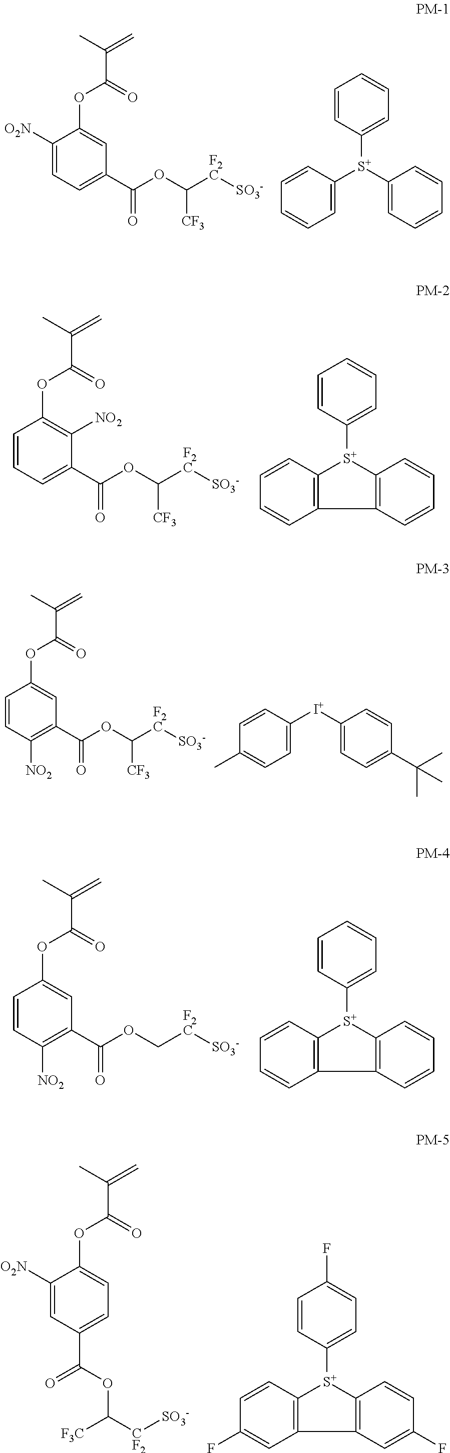

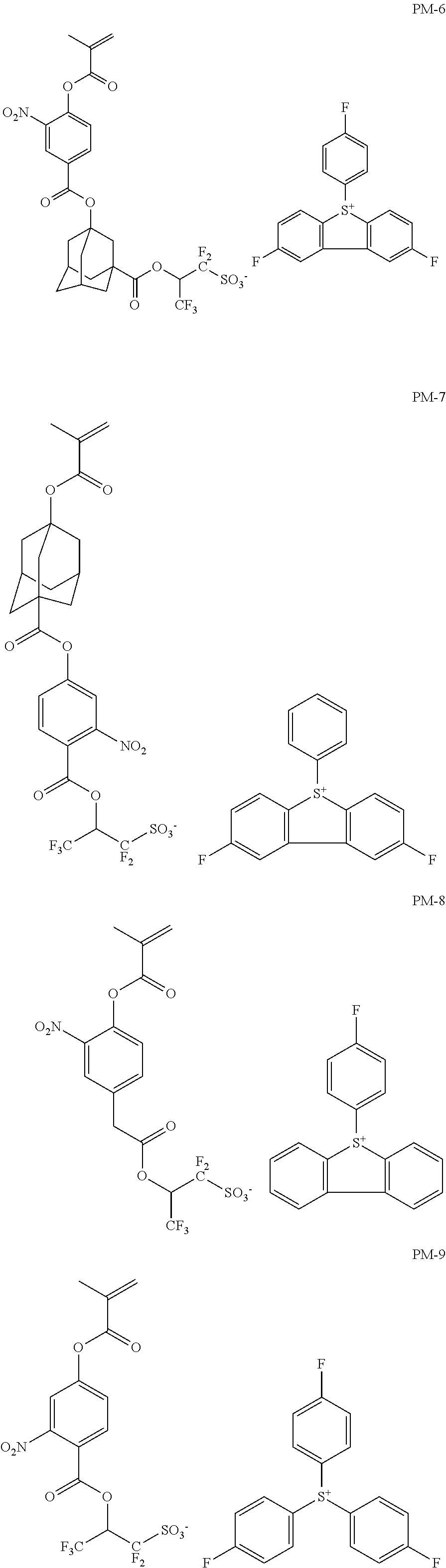

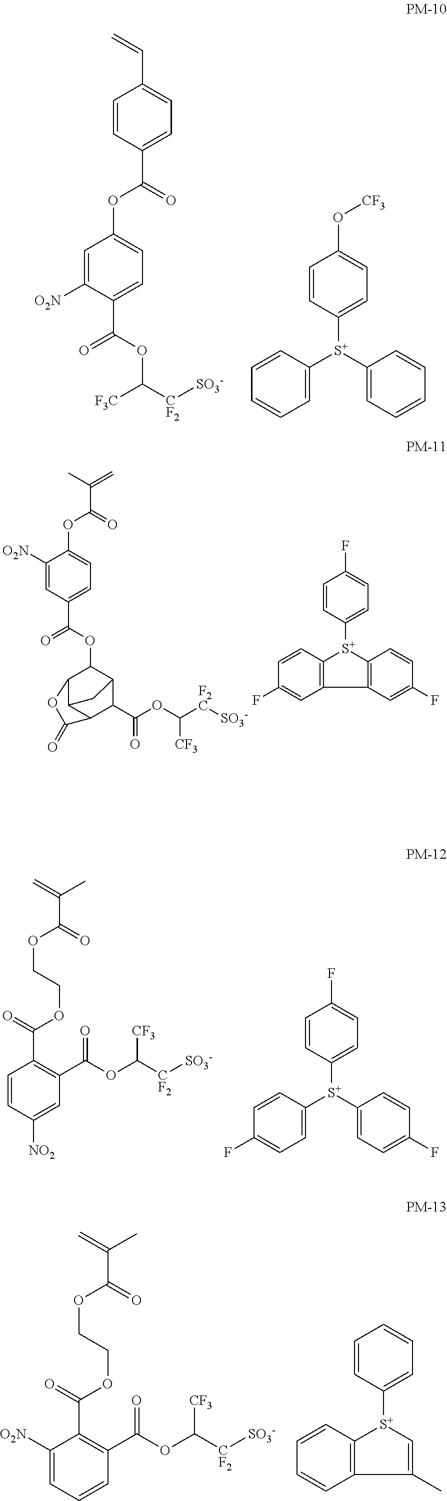

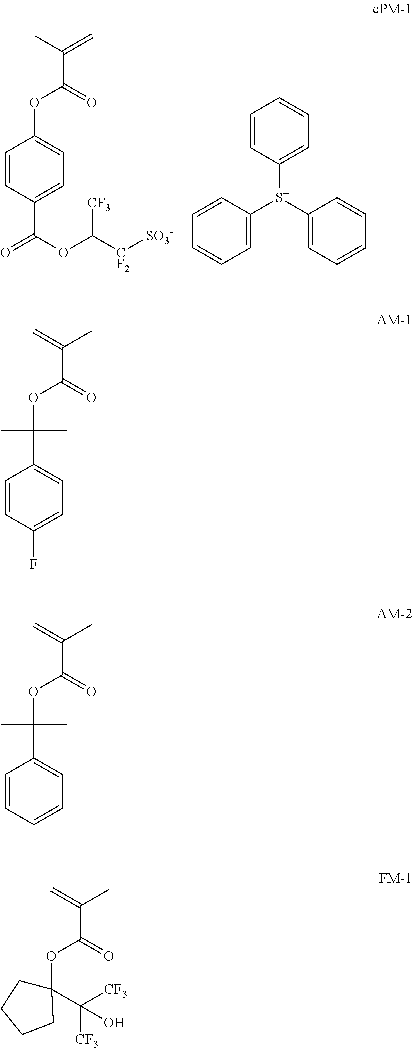

### Synthesis Example 1

Synthesis of Polymer P-1

A 2-L flask was charged with 8.4 g of 1-methyl-1-cyclopentyl methacrylate, 3.6 g of 4-hydroxyphenyl methacrylate, 4.5 g of 3-oxo-2,7-dioxatricyclo[4.2.1.0^{4,8}]nonan-9-yl methacrylate, 7.3 g of Monomer PM-1, and 40 g of tetrahydrofuran (THF) as solvent. The reactor was cooled at −70° C. in nitrogen atmosphere, after which vacuum pumping and nitrogen blow were repeated three times. The reactor was warmed up to room temperature, whereupon 1.2 g of azobisisobutyronitrile (AIBN) was added. The reactor was heated at 60° C., whereupon reaction ran for 15 hours. The reaction solution was poured into 1 L of isopropyl alcohol (IPA) for precipitation. The precipitated white solid was collected by filtration and vacuum dried at 60° C., yielding Polymer P-1 in white solid form. Polymer P-1 was analyzed for composition by ¹³C- and ¹H-NMR and for Mw and Mw/Mn by GPC.

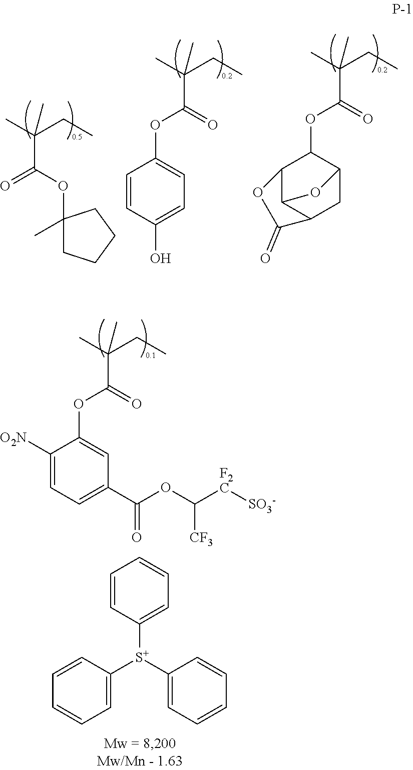

### Synthesis Example 2

Synthesis of Polymer P-2

A 2-L flask was charged with 8.4 g of 1-methyl-1-cyclopentyl methacrylate, 3.6 g of 4-hydroxystyrene, 14.8 g of Monomer PM-2, and 40 g of THF solvent. The reactor was cooled at −70° C. in nitrogen atmosphere, after which vacuum pumping and nitrogen blow were repeated three times. The reactor was warmed up to room temperature, whereupon 1.2 g of AIBN was added. The reactor was heated at 60° C., whereupon reaction ran for 15 hours. The reaction solution was poured into 1 L of IPA for precipitation. The precipitated white solid was collected by filtration and vacuum dried at 60° C., yielding Polymer P-2 in white solid form. Polymer P-2 was analyzed for composition by ¹³C- and ¹H-NMR and for Mw and Mw/Mn by GPC.

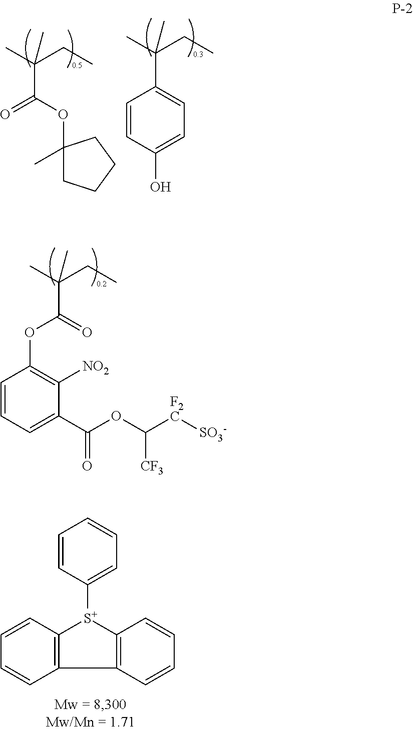

### Synthesis Example 3

Synthesis of Polymer P-3

A 2-L flask was charged with 8.4 g of 1-methyl-1-cyclopentyl methacrylate, 4.2 g of 4-hydroxystyrene, 12.2 g of Monomer PM-3, and 40 g of THF solvent. The reactor was cooled at −70° C. in nitrogen atmosphere, after which vacuum pumping and nitrogen blow were repeated three times. The reactor was warmed up to room temperature, whereupon 1.2 g of AIBN was added. The reactor was heated at 60° C., whereupon reaction ran for 15 hours. The reaction solution was poured into 1 L of IPA for precipitation. The precipitated white solid was collected by filtration and vacuum dried at 60° C., yielding Polymer P-3 in white solid form. Polymer P-3 was analyzed for composition by ¹³C- and ¹H-NMR and for Mw and Mw/Mn by GPC.

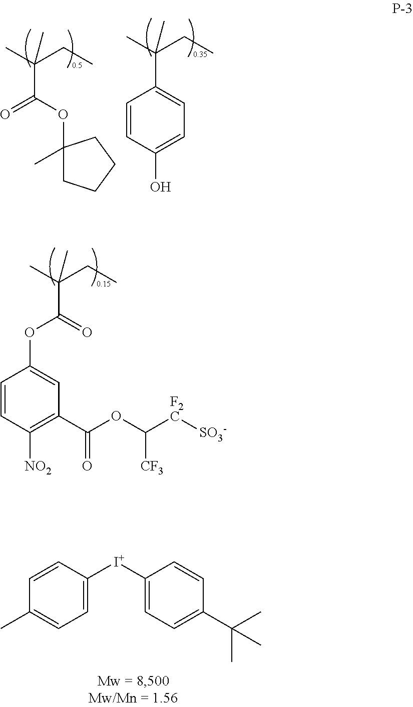

### Synthesis Example 4

Synthesis of Polymer P-4

A 2-L flask was charged with 11.1 g of Monomer AM-1, 4.2 g of 3-hydroxystyrene, 9.8 g of Monomer PM-4, and 40 g of THF solvent. The reactor was cooled at −70° C. in nitrogen atmosphere, after which vacuum pumping and nitrogen blow were repeated three times. The reactor was warmed up to room temperature, whereupon 1.2 g of AIBN was added. The reactor was heated at 60° C., whereupon reaction ran for 15 hours. The reaction solution was poured into 1 L of IPA for precipitation. The precipitated white solid was collected by filtration and vacuum dried at 60° C., yielding Polymer P-4 in white solid form. Polymer P-4 was analyzed for composition by ¹³C- and ¹H-NMR and for Mw and Mw/Mn by GPC.

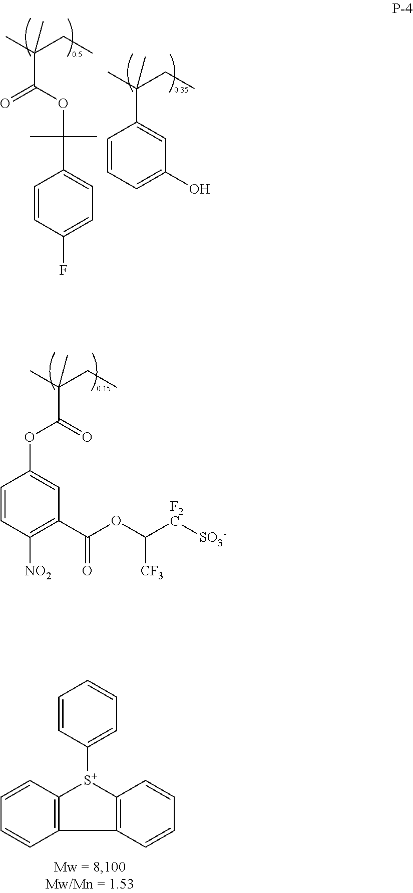

### Synthesis Example 5

Synthesis of Polymer P-5

A 2-L flask was charged with 10.2 g of Monomer AM-2, 4.2 g of 3-hydroxystyrene, 11.7 g of Monomer PM-5, and 40 g of THF solvent. The reactor was cooled at −70° C. in nitrogen atmosphere, after which vacuum pumping and nitrogen blow were repeated three times. The reactor was warmed up to room temperature, whereupon 1.2 g of AIBN was added. The reactor was heated at 60° C., whereupon reaction ran for 15 hours. The reaction solution was poured into 1 L of IPA for precipitation. The precipitated white solid was collected by filtration and vacuum dried at 60° C., yielding Polymer P-5 in white solid form. Polymer P-5 was analyzed for composition by ¹³C- and ¹H-NMR and for Mw and Mw/Mn by GPC.

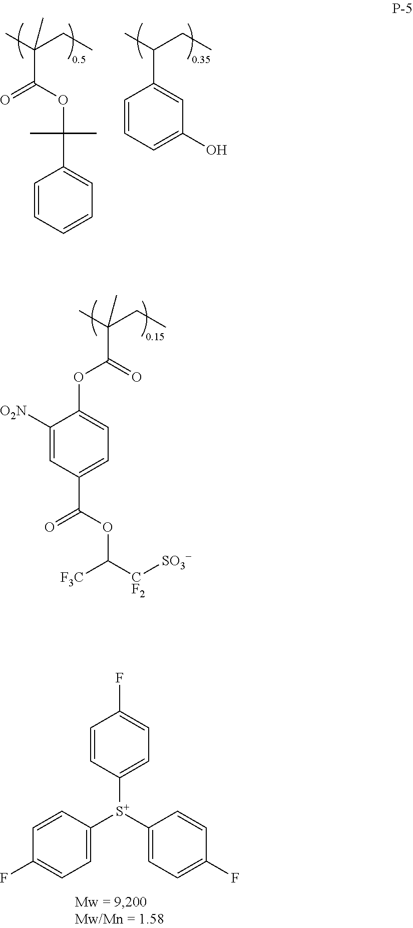

### Synthesis Example 6

Synthesis of Polymer P-6

A 2-L flask was charged with 8.4 g of 1-methyl-1-cyclopentyl methacrylate, 4.2 g of 3-hydroxystyrene, 14.4 g of Monomer PM-6, and 40 g of THF solvent. The reactor was cooled at −70° C. in nitrogen atmosphere, after which vacuum pumping and nitrogen blow were repeated three times. The reactor was warmed up to room temperature, whereupon 1.2 g of AIBN was added. The reactor was heated at 60° C., whereupon reaction ran for 15 hours. The reaction solution was poured into 1 L of IPA for precipitation. The precipitated white solid was collected by filtration and vacuum dried at 60° C., yielding Polymer P-6 in white solid form. Polymer P-6 was analyzed for composition by ¹³C- and ¹H-NMR and for Mw and Mw/Mn by GPC.

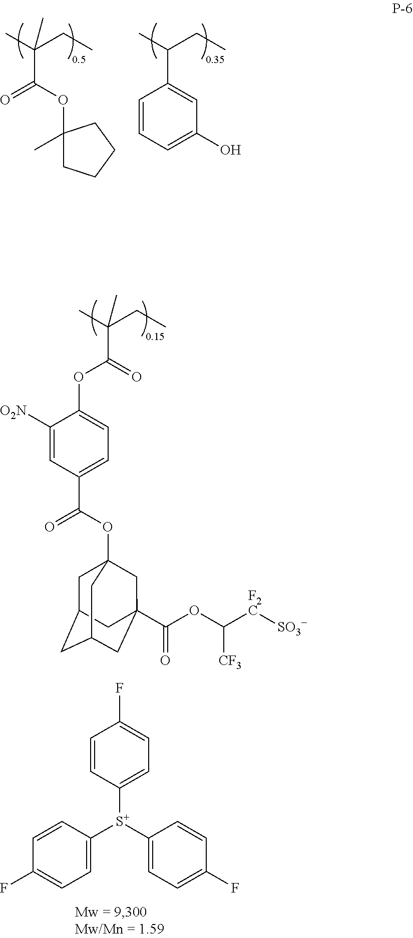

### Synthesis Example 7

Synthesis of Polymer P-7

A 2-L flask was charged with 8.4 g of 1-methyl-1-cyclopentyl methacrylate, 4.2 g of 3-hydroxystyrene, 14.1 g of Monomer PM-7, and 40 g of THF solvent. The reactor was cooled at −70° C. in nitrogen atmosphere, after which vacuum pumping and nitrogen blow were repeated three times. The reactor was warmed up to room temperature, whereupon 1.2 g of AIBN was added. The reactor was heated at 60° C., whereupon reaction ran for 15 hours. The reaction solution was poured into 1 L of IPA for precipitation. The precipitated white solid was collected by filtration and vacuum dried at 60° C., yielding Polymer P-7 in white solid form. Polymer P-7 was analyzed for composition by ¹³C- and ¹H-NMR and for Mw and Mw/Mn by GPC.

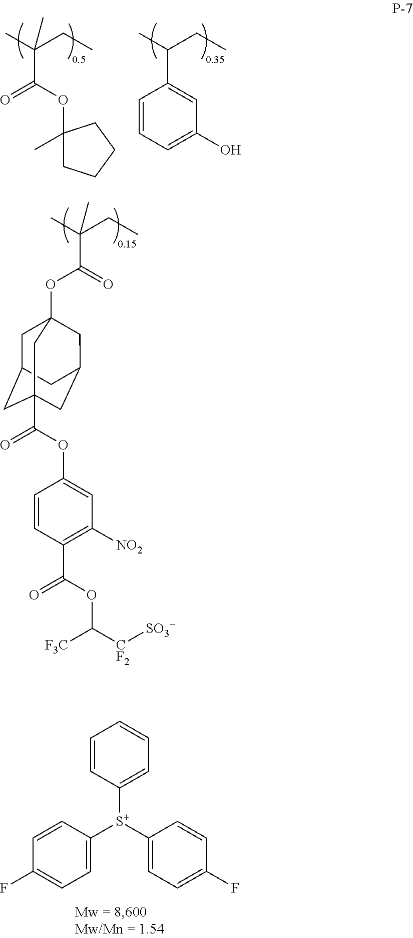

### Synthesis Example 8

Synthesis of Polymer P-8

A 2-L flask was charged with 8.4 g of 1-methyl-1-cyclopentyl methacrylate, 4.2 g of 3-hydroxystyrene, 11.3 g of Monomer PM-8, and 40 g of THF solvent. The reactor was cooled at −70° C. in nitrogen atmosphere, after which vacuum pumping and nitrogen blow were repeated three times. The reactor was warmed up to room temperature, whereupon 1.2 g of AIBN was added. The reactor was heated at 60° C., whereupon reaction ran for 15 hours. The reaction solution was poured into 1 L of IPA for precipitation. The precipitated white solid was collected by filtration and vacuum dried at 60° C., yielding Polymer P-8 in white solid form. Polymer P-8 was analyzed for composition by ¹³C- and ¹H-NMR and for Mw and Mw/Mn by GPC.

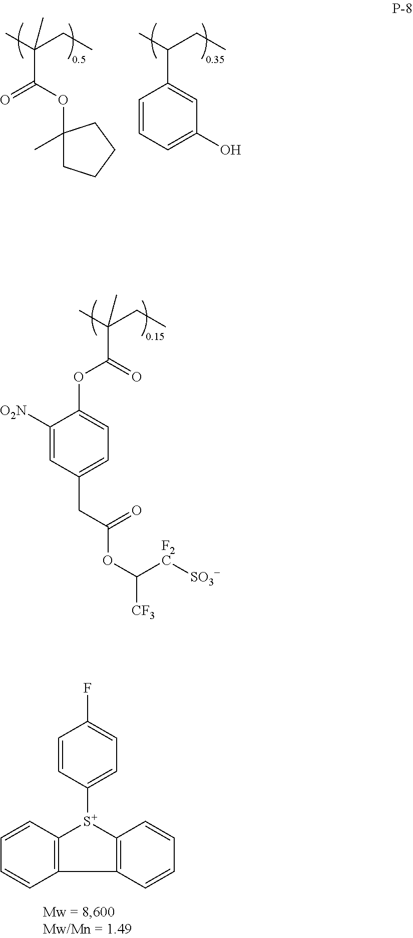

### Synthesis Example 9

Synthesis of Polymer P-9

A 2-L flask was charged with 8.4 g of 1-methyl-1-cyclopentyl methacrylate, 4.2 g of 3-hydroxystyrene, 11.9 g of Monomer PM-9, and 40 g of THF solvent. The reactor was cooled at −70° C. in nitrogen atmosphere, after which vacuum pumping and nitrogen blow were repeated three times. The reactor was warmed up to room temperature, whereupon 1.2 g of AIBN was added. The reactor was heated at 60° C., whereupon reaction ran for 15 hours. The reaction solution was poured into 1 L of IPA for precipitation. The precipitated white solid was collected by filtration and vacuum dried at 60° C., yielding Polymer P-9 in white solid form. Polymer P-9 was analyzed for composition by ¹³C- and ¹H-NMR and for Mw and Mw/Mn by GPC.

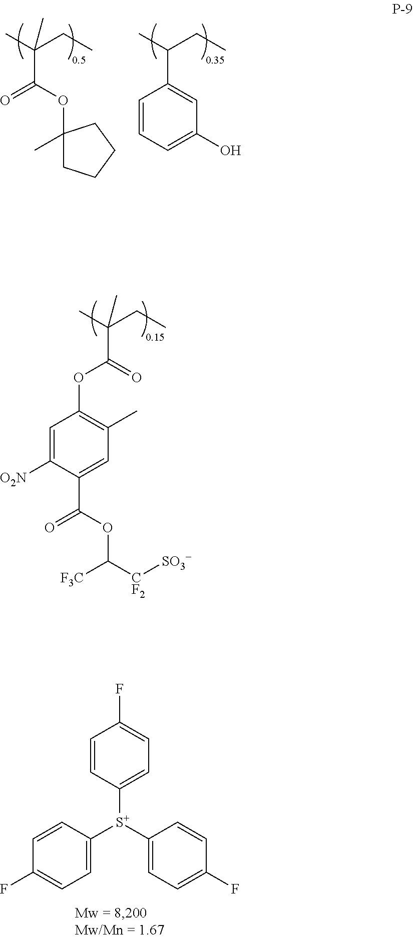

### Synthesis Example 10

Synthesis of Polymer P-10

A 2-L flask was charged with 8.4 g of 1-methyl-1-cyclopentyl methacrylate, 4.2 g of 3-hydroxystyrene, 13.1 g of Monomer PM-10, and 40 g of THF solvent. The reactor was cooled at −70° C. in nitrogen atmosphere, after which vacuum pumping and nitrogen blow were repeated three times. The reactor was warmed up to room temperature, whereupon 1.2 g of AIBN was added. The reactor was heated at 60° C., whereupon reaction ran for 15 hours. The reaction solution was poured into 1 L of IPA for precipitation. The precipitated white solid was collected by filtration and vacuum dried at 60° C., yielding Polymer P-10 in white solid form. Polymer P-10 was analyzed for composition by ¹³C- and ¹H-NMR and for Mw and Mw/Mn by GPC.

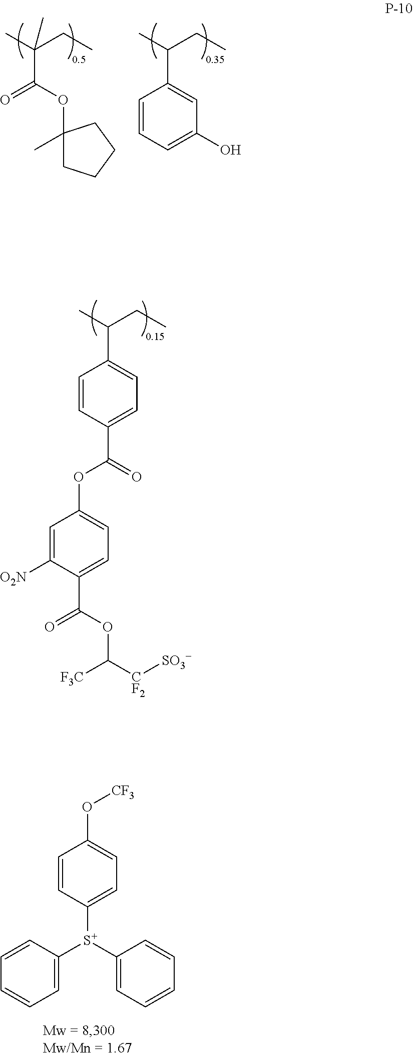

### Synthesis Example 11

Synthesis of Polymer P-11

A 2-L flask was charged with 8.4 g of 1-methyl-1-cyclopentyl methacrylate, 3.6 g of 3-hydroxystyrene, 3.2 g of Monomer FM-1, 14.4 g of Monomer PM-11, and 40 g of THF solvent. The reactor was cooled at −70° C. in nitrogen atmosphere, after which vacuum pumping and nitrogen blow were repeated three times. The reactor was warmed up to room temperature, whereupon 1.2 g of AIBN was added. The reactor was heated at 60° C., whereupon reaction ran for 15 hours. The reaction solution was poured into 1 L of IPA for precipitation. The precipitated white solid was collected by filtration and vacuum dried at 60° C., yielding Polymer P-11 in white solid form. Polymer P-11 was analyzed for composition by ¹³C- and ¹H-NMR and for Mw and Mw/Mn by GPC.

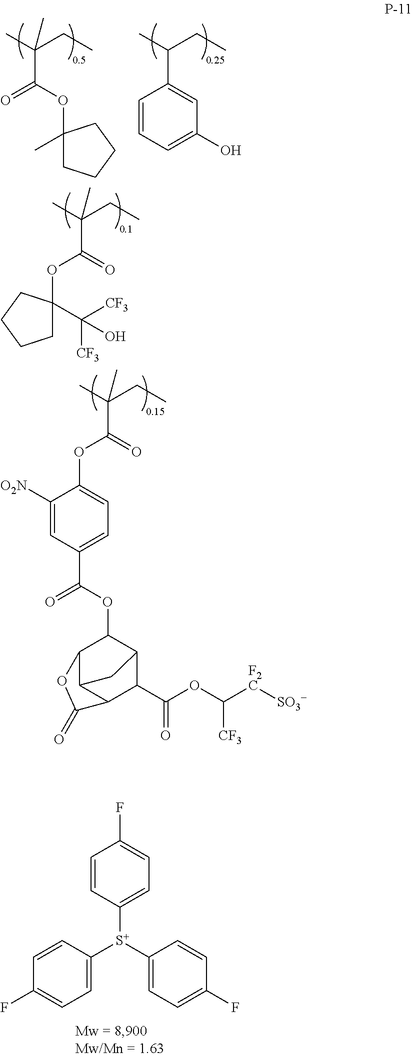

### Synthesis Example 12

Synthesis of Polymer P-12

A 2-L flask was charged with 11.1 g of Monomer AM-1, 4.2 g of 3-hydroxystyrene, 12.8 g of Monomer PM-12, and 40 g of THF solvent. The reactor was cooled at −70° C. in nitrogen atmosphere, after which vacuum pumping and nitrogen blow were repeated three times. The reactor was warmed up to room temperature, whereupon 1.2 g of AIBN was added. The reactor was heated at 60° C., whereupon reaction ran for 15 hours. The reaction solution was poured into 1 L of IPA for precipitation. The precipitated white solid was collected by filtration and vacuum dried at 60° C., yielding Polymer P-12 in white solid form. Polymer P-12 was analyzed for composition by ¹³C- and ¹H-NMR and for Mw and Mw/Mn by GPC.

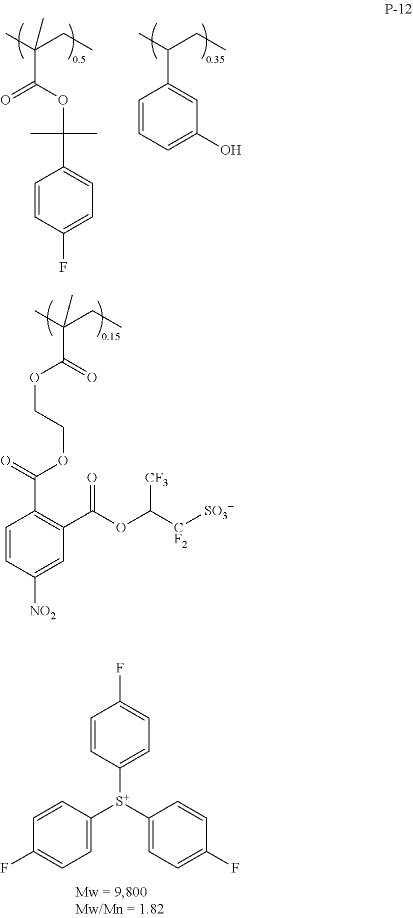

### Synthesis Example 13

Synthesis of Polymer P-13

A 2-L flask was charged with 12.2 g of Monomer AM-1, 4.2 g of 3-hydroxystyrene, 7.6 g of Monomer PM-13, and 40 g of THF solvent. The reactor was cooled at −70° C. in nitrogen atmosphere, after which vacuum pumping and nitrogen blow were repeated three times. The reactor was warmed up to room temperature, whereupon 1.2 g of AIBN was added. The reactor was heated at 60° C., whereupon reaction ran for 15 hours. The reaction solution was poured into 1 L of IPA for precipitation. The precipitated white solid was collected by filtration and vacuum dried at 60° C., yielding Polymer P-13 in white solid form. Polymer P-13 was analyzed for composition by ¹³C- and ¹H-NMR and for Mw and Mw/Mn by GPC.

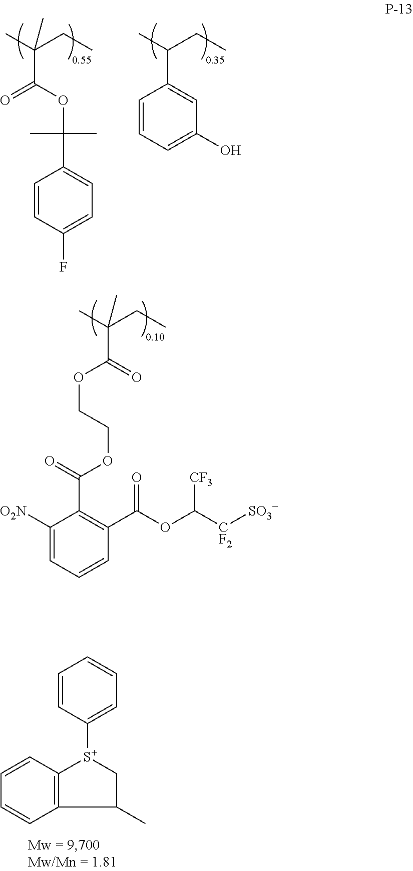

### Comparative Synthesis Example 1

Synthesis of Comparative Polymer cP-1

Comparative Polymer cP-1 was obtained in white solid form by the same procedure as in Synthesis Example 10 except that Monomer PM-10 was replaced by Monomer cPM-1. Comparative Polymer cP-1 was analyzed for composition by ¹³C- and ¹H-NMR and for Mw and Mw/Mn by GPC.

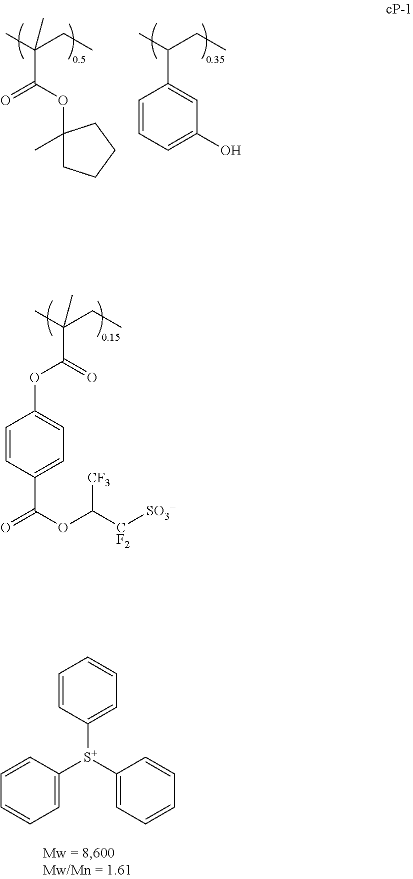

### Examples 1 to 13 and Comparative Example 1

### (1) Preparation of Resist Composition

Resist compositions were prepared by dissolving various components in a solvent in accordance with the recipe shown in Table 1, and filtering through a filter having a pore size of 0.2 μm. The solvent contained 100 ppm of surfactant PolyFox PF-636 (Omnova Solutions Inc.).

The components in Table 1 are as identified below.

Organic solvent:

PGMEA (propylene glycol monomethyl ether acetate)

EL (ethyl lactate)

DAA (diacetone alcohol)

Acid generator: PAG-1

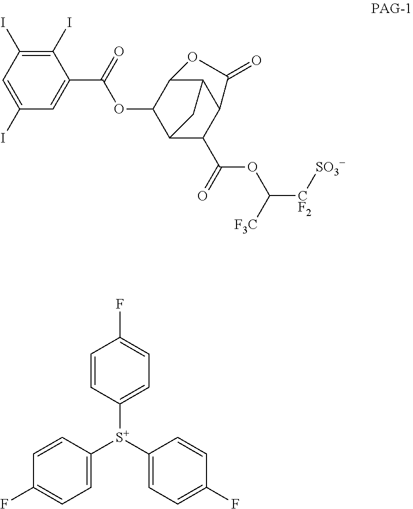

### Quencher: Q-1

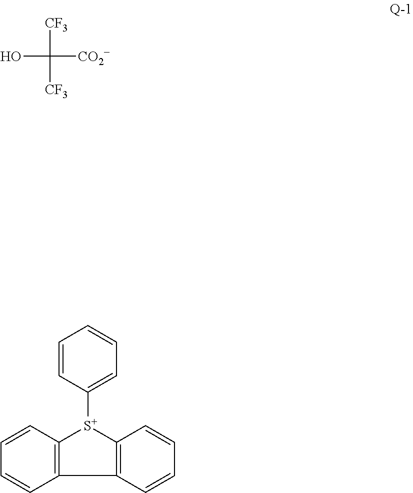

### (2) EUV Lithography Test

Each of the resist compositions in Table 1 was spin coated on a silicon substrate having a 20-nm coating of silicon-containing spin-on hard mask SHB-A940 (Shin-Etsu Chemical Co., Ltd., Si content 43 wt %) and prebaked on a hotplate at 105° C. for 60 seconds to form a resist film of 50 nm thick. Using an EUV scanner NXE3400 (ASML, NA 0.33, a 0.9/0.6, quadrupole illumination), the resist film was exposed to EUV through a mask bearing a hole pattern at a pitch 46 nm (on-wafer size) and +20% bias. The resist film was baked (PEB) on a hotplate at the temperature shown in Table 1 for 60 seconds and developed in a 2.38 wt % TMAH aqueous solution for 30 seconds to form a hole pattern having a size of 23 nm.

The resist pattern was observed under CD-SEM (CG-6300, Hitachi High-Technologies Corp.). The exposure close that provides a hole pattern having a size of 23 nm is reported as sensitivity. The size of 50 holes was measured, from which a 3-fold value (3a) of standard deviation (a) was computed and reported as size variation or CDU.

The resist composition is shown in Table 1 together with the sensitivity and CDU of EUV lithography.

TABLE 1

| | | | Acid | | | | | |
|---|---|---|---|---|---|---|---|---|
| | | Polymer | generator | Quencher | Organic solvent | PEB temp. | Sensitivity | CDU |
| | | (pbw) | (pbw) | (pbw) | (pbw) | (° C.) | (mJ/cm²) | (nm) |
| Example | 1 | P-1 | PAG-1 | Q-1 | PGMEA (2,000) | 85 | 26 | 2.8 |
| | | (100) | (12.1) | (4.72) | DAA (500) | | | |
| | 2 | P-2 | — | Q-1 | PGMEA (2,000) | 85 | 28 | 2.6 |
| | | (100) | | (4.72) | DAA (500) | | | |
| | 3 | P-3 | — | Q-1 | PGMEA (2,000) | 85 | 27 | 2.4 |
| | | (100) | | (4.72) | DAA (500) | | | |
| | 4 | P-4 | — | Q-1 | PGMEA (2,000) | 85 | 27 | 2.3 |
| | | (100) | | (4.72) | DAA (500) | | | |
| | 5 | P-5 | — | Q-1 | PGMEA (2,000) | 85 | 28 | 2.6 |
| | | (100) | | (4.72) | DAA (500) | | | |
| | 6 | P-6 | — | Q-1 | PGMEA (2,000) | 85 | 28 | 2.5 |
| | | (100) | | (4.72) | DAA (500) | | | |
| | 7 | P-7 | — | Q-1 | PGMEA (2,000) | 85 | 26 | 2.6 |
| | | (100) | | (4.72) | DAA (500) | | | |
| | 8 | P-8 | — | Q-1 | EL (2,000) | 85 | 31 | 2.4 |
| | | (100) | | (4.72) | DAA (500) | | | |
| | 9 | P-9 | — | Q-1 | PGMEA (2,000) | 85 | 27 | 2.3 |
| | | (100) | | (4.72) | DAA (500) | | | |
| | 10 | P-10 | — | Q-1 | PGMEA (2,000) | 85 | 27 | 2.4 |
| | | (100) | | (4.72) | DAA (500) | | | |
| | 11 | P-11 | — | Q-1 | PGMEA (2,000) | 85 | 28 | 2.3 |
| | | (100) | | (4.72) | DAA (500) | | | |
| | 12 | P-12 | — | Q-1 | PGMEA (2,000) | 85 | 26 | 2.3 |
| | | (100) | | (4.72) | DAA (500) | | | |
| | 13 | P-13 | — | Q-1 | PGMEA (2,000) | 85 | 26 | 2.4 |
| | | (100) | | (4.72) | DAA (500) | | | |
| Comparative | 1 | cP-1 | — | Q-1 | PGMEA (2,000) | 85 | 36 | 4.0 |
| Example | | (100) | | (4.72) | DAA (500) | | | |

It is demonstrated in Table 1 that resist compositions comprising a polymer comprising repeat units having formula (a1) or (a2) offer a high sensitivity and improved CDU.

Japanese Patent Application No. 2021-099189 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A resist composition comprising a polymer comprising repeat units having the formula (a1) or (a2): 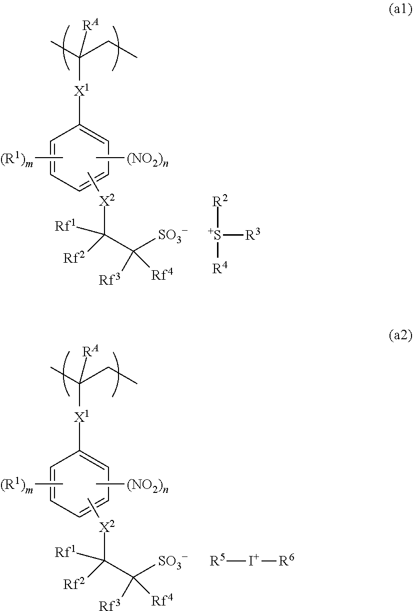
wherein R^{A} is hydrogen or methyl,
X¹ is a single bond, ester bond, amide bond or —X^{1A}—X^{1C}—X^{1B}—, X^{1A} and X^{1B} are each independently a single bond, ether bond or ester bond, X^{1C} is a C₁-C₁₂ saturated hydrocarbylene group, C₆-C₁₀ arylene group or a combination thereof, wherein some constituent —CH₂— may be replaced by an ether bond, ester bond, amide bond, lactone ring-containing moiety or sultone ring-containing moiety, and some or all of the hydrogen atoms on the aromatic ring may be substituted by a C₁-C₄ alkyl moiety, C₁-C₄ alkyloxy moiety, C₂-C₅ alkylcarbonyloxy moiety, halogen or nitro moiety,
X² is a single bond, ether bond, ester bond or —X^{2A}—X^{2C}—X^{2B}—, X^{2A} and X^{2B} are each independently a single bond, ether bond or ester bond, X^{2C} is a C₁-C₁₂ saturated hydrocarbylene group, C₆-C₁₀ arylene group or a combination thereof, wherein some constituent —CH₂— may be replaced by an ether bond, ester bond, amide bond, lactone ring-containing moiety or sultone ring-containing moiety, and some or all of the hydrogen atoms on the aromatic ring may be substituted by a C₁-C₄ alkyl moiety, C₁-C₄ alkyloxy moiety, C₂-C₅ alkylcarbonyloxy moiety, halogen or nitro moiety,
Rf¹ to Rf⁴ are each independently hydrogen, fluorine or trifluoromethyl, at least one of Rf¹ to Rf⁴ being fluorine or trifluoromethyl, and Rf¹ and Rf², taken together, may form a carbonyl group,
R¹ is a C₁-C₄ alkyl group, C₁-C₄ alkyloxy group, C₂-C₅ alkylcarbonyloxy group or halogen,
R² to R⁶ are each independently halogen or a C₁-C₂₀ hydrocarbyl group which may contain a heteroatom, R² and R³ may bond together to form a ring with the sulfur atom to which they are attached,
m is an integer of 0 to 3, and n is 1 or 2.

2. The resist composition of claim 1 wherein the repeat units having formula (a1) have the formula (a1-1) and the repeat units having formula (a2) have the formula (a2-1): 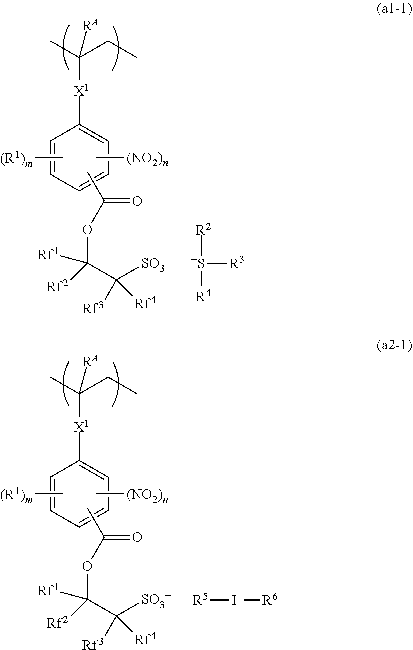
wherein R^{A}, X¹, Rf¹ to Rf⁴, R¹ to R⁶, m, and n are as defined above.

3. The resist composition of claim 1 wherein the polymer further comprises repeat units having the formula (b1) or (b2): 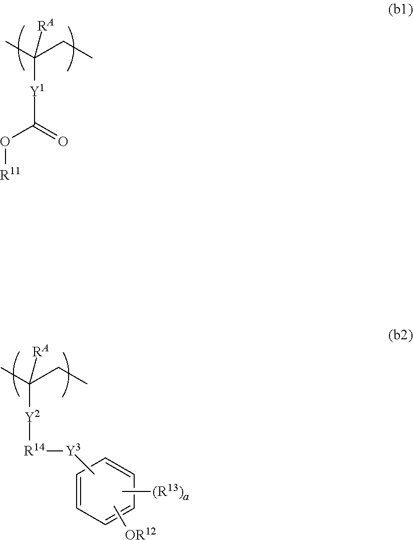
wherein R^{A} is each independently hydrogen or methyl,
Y¹ is a single bond, phenylene, naphthylene, or a C₁-C₁₂ linking group containing at least one moiety selected from ester bond, ether bond and lactone ring,
Y² is a single bond or ester bond,
R¹¹ and R¹² are each independently an acid labile group,
R¹³ is a C₁-C₄ saturated hydrocarbyl group, halogen, C₂-C₅ saturated hydrocarbylcarbonyl group, cyano group or C₂-C₅ saturated hydrocarbyloxycarbonyl group,
R¹⁴ is a single bond or a C₁-C₆ alkanediyl group which may contain an ether bond or ester bond, and
a is an integer of 0 to 4.

4. The resist composition of claim 3 which is a chemically amplified positive resist composition.

5. The resist composition of claim 1 wherein the polymer is free of an acid labile group.

6. The resist composition of claim 5 which is a chemically amplified negative resist composition.

7. The resist composition of claim 1, further comprising an organic solvent.

8. The resist composition of claim 1, further comprising a quencher.

9. The resist composition of claim 1, further comprising a surfactant.

10. A pattern forming process comprising the steps of applying the resist composition of claim 1 onto a substrate to form a resist film thereon, exposing the resist film to high-energy radiation, and developing the exposed resist film in a developer.

11. The process of claim 10 wherein the high-energy radiation is ArF excimer laser of wavelength 193 nm, KrF excimer laser of wavelength 248 nm, EB, or EUV of wavelength 3 to 15 nm.
